(19) United States
(12) Patent Application Publication
(10) Pub. No.: US 2026/0123170 A1
(43) Pub. Date: Apr. 30, 2026

(54) CONDENSED HETEROCYCLIC COMPOUND, LIGHT-EMITTING DEVICE AND ELECTRONIC DEVICE

(71) Applicant: Samsung Display Co., LTD., Yongin-si (KR)

(72) Inventors: Mun Ki SIM, Yongin-si (KR); Se Ran KIM, Yongin-si (KR); Hyung Jong KIM, Yongin-si (KR); Jun Ha PARK, Yongin-si (KR); Han Kyu PAK, Yongin-si (KR); Min Jae SUNG, Yongin-si (KR); Hyo Sup SHIN, Yongin-si (KR); Jae Yong LEE, Yongin-si (KR); Min Jung JUNG, Yongin-si (KR); Seok Hwan HWANG, Yongin-si (KR)

(21) Appl. No.: 19/267,569

(22) Filed: Jul. 13, 2025

(30) Foreign Application Priority Data
Oct. 31, 2024 (KR) 10-2024-0152226

(51) Int. Cl. H10K 50/12; C07F 5/02; H10K 85/30; H10K 85/40; H10K 85/60; H10K 101/20

(52) U.S. Cl. CPC H10K 50/12; C07F 5/027; H10K 85/346; H10K 85/40; H10K 85/615; H10K 85/633; H10K 85/636; H10K 85/654; H10K 85/6572; H10K 85/658; H10K 2101/20

(57) ABSTRACT

A condensed heterocyclic compound, a light-emitting device that includes the condensed heterocyclic compound, an electronic device that includes the light-emitting device.

The light-emitting device includes a first electrode, a second electrode, and an emission layer disposed between the first electrode and the second electrode. The emission layer includes the condensed heterocyclic compound represented by Chemical Formula 1.

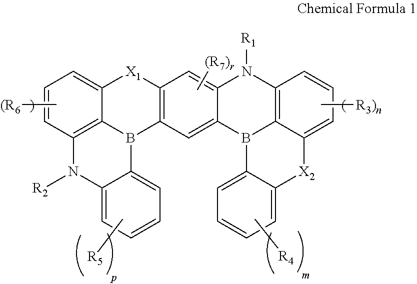

This application claims priority to Korean Patent Application No. 10-2024-0152226, filed on Oct. 31, 2024 in the Korean Intellectual Property Office (KIPO), and all the benefits accruing therefrom under 35 U.S.C. § 119, the content of which in its entirety is herein incorporated by reference.

### TECHNICAL FIELD

Embodiments of the present application relate to a condensed heterocyclic compound, a light-emitting device and an electronic device.

### BACKGROUND

An organic light-emitting device has a self-luminous property, and may provide improved viewing angle and contrast properties. Additionally, a high response speed and a high luminance may be provided.

The organic light-emitting device may include an emission layer disposed between a first electrode and a second electrode. A hole transferred from the first electrode and an electron transferred from the second electrode may be recombined in the emission layer to generate an exciton. Light emission properties are implemented as the exciton is shifted from an excited state to a ground state.

The emission layer may include a host material and a dopant material for implementing the above-described light emitting mechanism.

### SUMMARY

According to an aspect of the present disclosure, there is provided a provide a condensed heterocyclic compound having improved spectroscopic and luminescent properties.

According to an aspect of the present disclosure, there is provided a light-emitting device having improved luminescent properties and reliability.

According to an aspect of the present disclosure, there is provided an electronic device including the light-emitting device.

A condensed heterocyclic compound is represented by Chemical Formula 1:

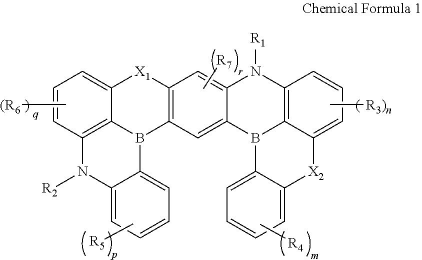

where in Chemical Formula 1, X₁ and X₂ are each independently O, S or Se, and R₁ and R₂ are each independently represented by Chemical Formula 2:

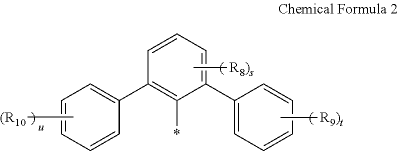

where in Chemical Formulae 1 and 2, R₃ to R₁₀ are each independently hydrogen, deuterium, halogen, a hydroxyl group, a cyano group, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group, a substituted or unsubstituted C₈-C₆₀ condensed polycyclic group, —SiRR′R″, —P(═O)RR′, —NRR′, —BRR′, —C(═O)R or —S(═O)₂R; or two or more of R₃ to R₁₀ are combined with each other to form a substituted or unsubstituted C₃-C₆₀ cycloalkyl ring, a substituted or unsubstituted C₅-C₆₀ cycloalkenyl ring, a substituted or unsubstituted C₃-C₆₀ heterocycloalkyl ring, a substituted or unsubstituted C₃-C₆₀ heterocycloalkenyl ring, a substituted or unsubstituted C₆-C₆₀ aryl ring, or a substituted or unsubstituted C₂-C₆₀ heteroaryl ring.

R, R′ and R″ are each independently hydrogen, deuterium, halogen, a hydroxyl group, a cyano group, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group or a substituted or unsubstituted C₈-C₆₀ condensed polycyclic group.

n, q and s are each independently an integer from 0 to 3. m and p are each independently an integer from 0 to 4. r is an integer from 0 to 2. t and u are each independently an integer from 0 to 5. When n, m, p, q, r, s, t and u are each 2 or more, two or more of each of R₃ to R₁₀ are the same or different from each other, and * represents a bonding position.

The light-emitting device includes a first electrode, a second electrode, and an intermediate layer between the first electrode and the second electrode. The intermediate layer includes an emission layer that includes the condensed heterocyclic compound represented by Chemical Formula 1:

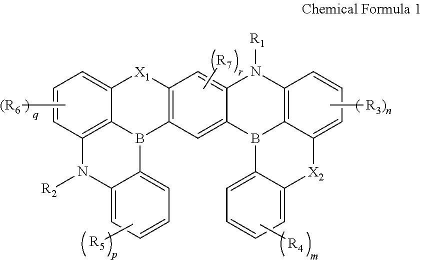

where in Chemical Formula 1, X₁ and X₂ are each independently O, S or Se, and R₁ and R₂ are each independently represented by Chemical Formula 2:

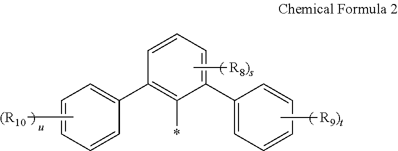

where in Chemical Formulae 1 and 2, R₃ to R₁₀ are each independently hydrogen, deuterium, halogen, a hydroxyl group, a cyano group, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group, a substituted or unsubstituted C₈-C₆₀ condensed polycyclic group, —SiRR′R″, —P(═O)RR′, —NRR′, —BRR′, —C(═O)R or —S(═O)₂R; or two or more of R₃ to R₁₀ are combined with each other to form a substituted or unsubstituted C₃-C₆₀ cycloalkyl ring, a substituted or unsubstituted C₅-C₆₀ cycloalkenyl ring, a substituted or unsubstituted C₃-C₆₀ heterocycloalkyl ring, a substituted or unsubstituted C₃-C₆₀ heterocycloalkenyl ring, a substituted or unsubstituted C₆-C₆₀ aryl ring, or a substituted or unsubstituted C₂-C₆₀ heteroaryl ring.

R, R′ and R″ are each independently hydrogen, deuterium, halogen, a hydroxyl group, a cyano group, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group or a substituted or unsubstituted C₈-C₆₀ condensed polycyclic group.

n, q and s are each independently an integer from 0 to 3. m and p are each independently an integer from 0 to 4. r is an integer from 0 to 2. t and u are each independently an integer from 0 to 5. When n, m, p, q, r, s, t and u are each 2 or more, two or more of each of R₃ to R₁₀ are the same or different from each other, and * represents a bonding position.

An electronic device including the light-emitting device is provided.

The electronic device may be at least one of a flat panel display, a curved display, a computer monitor, a medical monitor, a television, a billboard, a light for indoor or outdoor lighting and/or signals, a head-up display, a full or partial transparent display, a flexible display, a rollable display, a foldable display, a stretchable display, a laser printer, a phone, a mobile phone, a tablet, a phablet, a personal information terminal (PDA), a wearable device, a laptop computer, a digital camera, a camcorder, a viewfinder, a micro display, a three-dimensional (3D) display, a virtual reality or augmented reality display, a vehicle, a video wall including multiple displays tiled together, a theater or stadium screen, a phototherapy device, or a signage.

The condensed heterocyclic compound according to embodiments of the present inventive concepts may have a high depth of a highest occupied molecular orbital (HOMO) energy level, and may have improved luminous efficiency.

The condensed heterocyclic compound may have a three-dimensional chemical structure, thereby increasing a distance to a host and reducing a side reaction due to interaction between molecules. Thus, a light-emitting device having improved life-span properties may be implemented.

The condensed heterocyclic compound has a balanced chemical structure for a chalcogen element, allowing for the provision of a light-emitting device with improved efficiency and life-span properties.

### BRIEF DESCRIPTION OF THE DRAWINGS

FIGS. 1 to 6 are schematic cross-sectional views illustrating light-emitting devices in accordance with an embodiment.

FIG. 7 is a schematic cross-sectional view illustrating a display device in accordance with an embodiment.

FIG. 8 is a schematic cross-sectional view illustrating a display device in accordance with an embodiment.

FIG. 9 is a schematic cross-sectional view illustrating a stack construction of light-emitting structure in a display device in accordance with an embodiment.

FIG. 10 is a schematic cross-sectional view illustrating a display device in accordance with an embodiment.

FIG. 11 is a schematic cross-sectional view illustrating a display device in accordance with an embodiment.

FIG. 12 is a block diagram of an electronic device in accordance with an embodiment.

FIG. 13 is a schematic diagram of an electronic device in accordance with an embodiment.

FIG. 14 is a schematic exploded perspective view illustrating an electronic device in accordance with an embodiment.

FIG. 15 is a schematic cross-sectional view illustrating an electronic device in accordance with an embodiment.

### DETAILED DESCRIPTION OF THE EMBODIMENTS

According to the present disclosure, a condensed heterocyclic compound including a terphenyl structure bonded to nitrogen forming a condensed ring. Further, a light-emitting device, an electronic device including the condensed heterocyclic compound are provided.

### Definition of Terminology

The invention now will be described more fully hereinafter with reference to the accompanying drawings, in which various embodiments are shown. This invention may, however, be embodied in many different forms, and should not be construed as limited to the embodiments set forth herein. Like reference numerals refer to like elements throughout.

It will be understood that, although the terms “first,” “second,” “third” or the like. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. Therefore, reference to “an” element in a claim followed by reference to “the” element is inclusive of one element as well as a plurality of the elements.

“At least one” is not to be construed as limiting “a” or “an.” “Or” means “and/or.” As used herein, the term “and/or” includes any and all combinations of one or more of the associated listed items.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

In the present specification, the term “substituted or unsubstituted” may refer to being substituted or unsubstituted by one or more substituent selected from the group consisting of, e.g., a deuterium atom, a halogen atom, a cyano group, a nitro group, an amino group, a silyl group, an oxy group, a thio group, a sulfinyl group, a sulfonyl group, a carbonyl group, an ester group, boron, a phosphine oxide group, a phosphine sulfide group, an alkyl group (e.g., a C₁-C₆₀, C₁-C₁₀ alkyl group), an alkenyl group (e.g., a C₂-C₆₀, C₂-C₁₀ alkenyl group), an alkynyl group (e.g., a C₂-C₆₀, C₂-C₁₀ alkynyl group), an alkoxy group (e.g., a C₁-C₆₀, C₁-C₁₀ alkoxy group), a hydrocarbon ring group, an aryl group (e.g., a C₆-C₆₀ aryl group), and a heterocyclic group (e.g., a C₁-C₆₀ heterocyclic group). For example, the term “substituted alkyl group” may refer to a group in which at least one of hydrogen atoms of the alkyl group is substituted with the above-described substituent, and thus the substituent is further bonded to a carbon atom of the alkyl group.

The substituent may include a combination of substituents selected from the groups described above. For example, at least one hydrogen atom in the alkyl group, the aryl group, or the like, included as a substituent may be substituted with a deuterium atom, a halogen atom, a cyano group, a nitro group, an amino group, a silyl group, an oxy group, a thio group, a sulfinyl group, a sulfonyl group, a carbonyl group, an ester group, boron, a phosphine oxide group, a phosphine sulfide group, an alkyl group, an alkenyl group, an alkynyl group, a hydrocarbon ring group, an aryl group, a heterocyclic group, or a combination thereof.

In the substituents described above, a multivalent substituent such as an amino group, a phosphine sulfide group, a phosphine oxide group, a sulfinyl group, a sulfonyl group, an oxy group, a carbonyl group, an ester group, or the like, may each independently be substituted with a C₁-C₁₀ alkyl group, a C₁-C₁₀ alkenyl group, a C₁-C₁₀ alkynyl group, or a C₆-C₁₀ aryl group.

In the specification, the term “substituted or unsubstituted Cₐ-C_{b} Y group” the range of a to b refers to the number of carbon atoms in an unsubstituted Y group, and may not include the number of carbon atoms of a substituent.

In the specification, an alkyl group may be a monovalent hydrocarbon group in which one hydrogen atom is removed from a linear or branched hydrocarbon group. Examples of an alkyl group may include a methyl group, an ethyl group, a propyl group, a sec-butyl group, a tert-butyl group, an iso-butyl group, a pentyl group, a neopentyl group, a 2-ethyl butyl group, a 3,3-dimethyl butyl group, a hexyl group, a heptyl group, an octyl group, or the like.

In the specification, an alkylene group may be a divalent hydrocarbon group in which two hydrogen atoms are removed from a linear or branched hydrocarbon group.

In the specification, an alkenyl group may have the same skeleton as that of an alkyl group, and may be a monovalent hydrocarbon group that includes at least one carbon-carbon double bond. In the specification, an alkenylene group may be a divalent hydrocarbon group in which one hydrogen atom is further removed from an alkenyl group.

In the specification, an alkynyl group may have the same skeleton as that of an alkyl group, and may be a monovalent hydrocarbon group that includes at least one carbon-carbon triple bond. In the specification, an alkynylene group may be a divalent hydrocarbon group in which one hydrogen atom is further removed from an alkynyl group.

In the specification, an aryl group may be a monovalent hydrocarbon group in which one hydrogen atom is removed from a hydrocarbon group having an aromatic structure. The definition of an aryl group may also encompass a group in which multiple aromatic rings are directly connected, such as a biphenyl group. Examples of an aryl group may include, e.g., a phenyl group, a naphthyl group, an anthracenyl group, a phenanthrenyl group, a pyrenyl group, a fluorenyl group, a tetracenyl group, a biphenyl group, a terphenyl group, a quaterphenyl group, a chrysenyl group, or the like.

In the specification, a group in which two or more aryl rings are condensed to each other or linked to each other by an alicyclic hydrocarbon ring, such as a fluorenyl group, can be encompassed in the definition of an aryl group.

For example, a biphenyl group may be interpreted as an aryl group, or may be interpreted as a phenyl group that is substituted with a phenyl group.

In the specification, an arylene group may be a divalent hydrocarbon group in which two hydrogen atoms are removed from an aryl group.

In the specification, a heteroaryl group may be a monovalent group having an aromatic structure that includes at least one heteroatom such as B, O, P, S, and Si as a ring-forming atom. In the specification, a heteroarylene group may be a divalent group having an aromatic structure that includes at least one heteroatom such as B, O, P, S, and Si as a ring-forming atom. When a heteroaryl group or a heteroarylene group includes two or more heteroatoms, the two or more heteroatoms may be the same as or different from each other.

In the specification, a group in which two or more aryl rings are condensed or linked to a non-aromatic heterocyclic ring, such as a carbazole group, can also be encompassed in the definition of a heteroaryl group.

In the specification, the term “cyclic group” may encompass a monocyclic group or a polycyclic group, and may also encompass an alicyclic ring or an aromatic ring.

In the specification, the term “polycyclic group” may be a group in which two or more rings are connected to each other or condensed to each other through one or more atoms. For example, a polycyclic structure may include a bicyclic structure through a bridge carbon, a spiro structure, a fused structure, or the like.

In the specification, the term “condensed group” or “condensed ring structure” may each be a group in which two or more adjacent rings share two or more atoms among the above-described polycyclic structures. Examples of a condensed ring structure may include naphthalene, anthracene, phenanthrene, fluorene, pyrene, benzopyrene, pentacene, polyacene, helicene, or the like.

In the specification, the terms “cycloalkyl group” and “cycloalkenyl group” are a saturated cyclic group and unsaturated cyclic group, respectively, in which ring-forming atoms consist of carbon. The heterocyclic group (e.g., a C₁-C₆₀ heterocyclic group) may be a cyclic group that further include a heteroatom as ring-forming atoms in addition to carbon.

Each of the cycloalkyl, cycloalkenyl and heterocyclic groups may be a monocyclic group consisting of one ring or a polycyclic group in which two or more rings are condensed with each other.

### Condensed Heterocyclic Compound

A condensed heterocyclic compound represented by Chemical Formula 1 is provided.

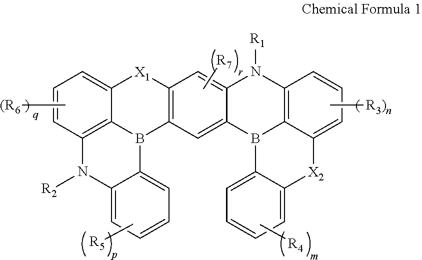

In Chemical Formula 1, X₁ and X₂ may each independently be O, S or Se. In an embodiment, X₁ and X₂ may be the same or different from each other.

In an embodiment, X₁ and X₂ may be O. In an embodiment, X₁ and X₂ may be S. In an embodiment, X₁ and X₂ may be Se. In an embodiment, X₁ may be O, and X₂ may be S. In an embodiment, X₁ may be O, and X₂ may be Se. In an embodiment, X₁ may be S, and X₂ may be O. In an embodiment, X₁ may be S, and X₂ may be Se. In an embodiment, X₁ may be Se, and X₂ may be O. In an embodiment, X₁ may be Se, and X₂ may be S.

R₁ and R₂ may each independently be represented by Chemical Formula 2.

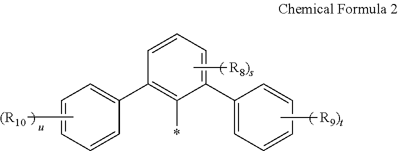

In Chemical Formulae 1 and 2, R₃ to R₁₀ may each independently be hydrogen, deuterium, halogen, a hydroxyl group, a cyano group, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group, a substituted or unsubstituted C₈-C₆₀ condensed polycyclic group, —SiRR′R″, —P(═O)RR′, —NRR′, —BRR′, —C(═O)R or —S(═O)₂R.

In an embodiment, R₃ to R₁₀ may each independently be hydrogen, deuterium, halogen, a hydroxyl group, a cyano group, a substituted or unsubstituted C₁-C₂₀ alkyl group, a substituted or unsubstituted C₂-C₂₀ alkenyl group, a substituted or unsubstituted C₂-C₂₀ alkynyl group, a substituted or unsubstituted C₁-C₂₀ alkoxy group, a substituted or unsubstituted C₃-C₄₀ cycloalkyl group, a substituted or unsubstituted C₅-C₄₀ cycloalkenyl group, a substituted or unsubstituted C₃-C₄₀ heterocycloalkyl group, a substituted or unsubstituted C₃-C₄₀ heterocycloalkenyl group, a substituted or unsubstituted C₆-C₄₀ aryl group, a substituted or unsubstituted C₂-C₄₀ heteroaryl group, a substituted or unsubstituted C₆-C₄₀ aryloxy group, a substituted or unsubstituted C₆-C₄₀ arylthio group, a substituted or unsubstituted C₈-C₄₀ condensed polycyclic group, —SiRR′R″, —P(═O)RR′, —NRR′, —BRR′, —C(═O)R or —S(═O)₂R.

In an embodiment, R₃ to R₁₀ may each independently be hydrogen, deuterium, a cyano group, a substituted or unsubstituted C₁-C₁₀ alkyl group, a substituted or unsubstituted C₂-C₁₀ alkenyl group, a substituted or unsubstituted C₂-C₁₀ alkynyl group, a substituted or unsubstituted C₁-C₁₀ alkoxy group, a substituted or unsubstituted C₃-C₂₀ cycloalkyl group, a substituted or unsubstituted C₅-C₂₀ cycloalkenyl group, a substituted or unsubstituted C₃-C₂₀ heterocycloalkyl group, a substituted or unsubstituted C₃-C₂₀ heterocycloalkenyl group, a substituted or unsubstituted C₆-C₂₀ aryl group, a substituted or unsubstituted C₂-C₂₀ heteroaryl group, a substituted or unsubstituted C₆-C₂₀ aryloxy group, a substituted or unsubstituted C₆-C₂₀ arylthio group, a substituted or unsubstituted C₈-C₂₀ condensed polycyclic group, —SiRR′R″ or —NRR′.

R, R′ and R″ may each independently be hydrogen, deuterium, halogen, a hydroxyl group, a cyano group, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group or a substituted or unsubstituted C₈-C₆₀ condensed polycyclic group.

In an embodiment, R₃ to R₁₀ may each independently be hydrogen, deuterium, a cyano group, a C₄-C₁₅ tert-alkyl group substituted or unsubstituted with deuterium (e.g., a tert-butyl group substituted or unsubstituted with deuterium), a C₃-C₁₅ trialkylsilyl group substituted or unsubstituted with deuterium (e.g., a trimethylsilyl group substituted or unsubstituted with deuterium), a C₁₈-C₄₀ triarylsilyl group substituted or unsubstituted with deuterium (e.g., a triphenylsilyl group substituted or unsubstituted with deuterium), a phenyl group substituted or unsubstituted with deuterium, a cyanophenyl group substituted or unsubstituted with deuterium, a C₇-C₂₀ alkylphenyl group substituted or unsubstituted with deuterium (e.g., a methylphenyl group substituted or unsubstituted with deuterium, a di-tert-butylphenyl group substituted or unsubstituted with deuterium, a trimethylphenyl group substituted or unsubstituted with deuterium), a biphenyl group substituted or unsubstituted with deuterium, a terphenyl group substituted or unsubstituted with deuterium, a naphthalene group substituted or unsubstituted with deuterium, a tetrahydronaphthalene group substituted or unsubstituted with deuterium, a C₁₁-C₄₀ alkyltetrahydronaphthalene group substituted or unsubstituted with deuterium (e.g., a tetramethylhydronaphthalene group substituted or unsubstituted with deuterium), a C₁₂-C₂₀ diarylamine group substituted or unsubstituted with deuterium (e.g., a diphenylamine group substituted or unsubstituted with deuterium), a carbazole group substituted or unsubstituted with deuterium, a dibenzofuran group substituted or unsubstituted with deuterium, a phenothiazine group substituted or unsubstituted with deuterium, or a pyridine group substituted or unsubstituted with deuterium.

In an embodiment, R₃ to R₁₀ may each independently be hydrogen, deuterium, an amidino group, a hydrazine group, a hydrazone group, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a naphthyl group, a tetrahydronaphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a benzoisoquinolinyl group, a phthalazinyl group, a naphthyridinyl group, a quinoxalinyl group, a benzoquinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a thiadiazolyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, an azafluorenyl group, or an azadibenzosilolyl group. These can be unsubstituted or substituted with the above-mentioned substituent.

In an embodiment, R₃ to R₁₀ may each independently be a substituted or unsubstituted C₆-C₂₀ aryl group or a substituted or unsubstituted C₂-C₁₅ heteroaryl group. For example, R₃ to R₁₀ may each independently be a C₆-C₂₀ aryl group substituted or unsubstituted with deuterium or a C₂-C₁₅ heteroaryl group substituted or unsubstituted with deuterium.

Accordingly, the condensed heterocyclic compound comprising an aryl structure, and resonance and electron transport properties of the condensed heterocyclic compound may be improved.

In Chemical Formulae 1 and 2, two or more of R₃ to R₁₀ may be combined with each other to form a ring. A remainder that may not form a ring may be selected from those listed groups.

In an embodiment, two or more of R₃ to R₁₀ may be combined with each other to form a substituted or unsubstituted C₃-C₆₀ cycloalkyl ring, a substituted or unsubstituted C₅-C₆₀ cycloalkenyl ring, a substituted or unsubstituted C₃-C₆₀ heterocycloalkyl ring, a substituted or unsubstituted C₃-C₆₀ heterocycloalkenyl ring, a substituted or unsubstituted C₆-C₆₀ aryl ring, or a substituted or unsubstituted C₂-C₆₀ heteroaryl ring.

In an embodiment, two or more of R₃ to R₁₀ may be combined with each other to form a substituted or unsubstituted C₃-C₄₀ cycloalkyl ring, a substituted or unsubstituted C₅-C₄₀ cycloalkenyl ring, a substituted or unsubstituted C₃-C₄₀ heterocycloalkyl ring, a substituted or unsubstituted C₃-C₄₀ heterocycloalkenyl ring, a substituted or unsubstituted C₆-C₄₀ aryl ring, or a substituted or unsubstituted C₂-C₄₀ heteroaryl ring. For example, when two or more of R₃ to R₁₀ are combined to form a ring, a substituted or unsubstituted C₂-C₄₀ condensed heteroaryl ring may be formed.

In an embodiment, when each of R₃ to R₁₀ are present in plural, adjacent ones may be combined to form a ring, or non-adjacent ones may be combined to form a ring.

For example, when R₃ is present in plural, multiple R₃ may be combined to form a ring. When R₄ is present in plural, multiple R₄ may be combined to form a ring. When R₅ is present in plural, multiple R₅ may be combined to form a ring.

For example, R₄ and R₅ may be combined to form a ring.

In Chemical Formulae 1 and 2, n, q and s may each independently be an integer from 0 to 3. For example, n, q and s may each independently be 0 or 1.

When each of n, q and s is 2 or more, two or more of each of R₃, R₆ and R₈ may each independently be the same or different from each other.

In Chemical Formula 1, m and p may each independently be an integer from 1 to 4. For example, m and p can each independently be 0 or 1.

When m and p are each 2 or more, two or more of each of R₄ and R₅ may each be independently the same or different from each other.

In Chemical Formula 1, r may be 0, 1 or 2. For example, r may be 0 or 1.

When r is 2, multiple R₇ may be the same or different from each other.

In Chemical Formula 2, t and u may each independently be an integer of 0 to 5. For example, t and u may each independently be 0 or 1.

When t and u are each 2 or more, two or more of each of R₉ and R₁₀ may each independently be the same or different from each other.

In Chemical Formula 2, * refers to a bonding position, and may also indicate a bonding position in descriptions below.

In an embodiment, at least one of R₃ to R10 may be deuterium.

The condensed heterocyclic compound according to embodiments may be represented by any one of Chemical Formulae 1-1 to 1-6.

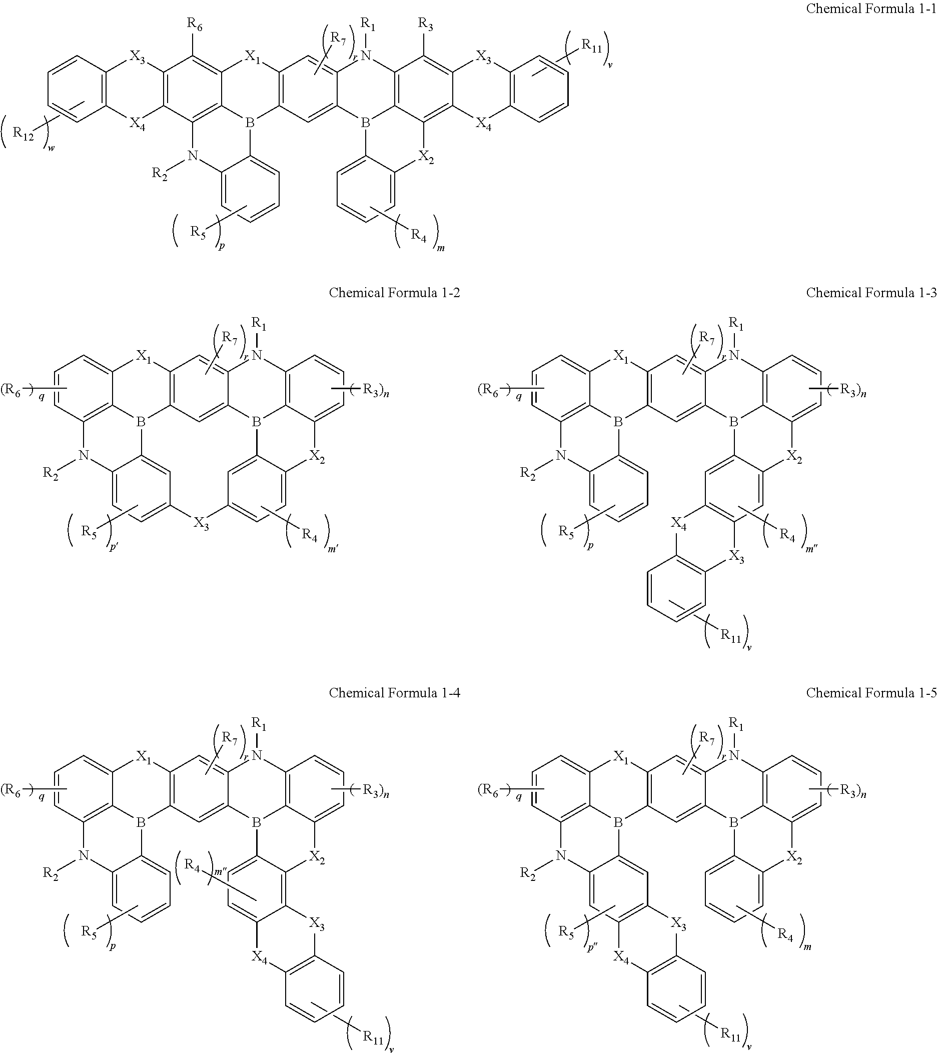

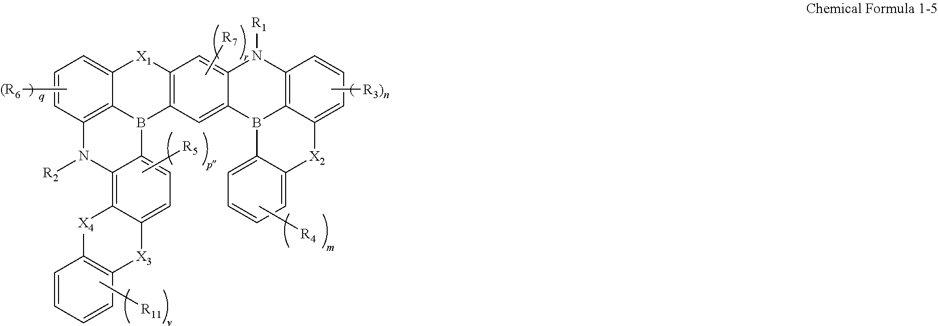

In Chemical Formulae 1-1 to 1-6, the above definitions of, X₁ and X₂, R₁ to R₇, n, m, p, q and r may be equally applied.

In Chemical Formulae 1-1 to 1-6, X₃ and X₄ may each independently be a direct bond, O, S, Se, NR or CRR′. For example, X₃ and X₄ may each independently be a direct bond, O, S or CRR′.

In an embodiment, in Chemical Formula 1-1, two or more of X₃ may be the same or different from each other, and two or more of X₄ may be the same or different from each other. Two or more of X₃ and two more of X4ₛ may be the same or different from each other.

In an embodiment, in Chemical Formulae 1-3 to 1-6, one of X₃ and X₄ may be a direct bond, and the other may be O, S, Se, NR or CRR′. For example, in Chemical Formulae 1-3 to 1-6, one of X₃ and X₄ may be a direct bond, and the other may be O or S.

In Chemical Formulae 1-1 to 1-6, R₁₁ and R₁₂ may each independently be hydrogen, deuterium, halogen, a cyano group, a hydroxyl group, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group, a substituted or unsubstituted C₈-C₆₀ condensed polycyclic group, —SiRR′R″, —P(═O)RR′, —NRR′, —BRR′, —C(═O)RR′ or —S(═O)₂R.

In an embodiment, R₁₁ and R₁₂ may each independently be hydrogen, deuterium, a substituted or unsubstituted C₁-C₂₀ alkyl group, a substituted or unsubstituted C₂-C₂₀ alkenyl group, a substituted or unsubstituted C₂-C₂₀ alkynyl group, a substituted or unsubstituted C₁-C₂₀ alkoxy group, a substituted or unsubstituted C₃-C₄₀ cycloalkyl group, a substituted or unsubstituted C₅-C₄₀ cycloalkenyl group, a substituted or unsubstituted C₃-C₄₀ heterocycloalkyl group, a substituted or unsubstituted C₃-C₄₀ heterocycloalkenyl group, a substituted or unsubstituted C₆-C₄₀ aryl group, a substituted or unsubstituted C₂-C₄₀ heteroaryl group, a substituted or unsubstituted C₆-C₄₀ aryloxy group, a substituted or unsubstituted C₆-C₄₀ arylthio group, a substituted or unsubstituted C₈-C₄₀ condensed polycyclic group, —SiRR′R″, —P(═O)RR′, —NRR′, —BRR′, —C(═O)RR′ or —S(═O)₂R.

The definitions of R, R′ and R″ may be equally applied.

For example, R and R′ may each independently be a substituted or unsubstituted C₆-C₂₀ aryl group, or a substituted or unsubstituted C₂-C₂₀ heteroaryl group.

In Chemical Formula 1-1 and Chemical Formulae 1-3 to 1-6, v and w may each independently be an integer from 0 to 4. When v and w are 2 or more, two or more of each of R₁₁ and R₁₂ may each independently be the same as or different from each other.

In Chemical Formula 1-2, p′ and m′ may each independently be an integer from 0 to 3. When p′ and m′ are 2 or more, two or more of each of R₄ and R₅ may each independently be the same as or different from each other.

In Chemical Formulae 1-3 to 1-6, p″ and m″ may each independently be 0, 1 or 2. When p″ and m″ are 2 or more, two or more of each of R₄ and R₅ may each independently be the same as or different from each other.

The condensed heterocyclic compound according to embodiments may be represented by Chemical Formula 1-7.

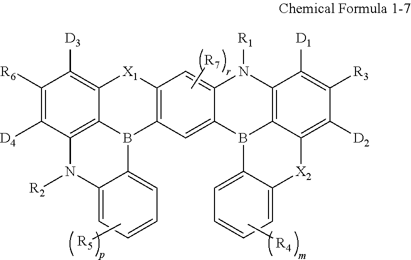

In Chemical Formula 1-7, the above definitions of X₁ and X₂, R₁ to R₇, m, p and r may be equally applied.

In Chemical Formula 1-7, D₁ to D₄ may each independently be hydrogen or deuterium. In an embodiment, D₁ to D₄ may be hydrogen. In an embodiment, at least one of D₁ to D₄ may be deuterium.

A degree of deuterium substitution of the condensed heterocyclic compound according to embodiments may be in a range from 0% to 100%. The degree of deuterium substitution may be a value calculated as a percentage of the number of deuterium atoms relative to the sum of the number of hydrogen atoms and the number of deuterium atoms included in the compound. For example, the degree of deuterium substitution of benzene substituted with 5 deuterium atoms may be about 83.33%.

The degree of deuterium substitution of the condensed heterocyclic compound according to an embodiment may be in a range from 1% to 100%, from 5% to 100%, from 20% to 100%, from 30% to 100%, from 40% to 100%, or from 50% to 100%.

The degree of deuterium substitution of the condensed heterocyclic compound according to an embodiment may be in a range from 0% to 90%, from 0% to 80%, from 0% to 70%, from 0% to 60%, or from 0% to 50%.

The condensed heterocyclic compound according to embodiments may include at least one of compounds represented by chemical formulae below:

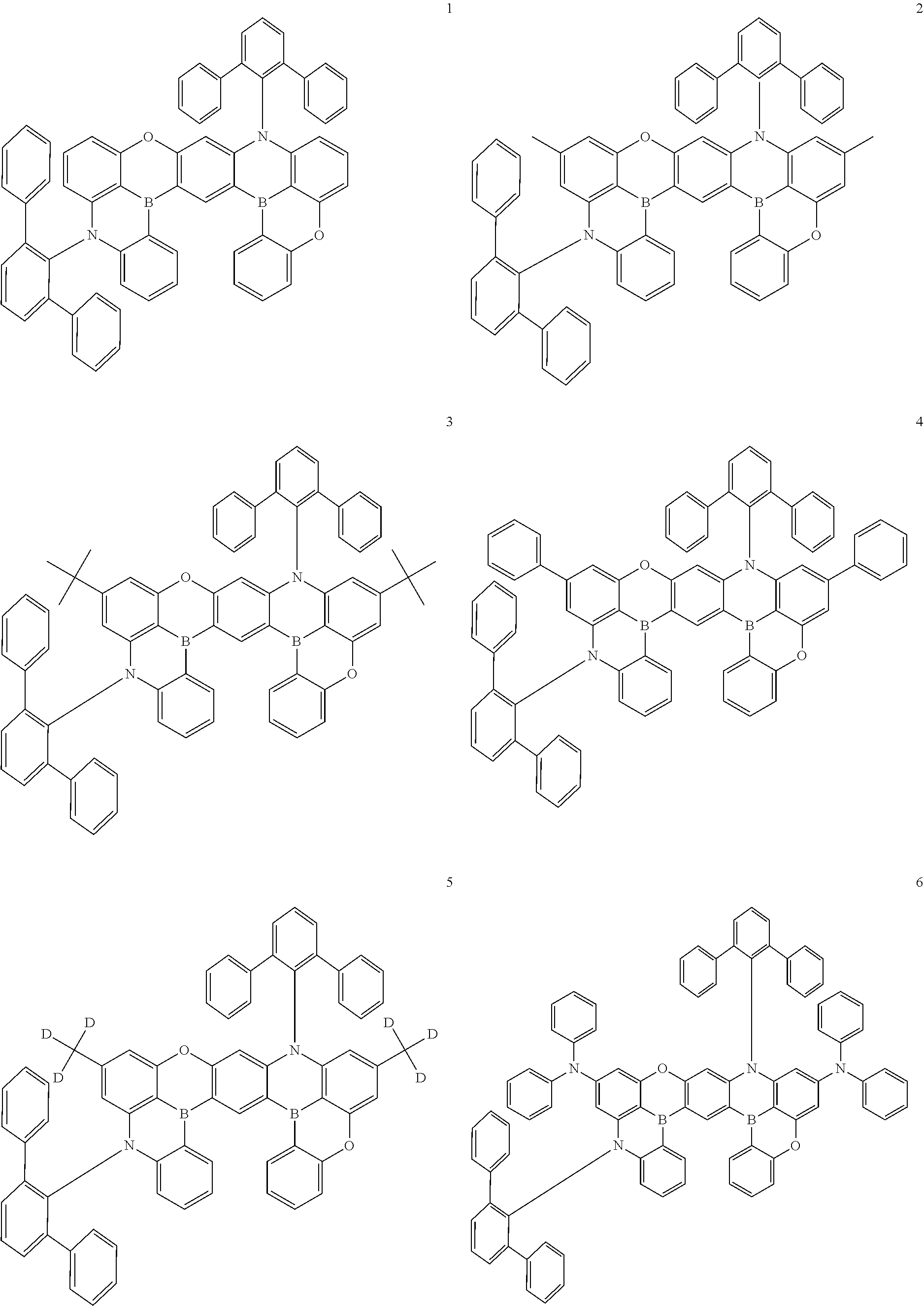

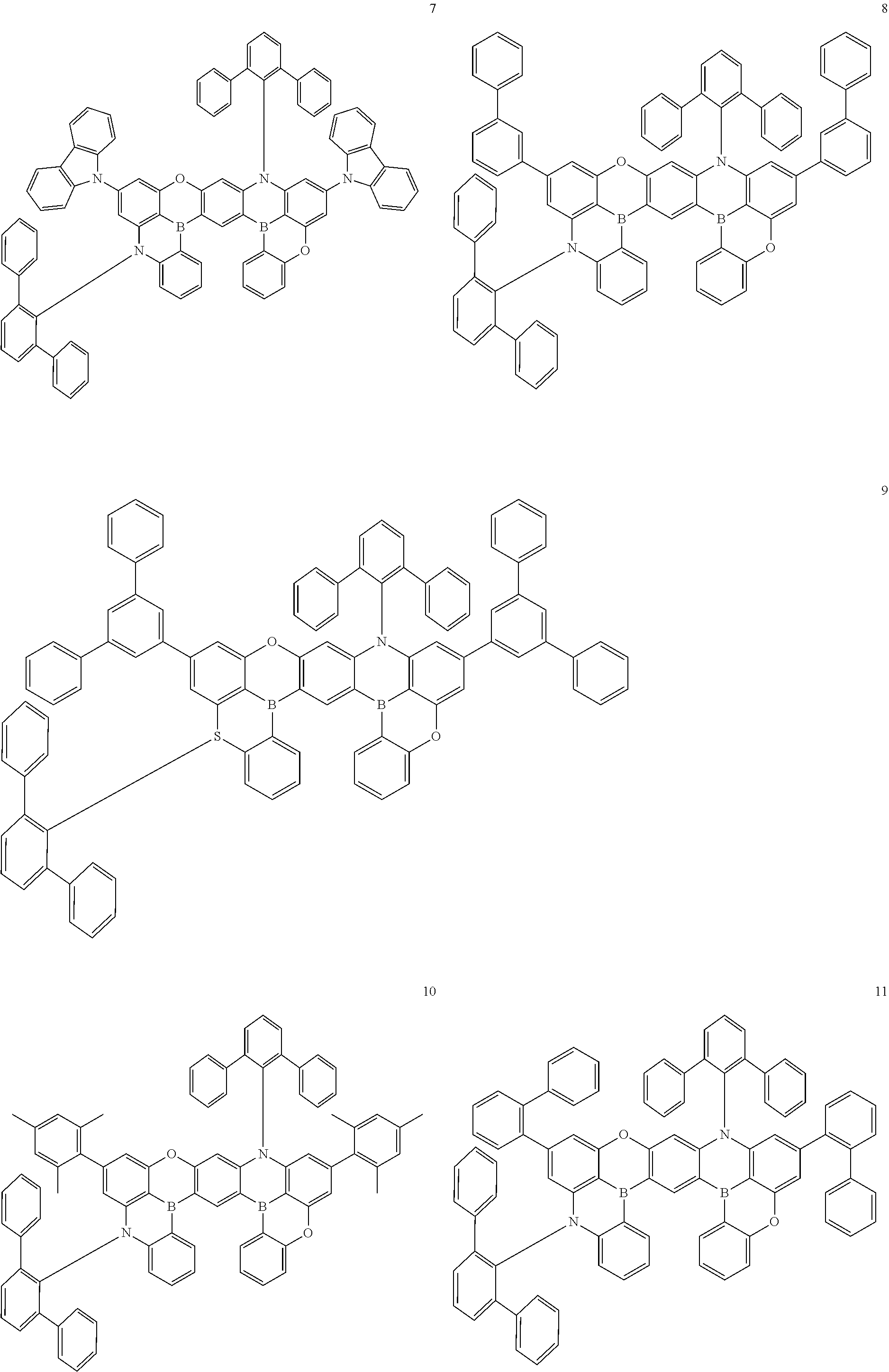

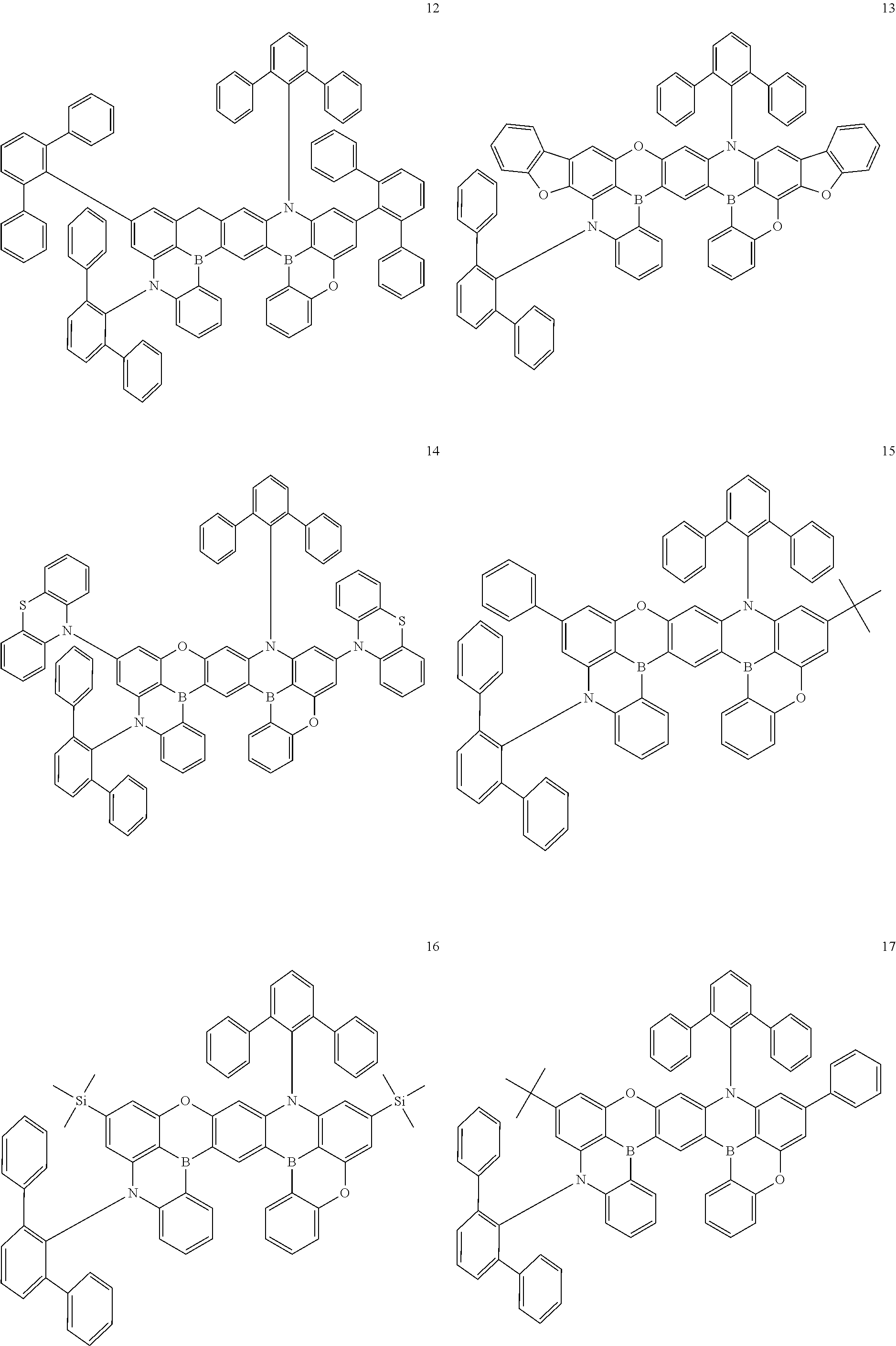

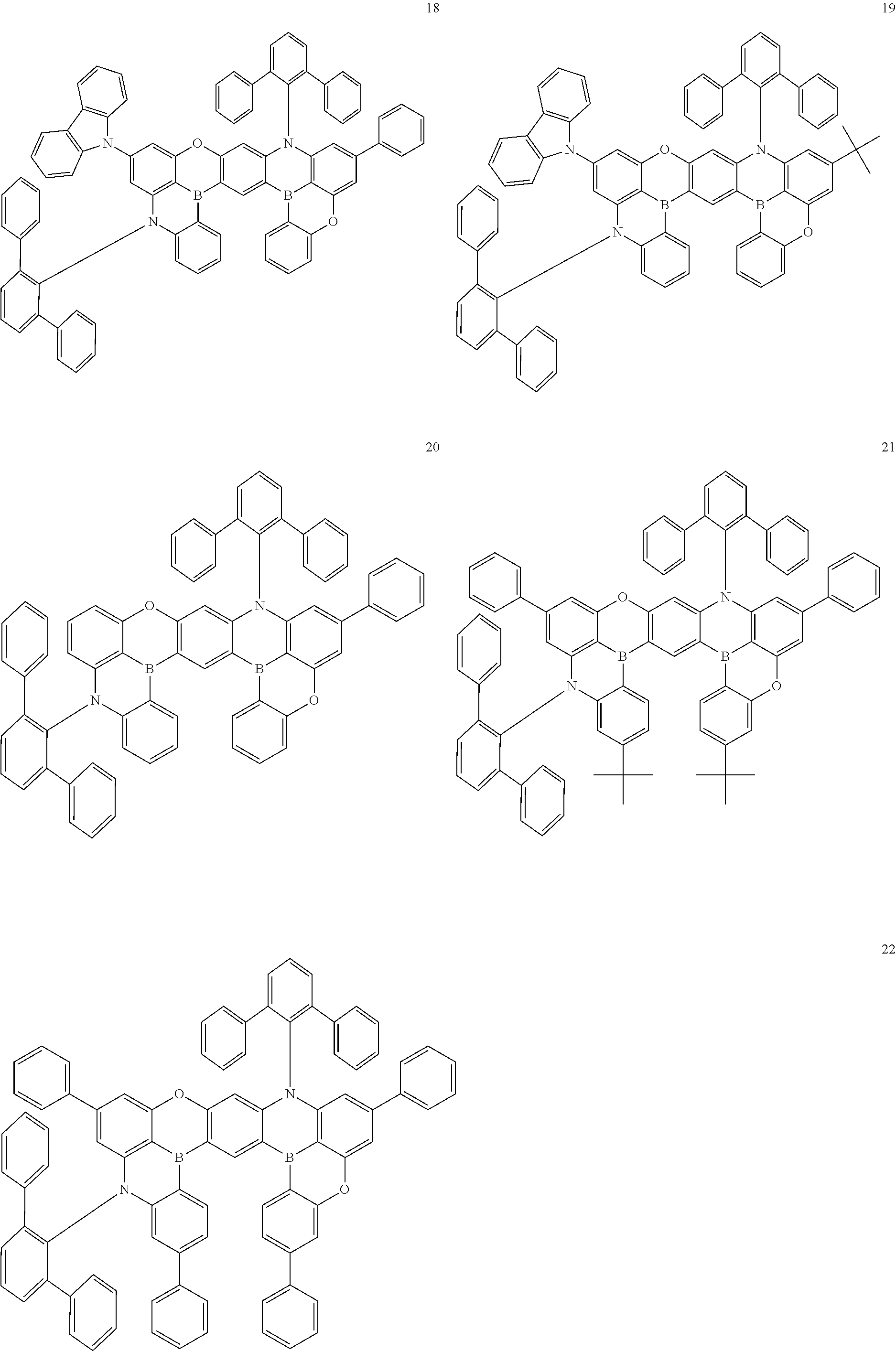

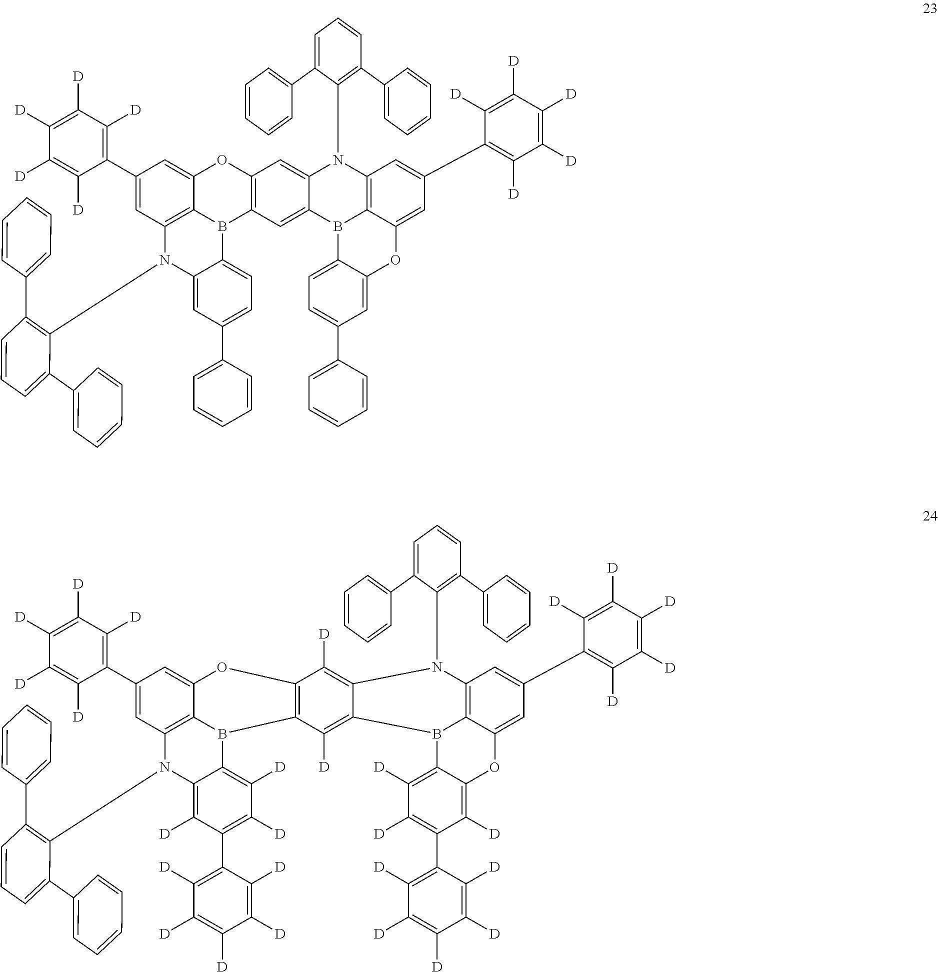

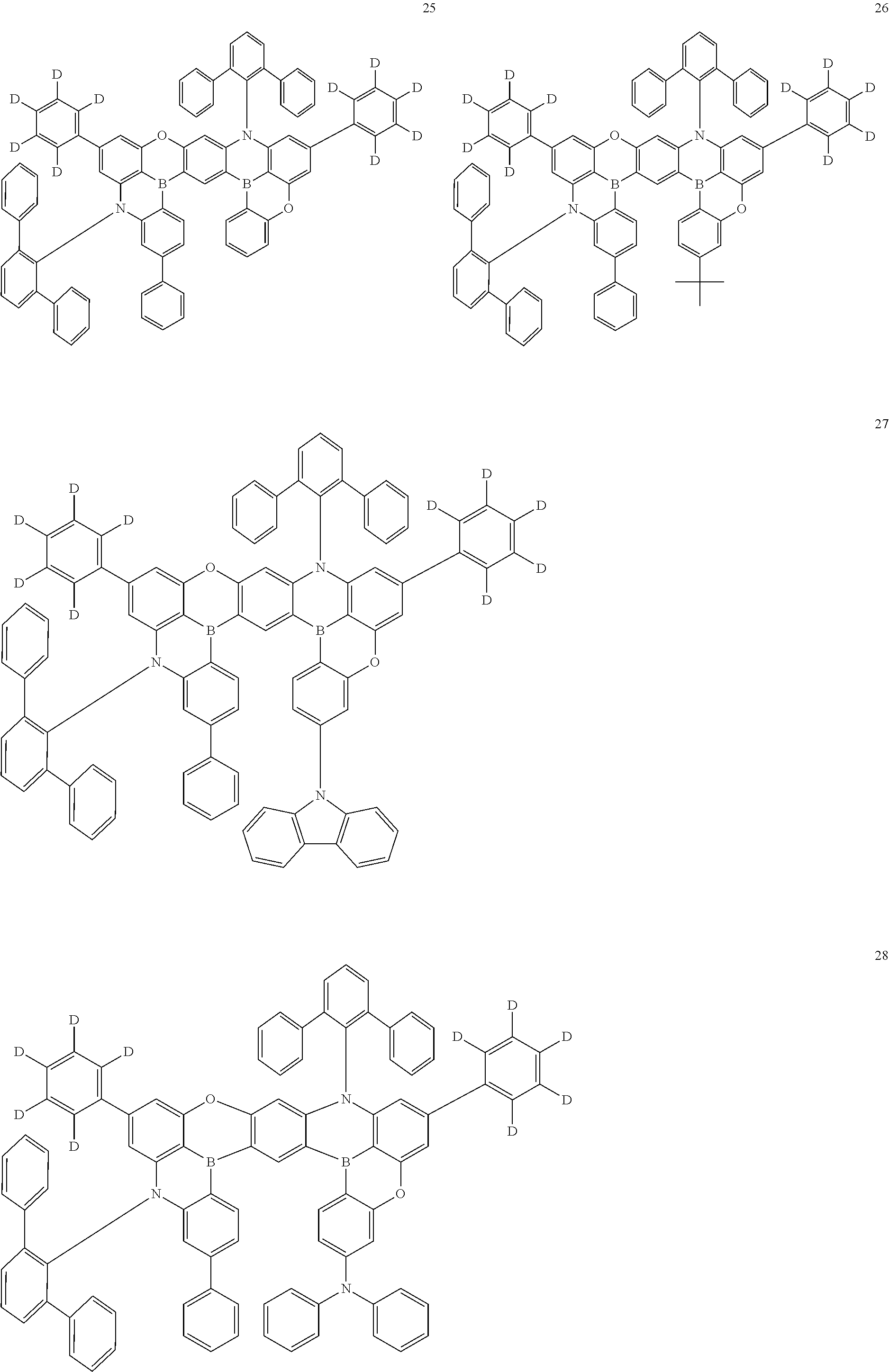

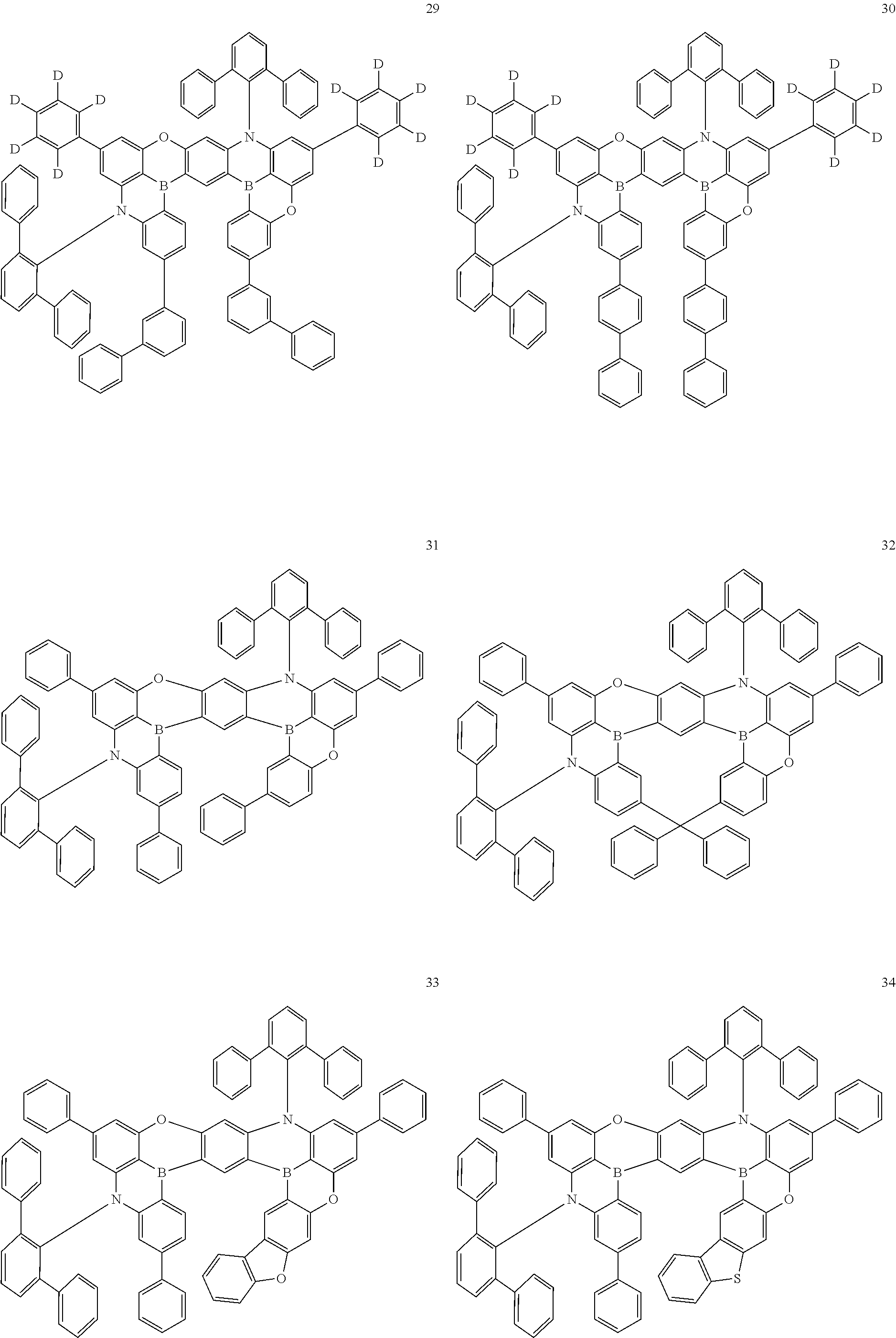

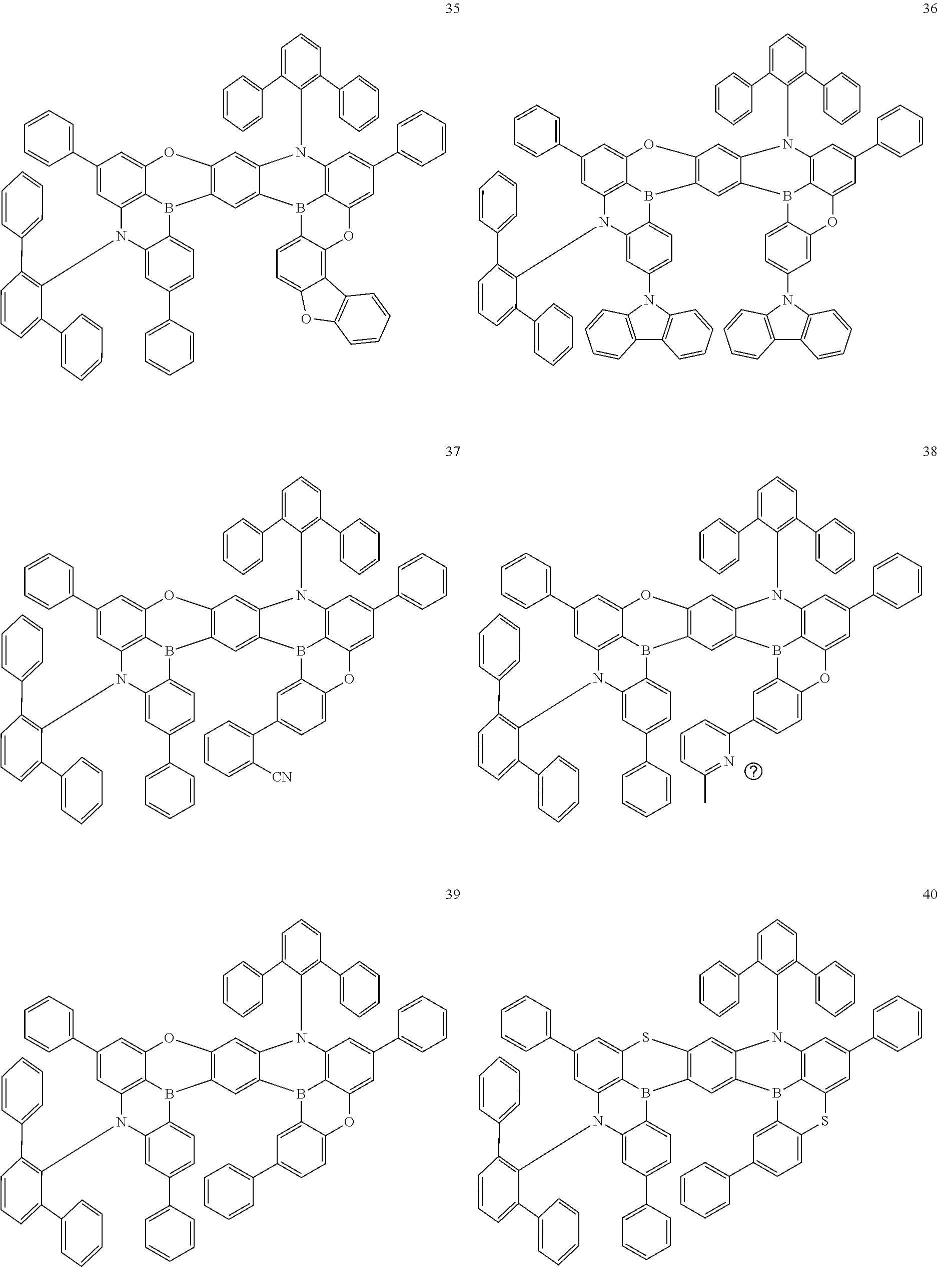

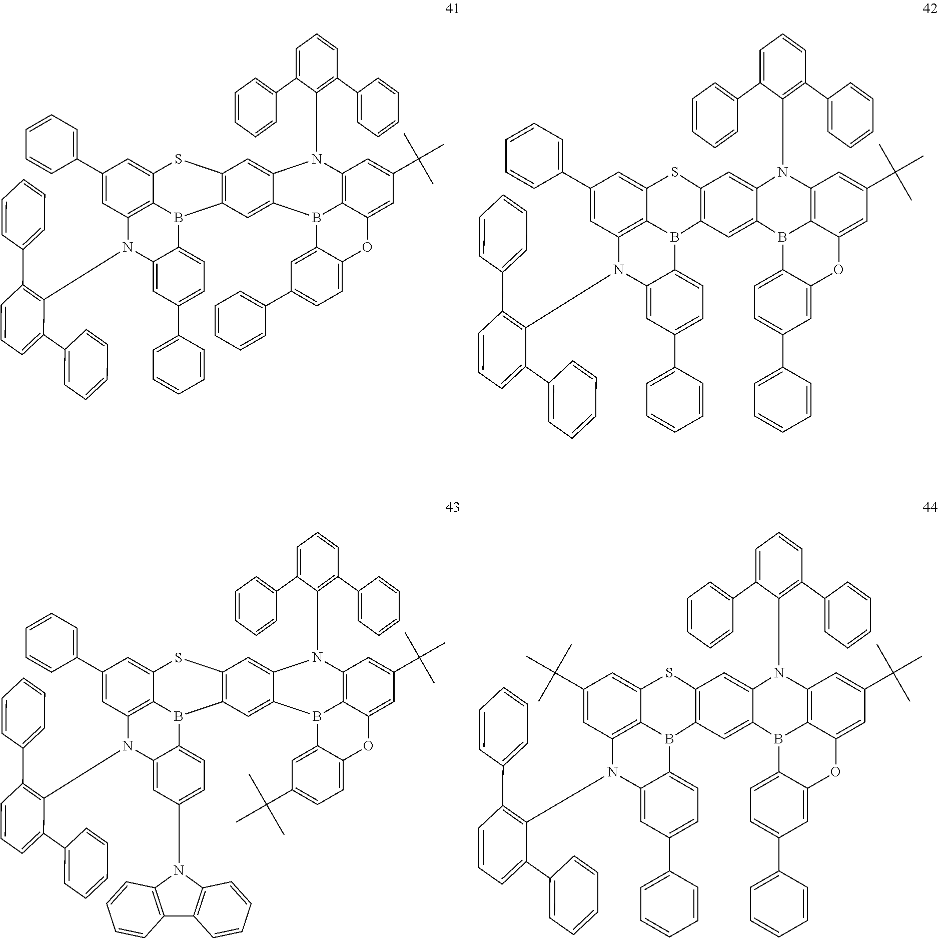

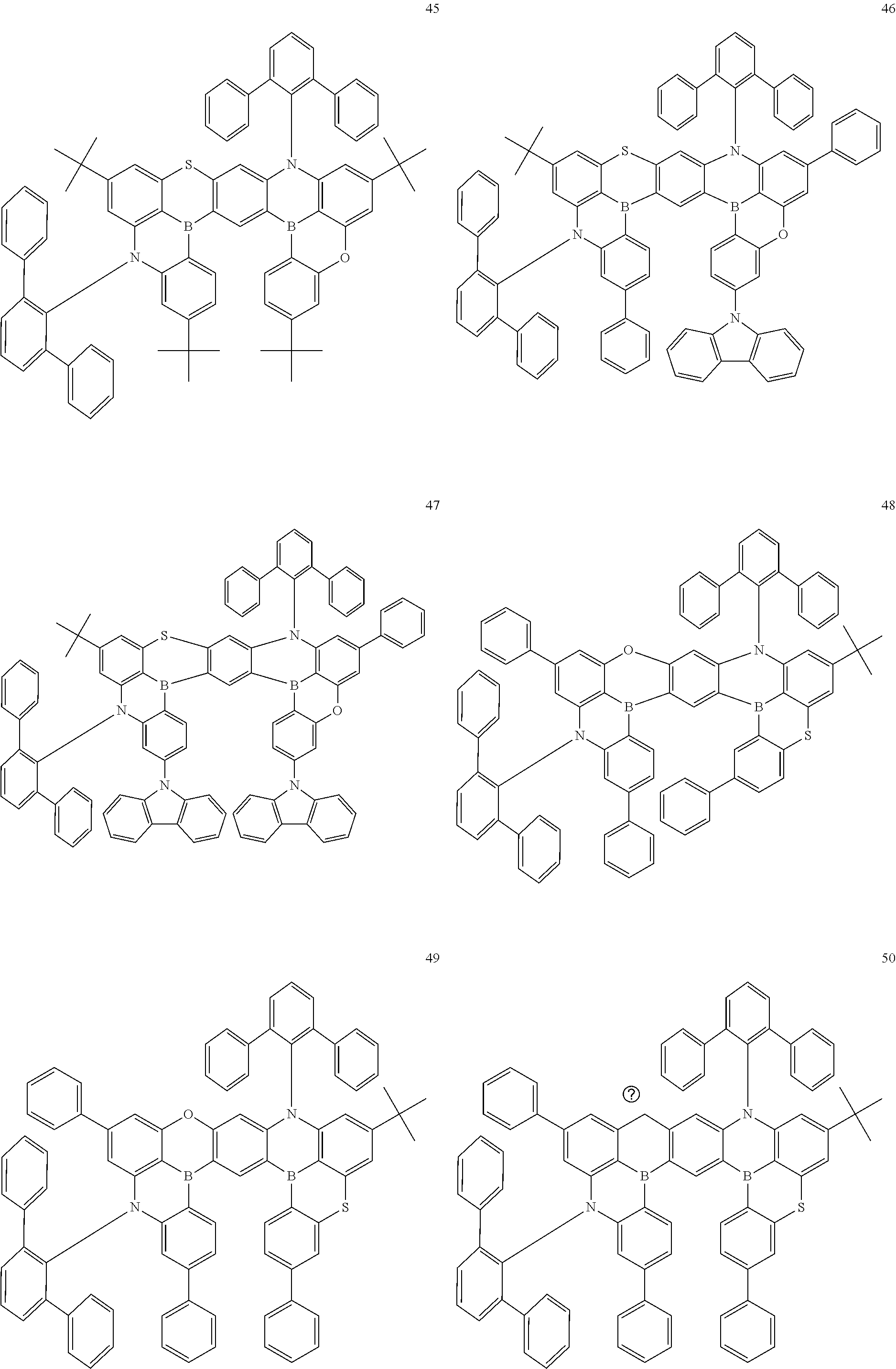

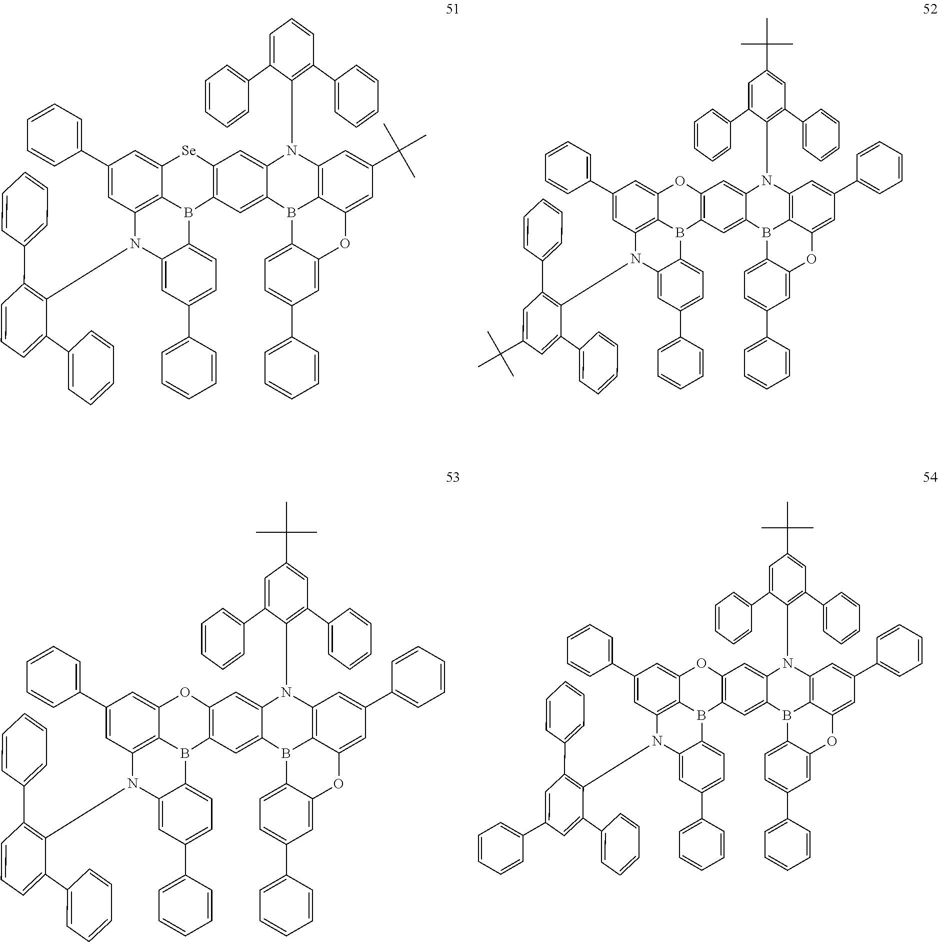

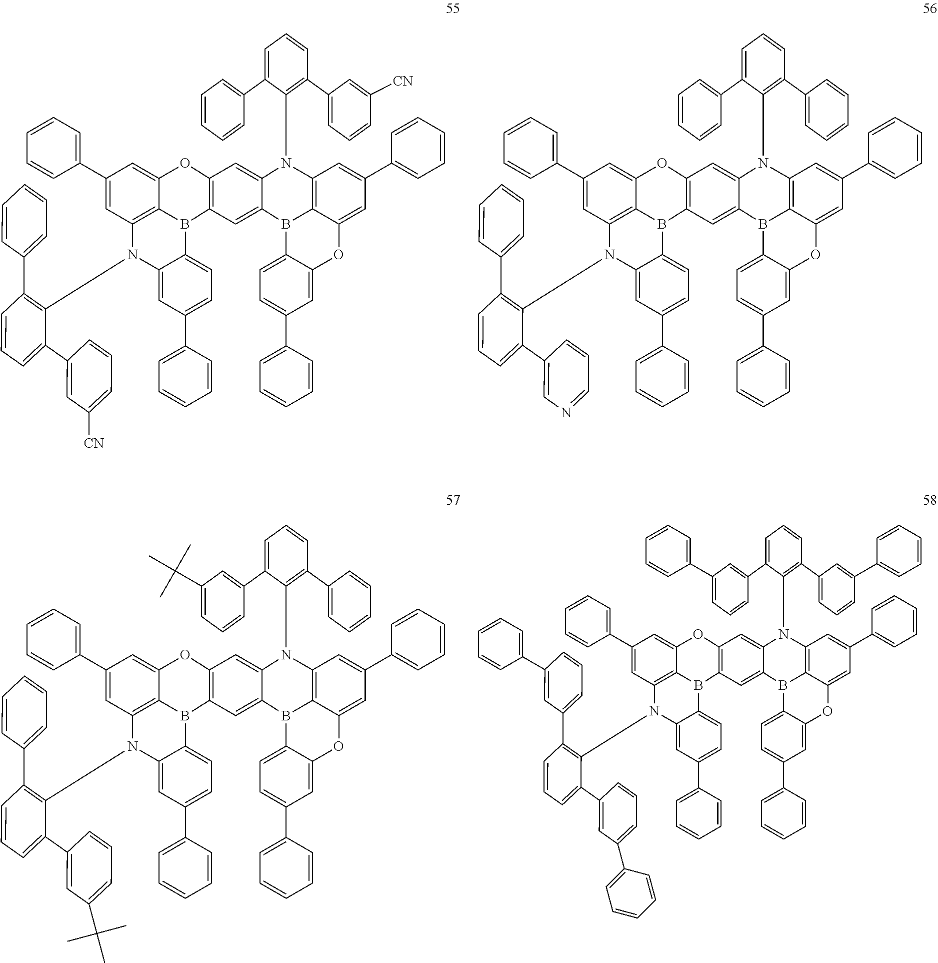

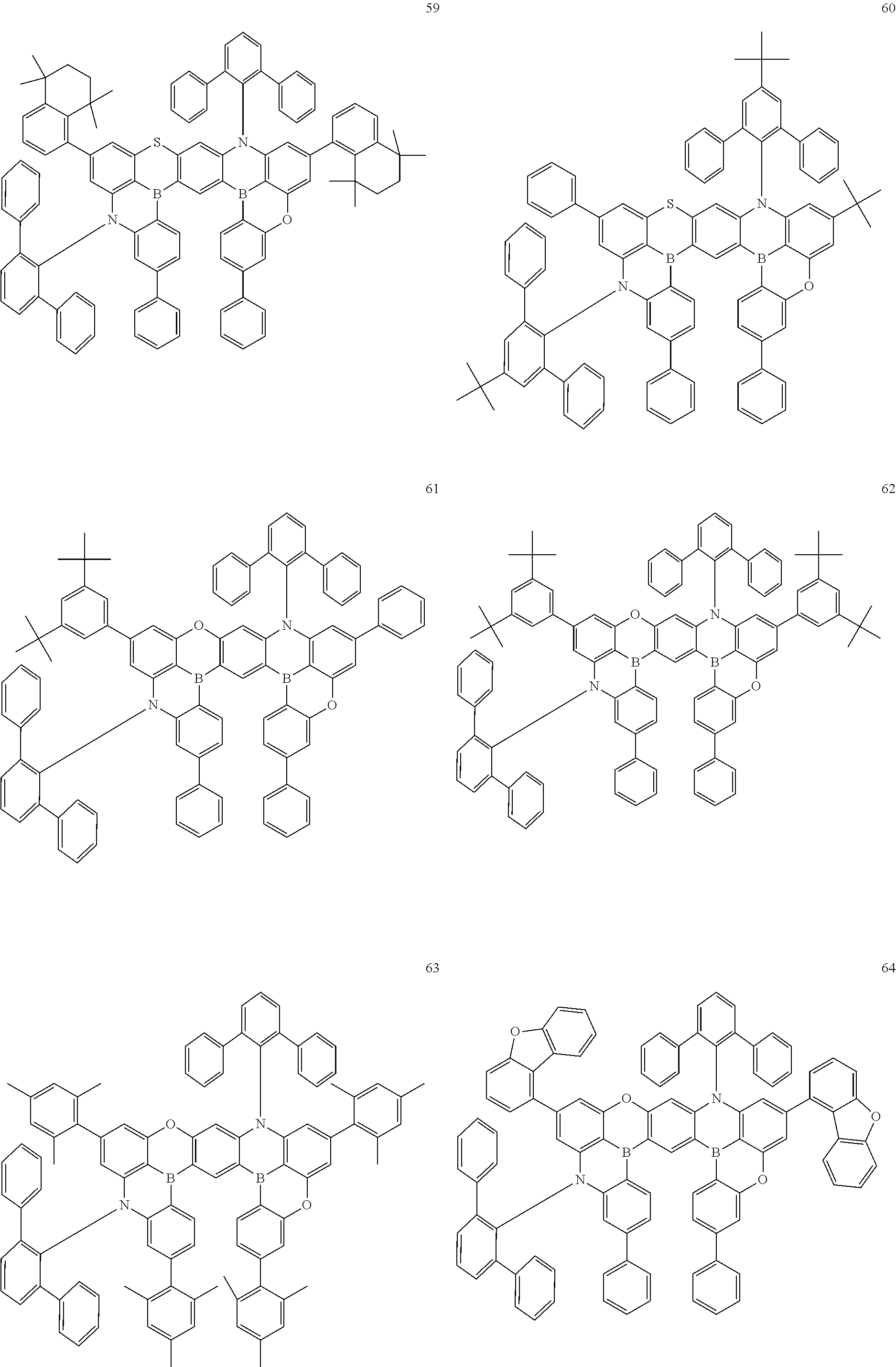

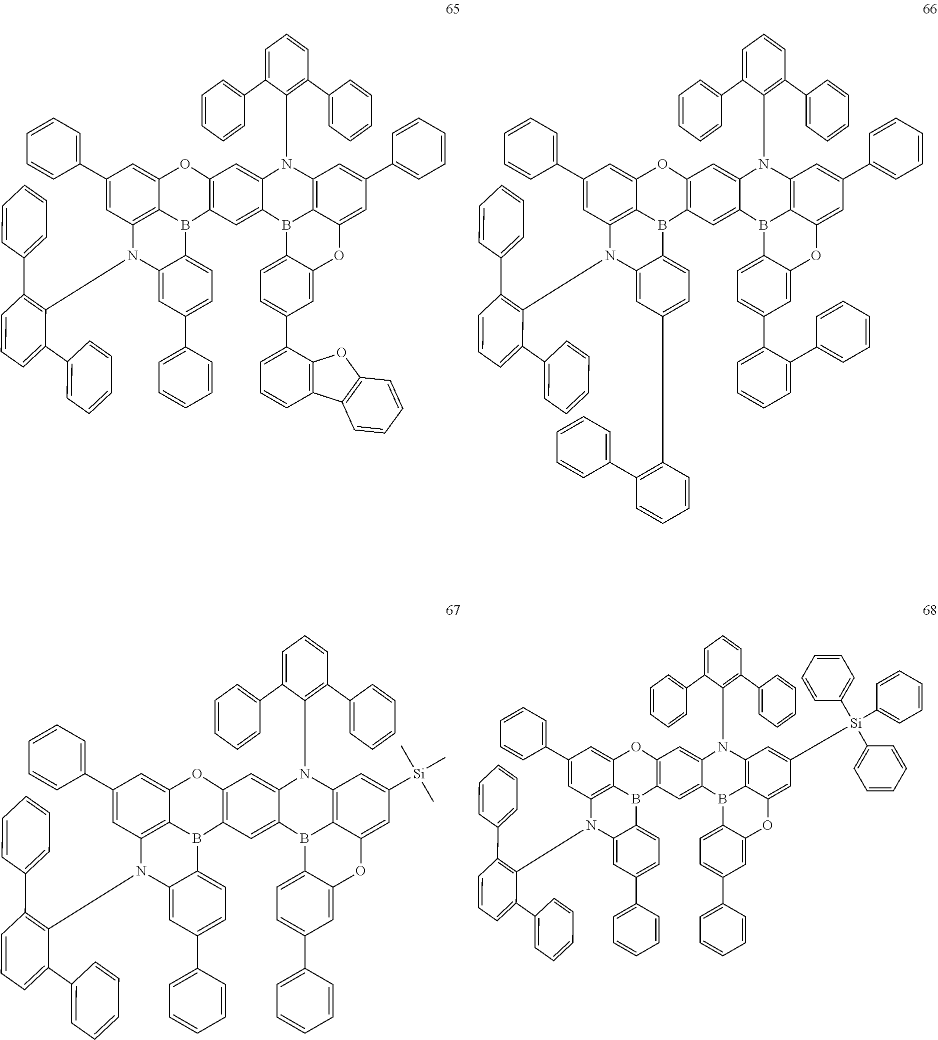

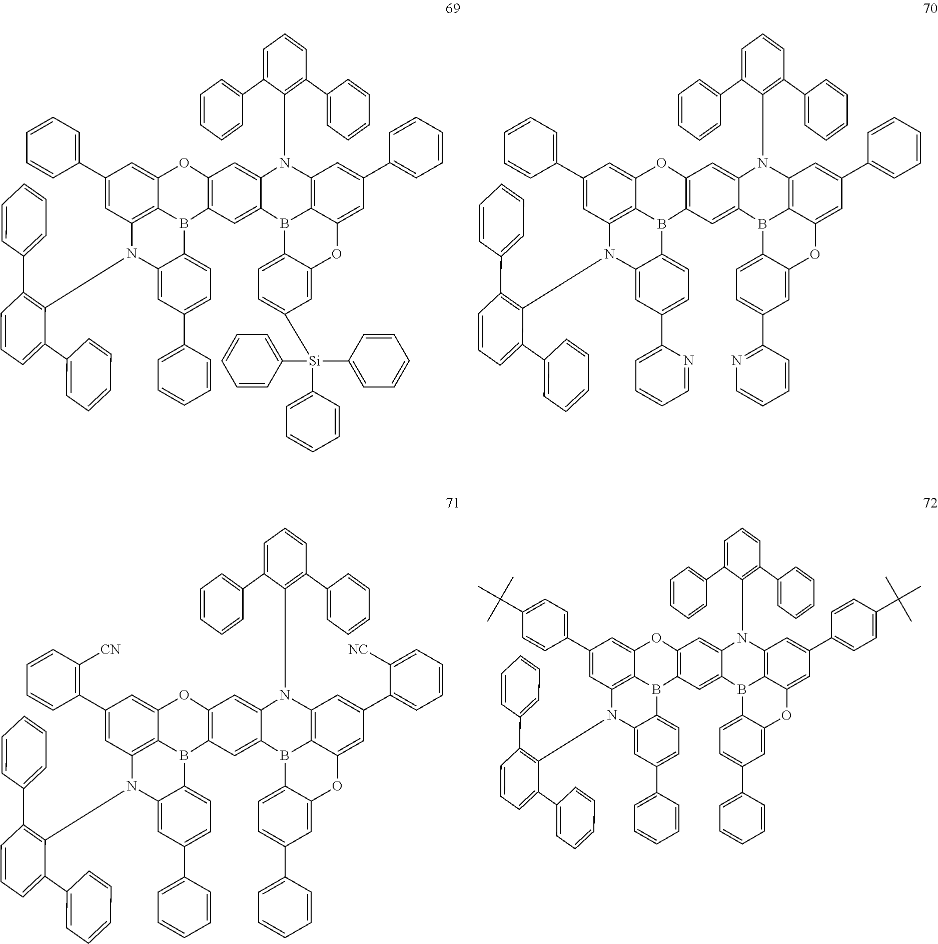

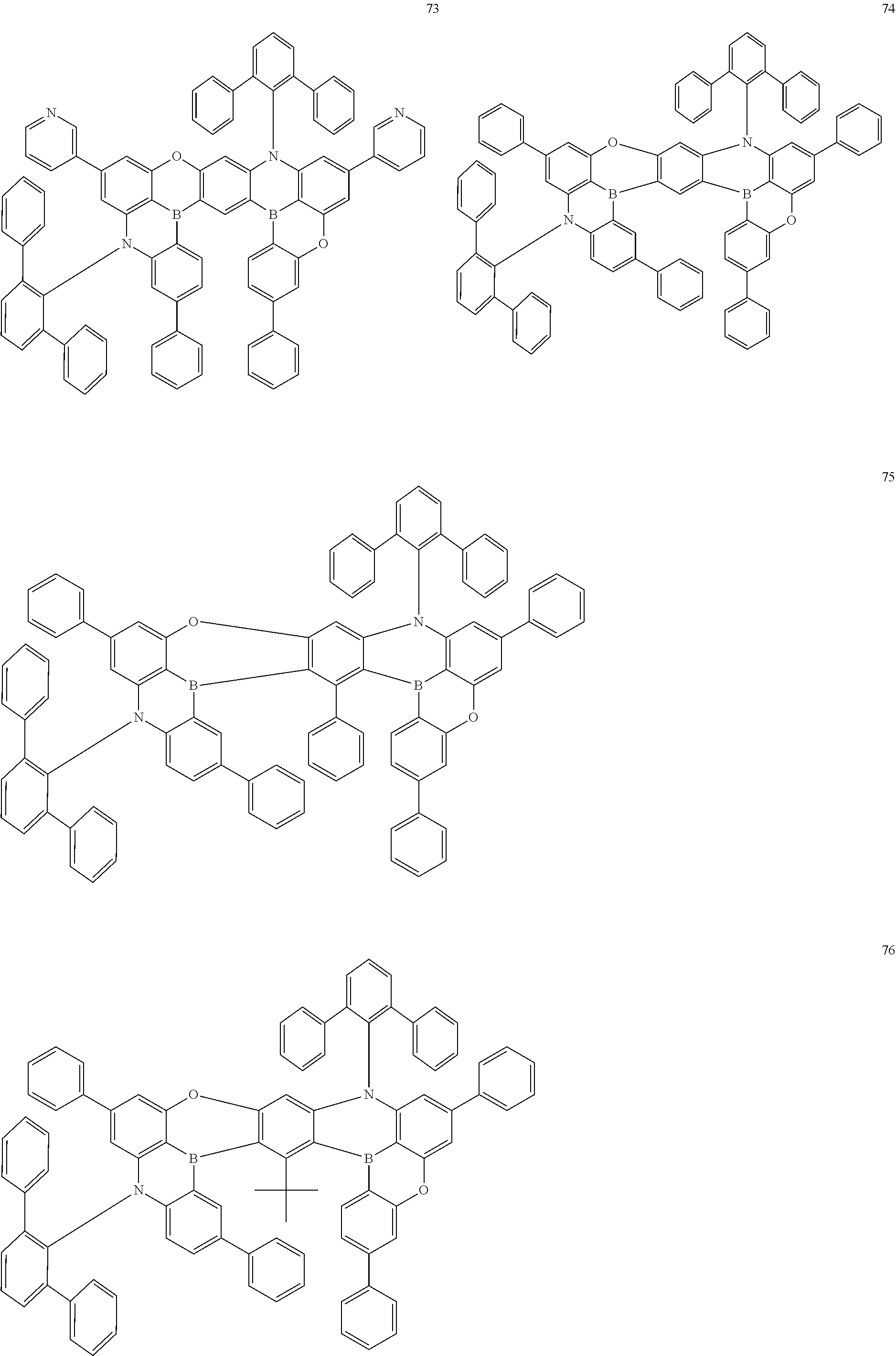

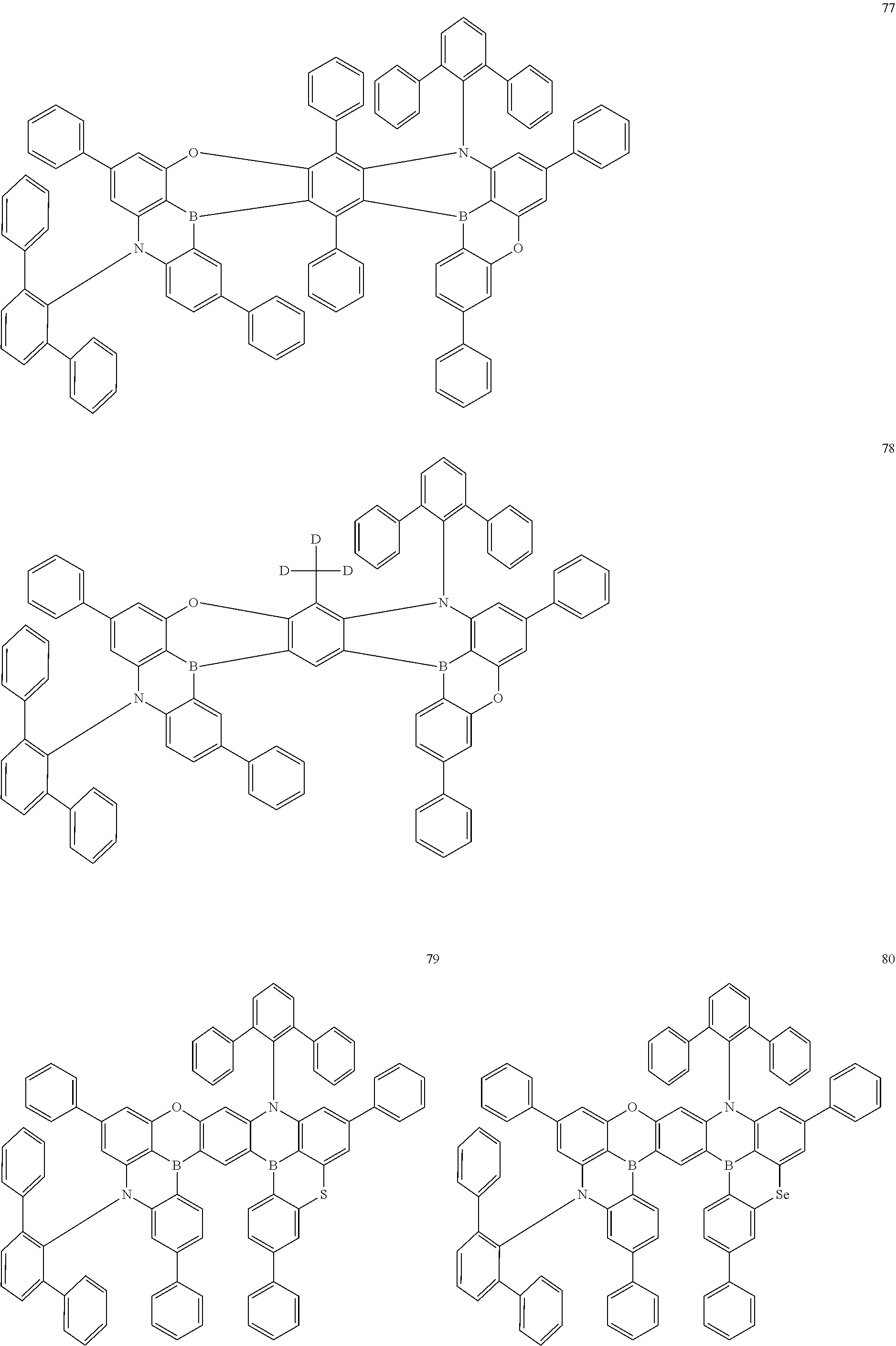

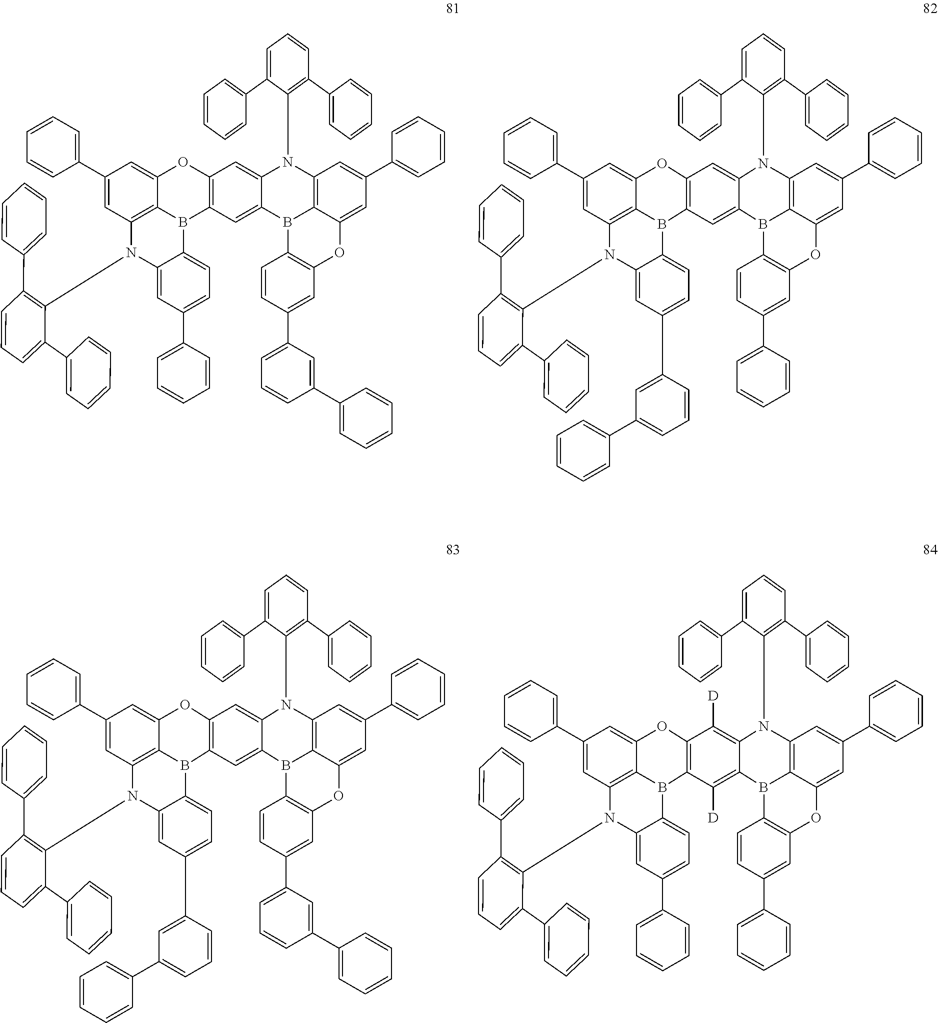

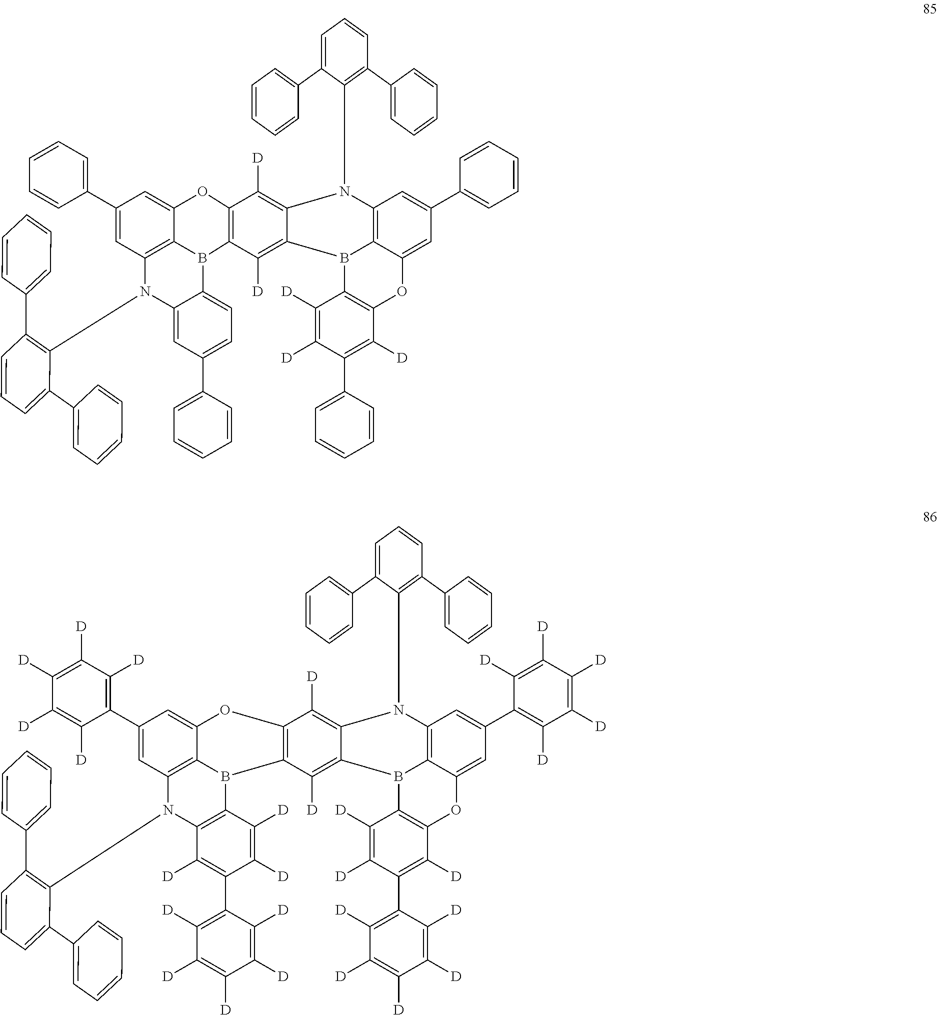

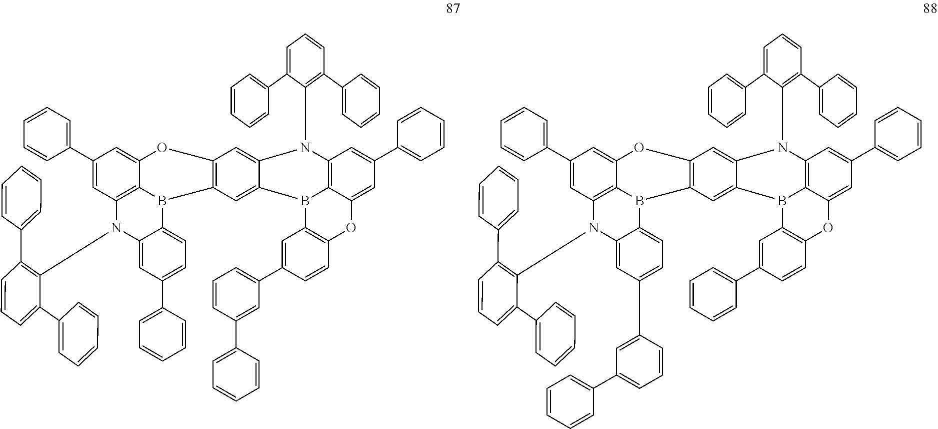 [SMILES: c1ccc(-c2cccc(-c3ccc4c(c3)B3c5cc6c(cc5N(c5c(-c7ccccc7)cccc5-c5ccccc5)c5cc(-c7ccccc7)cc(c53)O4)Oc3cc(-c4ccccc4)cc4c3B6c3ccc(-c5ccccc5)cc3N4c3c(-c4ccccc4)cccc3-c3ccccc3)c2)cc1 ; c1ccc(-c2cccc(-c3ccc4c(c3)N(c3c(-c5ccccc5)cccc3-c3ccccc3)c3cc(-c5ccccc5)cc5c3B4c3cc4c(cc3O5)N(c3c(-c5ccccc5)cccc3-c3ccccc3)c3cc(-c5ccccc5)cc5c3B4c3cc(-c4ccccc4)ccc3O5)c2)cc1]

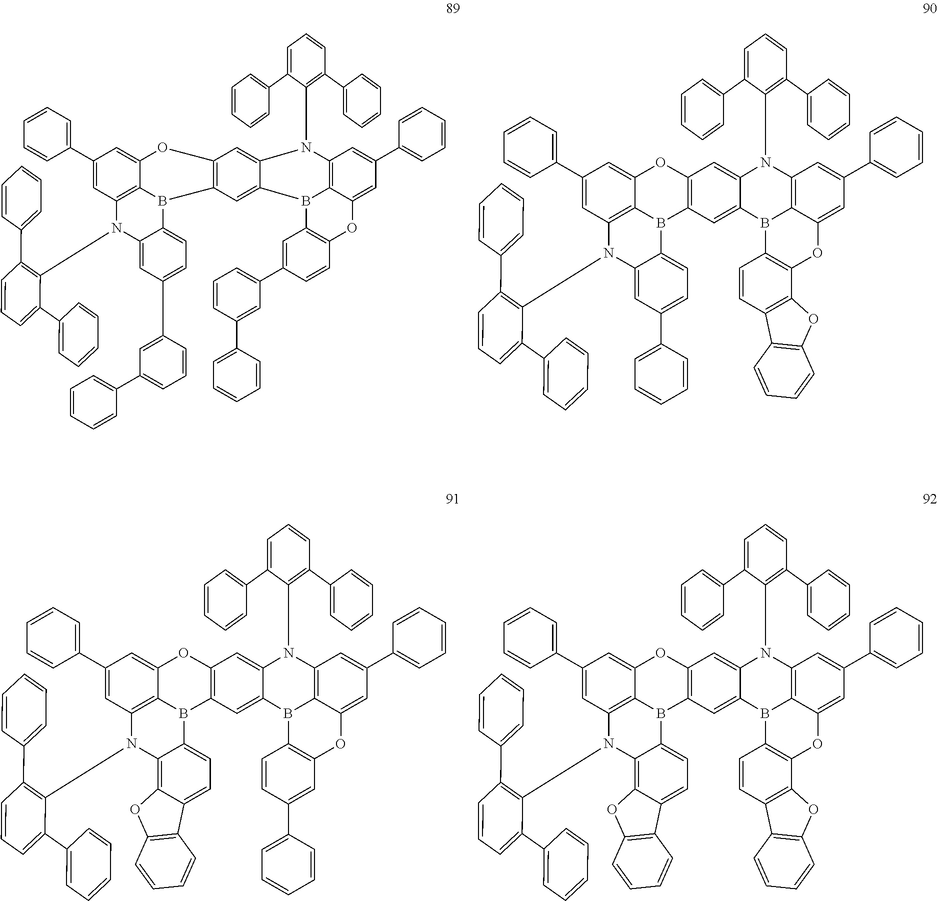

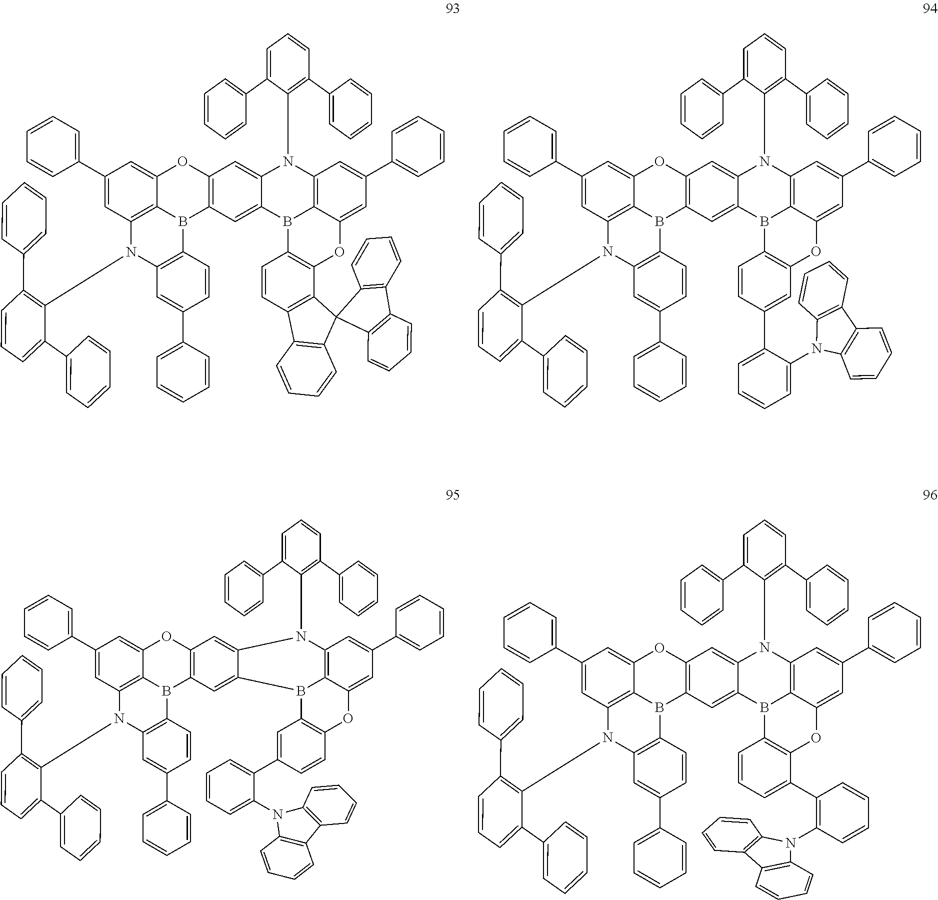

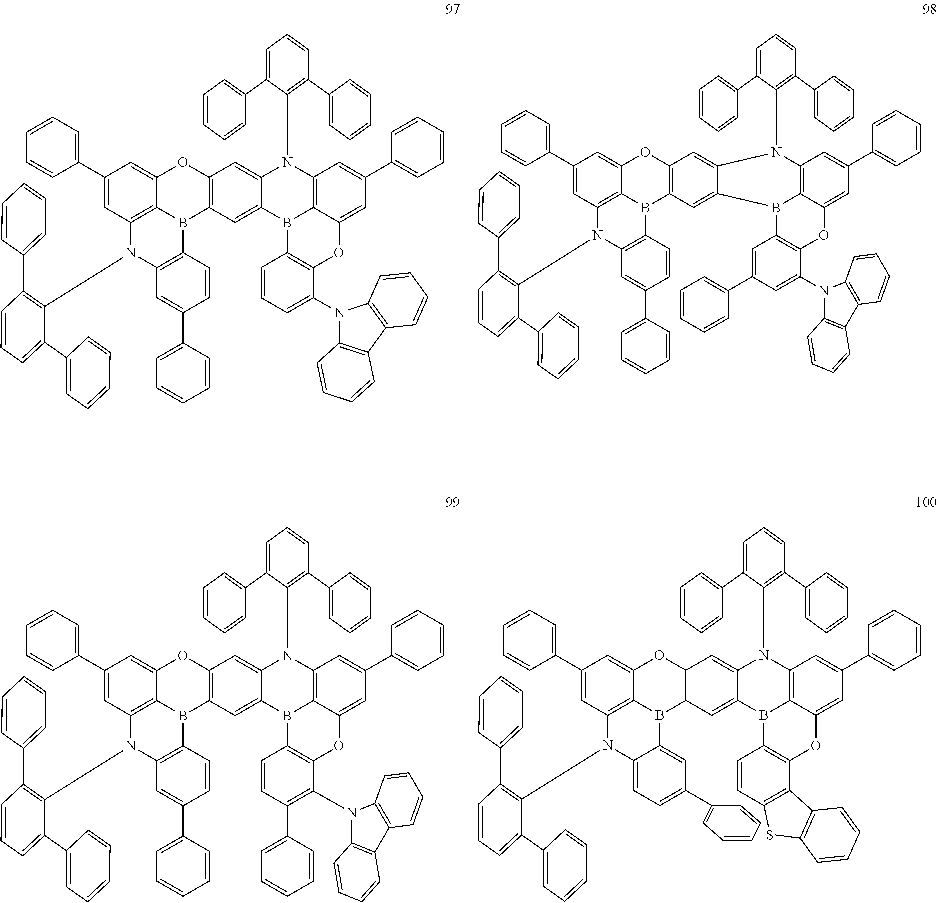

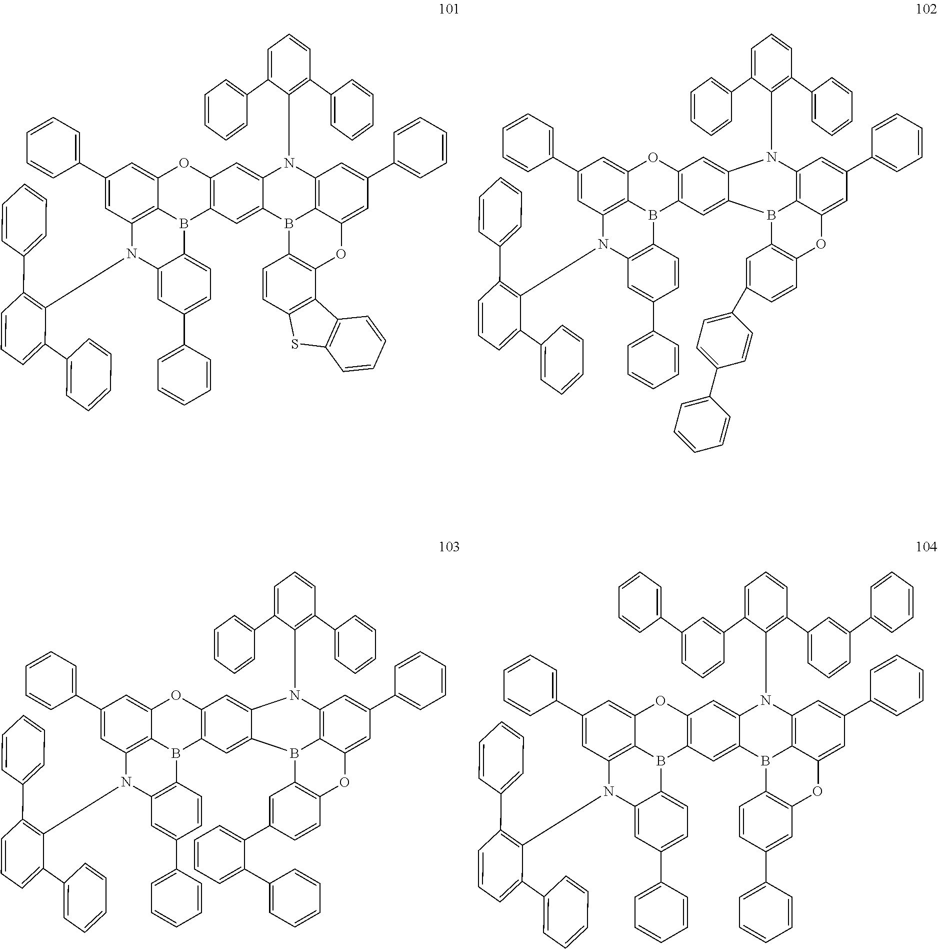

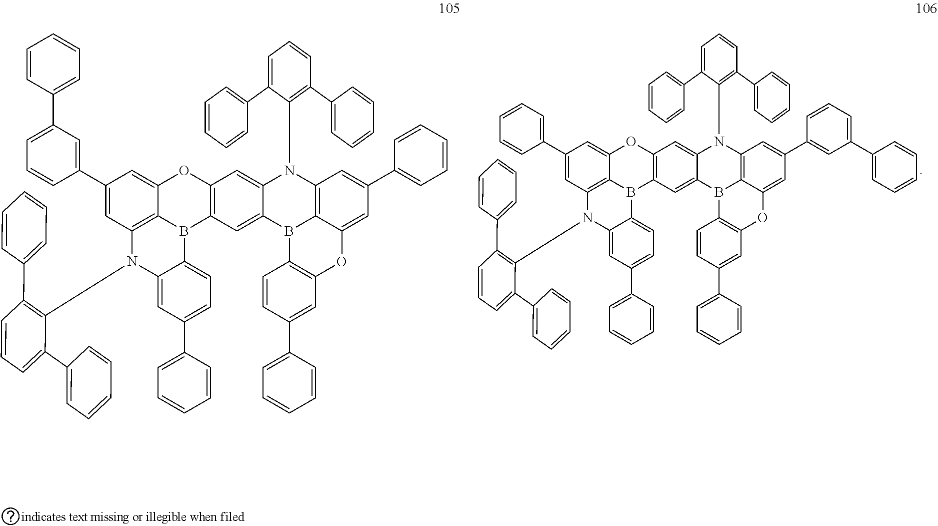

The condensed heterocyclic compound may have a heterocyclic core structure including boron, nitrogen and a chalcogen atom such as O, and may include an ortho-terphenyl moiety bonded to nitrogen. A nitrogen atom includes an unshared electron pair, so that the ortho-terphenyl group may face in a vertical direction based on a light-emitting core plane of the compound. Accordingly, a distance to a host in the emission layer may be increased, and a side reaction due to intermolecular interaction may be reduced, thereby improving life-span properties of the light-emitting device including the compound.

Additionally, the condensed heterocyclic compound may include two nitrogen atoms and may include ortho-terphenyl moieties bonded to each of the nitrogen atoms. Accordingly, the condensed heterocyclic compound may have a balanced molecular structure, and compound decay due to exciton or polaron may be prevented.

In an embodiment, the condensed heterocyclic compound may be included as a dopant in the emission layer of the light-emitting device as described below.

In an embodiment, a HOMO energy level of the condensed heterocyclic compound may be −5.30 electronvolts (eV) or less, in a range from −5.50 eV to −5.30 eV, from −5.45 eV to −5.30 eV, or from −5.40 eV to −5.30 eV. In the above range, life-span of the light-emitting device may be enhanced. In the above Chemical Formula 1, a chalcogen element such as O, S and Se may be arranged at positions X₁ and X₂, so that a deep HOMO energy level may be achieved.

A luminescence (Photoluminescence Quantum Yield, PLQY) of the condensed heterocyclic compound may be 95% or more, 96% or more, or 97% or more.

A difference (Stokes-shift) between a maximum wavelength when the condensed heterocyclic compound absorbs energy and a maximum wavelength when the condensed heterocyclic compound emits energy may be 10 nanometers (nm) or less, 9 nm or less, or 7 nm or less.

A triplet-singlet energy value of the condensed heterocyclic compound may be 0.2 eV or less. Accordingly, triplet excitons may be rapidly obtained as singlet excitons by a reverse inter-system crossing (RISC) mechanism, and efficiency and life-span propertied of the light-emitting device may be further improved.

In an embodiment, the condensed heterocyclic compound may be used as a blue light-emitting dopant.

In an embodiment, a maximum emission wavelength of the blue light may be in a range from 430 nm to 475 nm, from 440 nm to 470 nm, from 440 nm to 460 nm, from 445 nm to 460 nm, or from 450 nm to 460 nm.

In an embodiment, a full width at quarter maximum (FWQM) of the emitted blue light may be 40 nm or less, from 5 nm to 40 nm, from 10 nm to 40 nm, from 15 nm to 40 nm, from 20 nm to 40 nm, 40 nm, from 5 nm to 35 nm, from 10 nm to 35 nm, from 15 nm to 35 nm, from 20 nm to 35 nm, from 5 nm to 30 nm, from 10 nm to 30 nm, from 15 nm to 30 nm, from 20 nm to 30 nm, from 5 nm to 25 nm, from 10 nm to 25 nm, from 15 nm to 25 nm, or from 20 nm to 25 nm.

### Light-Emitting Device

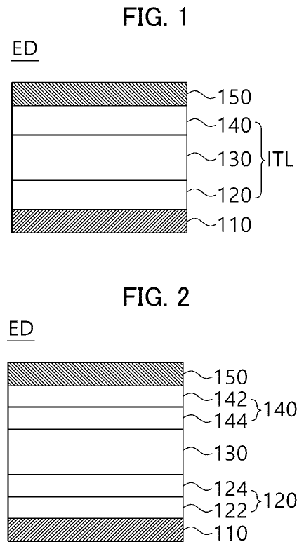

FIGS. 1 to 6 are schematic cross-sectional views illustrating light-emitting devices in accordance with an embodiment.

Referring to FIG. 1, a light-emitting device ED may include a first electrode 110, a second electrode 150, and an intermediate layer ITL interposed between the first electrode 110 and the second electrode 150. The intermediate layer ITL may include an emission layer 130. The intermediate layer ITL may further include a hole transfer region 120 and an electron transfer region 140.

The first electrode 110 may be an anode or a cathode. In an embodiment, the first electrode 110 may be an anode, and may serve as a pixel electrode. In this case, the first electrode 110 may include a conductive material with a high work function that promotes hole injection.

In an embodiment, the first electrode 110 may be a transmissive electrode. The first electrode 110 may include a transparent conductive oxide such as indium tin oxide (ITO), indium zinc oxide (IZO), zinc oxide (ZnO), indium tin oxide (ITZO), or the like.

In an embodiment, the first electrode 110 may be a translucent electrode or a reflective electrode. The first electrode 110 may include at least one of Ag, Mg, Cu, Al, Pt, Pd, Au, Ni, Nd, Ir, Cr, Li, Ca, LiF, Mo, Ti, W, In, Sn, Zn, or an alloy containing at least two therefrom. For example, the first electrode 110 may include Li, Ca, LiF/Ca (a stacked structure of LiF and Ca), LiF/Al (a stacked structure of LiF and Al), a mixture of Ag and Mg, or the like.

The first electrode 110 may have a single-layered structure or a multi-layered structure. For example, the first electrode 110 may have a triple-layered structure of ITO/Ag/ITO.

A thickness of the first electrode 110 may be in a range of about 700 angstroms (Å) to about 10,000 Å. For example, the thickness of the first electrode 110 may be in a range of about 1,000 Å to about 3,000 Å.

The second electrode 150 may be a cathode or an anode. In an embodiment, the second electrode 150 may serve as an electron injection electrode or as a cathode. The second electrode 150 may include a metal, an alloy, an electrically conductive compound, or the like, having a low work function.

For example, the second electrode 150 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or the like. The second electrode 150 may include one of the aforementioned materials, or a combination thereof.

The second electrode 150 may be a transmissive electrode, a translucent electrode, or a reflective electrode. The second electrode 150 may have a single-layered structure or a multi-layered structure.

The emission layer 130 may include the above-described condensed heterocyclic compound. In an embodiment, the condensed heterocyclic compound may serve as a dopant. In an embodiment, the condensed heterocyclic compound may serve as a fluorescent dopant. For example, the condensed heterocyclic compound may serve as a thermally activated delayed fluorescence (TADF) dopant.

In an embodiment, the condensed heterocyclic compound may be included as a blue light-emitting dopant. For example, the condensed heterocyclic compound may be included as a light-emitting material having an emission central wavelength in a range of 430 nm to 490 nm.

In an embodiment, the emission layer 130 may further include a dopant represented by Chemical Formula FD. For example, a compound represented by Chemical Formula FD may be used as a fluorescent dopant.

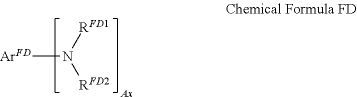

In Chemical Formula FD, Ar^{FD}, R^{FD1}, and R^{FD2} may each independently be a substituted or unsubstituted C₃-C₆₀ carbocyclic group, or a substituted or unsubstituted C₁-C₆₀ heterocyclic group. Ax may be an integer from 1 to 6.

In an embodiment, Ar^{FD} may include a condensed ring structure in which three or more aryl rings or benzene rings are condensed together (e.g., an anthracene group, a chrysene group, a pyrene group, or the like).

In an embodiment, the emission layer 130 may include a phosphorescent dopant. The phosphorescent dopant may include an organometallic compound that includes a central metal and at least one ligand bonded to the central metal via a coordination bond. The central metal may include, e.g., a transition metal, and the ligand may include, e.g., a monodentate ligand, a bidentate ligand, a tridentate ligand, a tetradentate ligand, a pentadentate ligand, a hexadentate ligand, or a combination thereof.

The phosphorescent dopant may include, e.g., a compound represented by Chemical Formula PD.

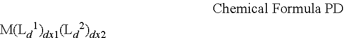

In Chemical Formula PD, M may be a transition metal atom, e.g., iridium (Ir), platinum (Pt), palladium (Pd), osmium (Os), titanium (Ti), gold (Au), hafnium (Hf), europium (Eu), terbium (Tb), rhodium (Rh), rhenium (Re), ruthenium (Ru), copper (Cu), or thulium (Tm).

In Chemical Formula PD, L_{d}¹ may be a ligand represented by Chemical Formula LD1.

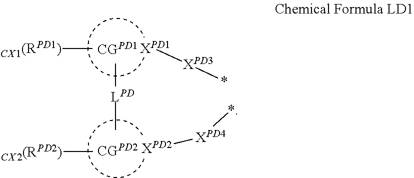

In Chemical Formula LD1, X^{PD1} and X^{PD2} may each independently be carbon (C) or nitrogen (N).

In an embodiment, one of X^{PD1} and X^{PD2} may be C and the other may be N. In an embodiment, X^{PD1} and X^{PD2} may each be N.

In Chemical Formula LD1, CG^{PD1} and CG^{PD2} may each independently be a substituted or unsubstituted C₃-C₆₀ carbocyclic group, or a substituted or unsubstituted C₁-C⁶⁰ heterocyclic group.

For example, CG^{PD1} and CG^{PD2} may each independently be a pyrrole group, a pyrazole group, an imidazole group, a triazole group, an oxazole group, an isoxazole group, a thiazole group, an isothiazole group, an oxadiazole group or a thiadiazole group, a benzene group, a pyridine group, a pyrimidine group, a naphthalene group, a dibenzofuran group, a dibenzothiophene group, a carbazole group, a fluorene group, a dibenzosilole group, a naphthobenzofuran group, a naphthobenzothiophene group, a benzocarbazole group, a benzofluorene group, a naphthobenzosilole group, a dinaphthofuran group, a dinaphthothiophene group, a dibenzocarbazole group, a dibenzofluorene group, a dinaphthosilole group, an azadibenzofuran group, an azadibenzothiophene group, an azacarbazole group, an azafluorene group, an azadibenzosilole group, an azanaphthobenzofuran group, an azanaphthobenzothiophene group, an azabenzocarbazole group, an azabenzofluorene group, an azanaphthobenzosilole group, an azadinapthofuran group, an azadinapthothiophene group, an azadibenzocarbazole group, an azadibenzofluorene group, or an azadinapthosilole group.

In Chemical Formula LD1, L^{PD} may be a single bond, a substituted or unsubstituted methylene group, a substituted or unsubstituted ethylene group, *—O—*, *—S—*′, *—C(═O)—*′, *—N(R^{PD3})—*, *—C(R^{PD4})═*′, or *═C(R^{PD5})—*′.

In Chemical Formula LD1, X^{PD3} and X^{PD4} may each independently be a chemical bond, O, S, N(R^{PD6}), B(R^{PD7}), P(R^{PD8}) C(R^{PD8})(R^{PD9}), or Si(R^{PD10})(R^{PD11}). The chemical bond may be, e.g., a covalent bond or a coordination bond.

In Chemical Formula LD1, R^{PD1} and R^{PD2} may each independently be hydrogen, deuterium, —F, —Cl, —Br, —I, —OH, —CN, —NO₂, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group, a substituted or unsubstituted C₈-C₆₀ condensed polycyclic group, a substituted or unsubstituted silyl group, a substituted or unsubstituted amine group, a substituted or unsubstituted aniline group, —B(R^{PD12})(R^{PD13}), —C(═O)(R^{PD14}), —S(═O)₂(R^{PD15}), or —P(═O)(R^{PD16})(R^{PD17}). The silyl group may be represented by —Si(R^{sa})(R^{sb})(R^{sc}) as described below.

R^{PD3} to R^{PD17} may each independently be hydrogen, deuterium, —F, —Cl, —Br, —I, —OH, —CN, —NO₂, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group, or a substituted or unsubstituted C₈-C₆₀ condensed polycyclic group.

In Chemical Formula LD1, cx1 and cx2 may each independently be an integer from 0 to 10. When at least one of cx1 and cx2 is 2 or more, two or more of R^{PD1} or two or more of R^{PD2} may be the same as or different from each other.

The symbols -* and -*′ each represent a binding site where the ligand represented by Chemical Formula LD1 bonds to M.

In Chemical Formula PD, dx1 may be an integer from 1 to 3. When dx1 is 2 or 3, two or three of L_{d}¹ may be the same as or different from each other. Among two or three of L_{d}¹, CG^{PD1} and/or CG^{PD2} adjacent to each other may be connected to each other through a connecting group such as L^{PD1}, L^{PD2}, or the like. The connecting group such as L^{PD1}, L^{PD2}, or the like, may each independently be the same as defined in connection with L^{PD}.

In Chemical Formula PD, L_{d}² may be an organic ligand. L_{d}² may include, e.g., a halogen group, CO, NO, CS, picolinate, acetate, oxalate, a diketone group, an isonitrile group, isothiocyanato-N, thiosulphato-S, an alkyl phosphine, phenylphosphine, an aryl phosphine, phosphine oxide, phosphite, or a combination thereof.

In Chemical Formula PD, dx2 is an integer of 1 to 4. When dx2 is 2 or more, two or more of L_{d}² may be the same as or different from each other.

In an embodiment, the emission layer 130 may include a styryl derivative (e.g., 1,4-bis[2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (NBDAVBi)), 4,4′-bis[2-(4-(N,N-diphenylamino)phenyl)vinyl]biphenyl (DPAVBi), perylene or a derivative thereof (e.g., 2,5,8,11-tetra-t-butylperylene (TBP)), pyrene or a derivative thereof (e.g., 1,1-dipyrene, 1,4-dipyrenylbenzene, 1,4-bis(N,N-diphenylamino)pyrene)), or the like, as a fluorescent dopant material.

The emission layer 130 may include a metal complex that includes iridium (Ir), platinum (Pt), osmium (Os), gold (Au), titanium (Ti), zirconium (Zr), hafnium (Hf), europium (Eu), terbium (Tb), or thulium (Tm) as a phosphorescent dopant, in addition to the materials described above. For example, FIrpic (iridium(III) bis(4,6-difluorophenylpyridinato-N,C2′)picolinate), FIr6 (bis(2,4-difluorophenylpyridinato)-tetrakis(1-pyrazolyl)borate iridium(III)), PtOEP (platinum octaethyl porphyrin), or the like, may be used as a phosphorescent dopant.

The above-described dopant materials may be used alone or in a combination of two or more therefrom.

The emission layer 130 may include a host that may interact with the above-described dopant. For example, the emission layer 130 may include a host material widely known in the related art, such as an anthracene derivative, a pyrene derivative, a fluoranthene derivative, a chrysene derivative, a dihydrobenzanthracene derivative, a triphenylene derivative, or the like.

In an embodiment, the emission layer 130 may include, e.g., a host material represented by Chemical Formula FH. For example, the compound represented by Chemical Formula FH may be used as a fluorescent host material.

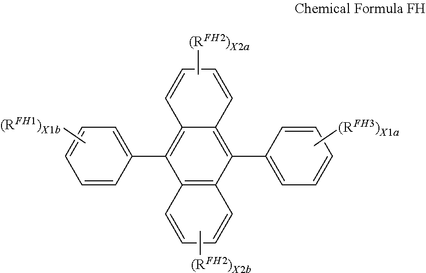

In Chemical Formula FH, R^{FH1} to R^{FH4} may each independently be a hydrogen atom, a deuterium atom, a halogen atom, a substituted or unsubstituted silyl group, a substituted or unsubstituted thio group, a substituted or unsubstituted oxy group, a substituted or unsubstituted C₁-C₁₀ alkyl group, a substituted or unsubstituted C₂-C₁₀ alkenyl group, a substituted or unsubstituted C₆-C₃₀ aryl group, a substituted or unsubstituted C₆-C₃₀ heteroaryl group, or a cyclic group formed through a combination thereof. In an embodiment, in Chemical Formula FH, at least one of R^{FH1} to R^{FH4} may form a condensed ring with a bonded benzene ring.

In Chemical Formula FH, x1a and x1b may each independently be an integer from 0 to 5; and x2a and x2b may each independently be an integer from 0 to 4. When x1a, x1b, x2a, and x2b are each 2 or more, two or more of each of R^{FH1} to R^{FH4} may be the same as or different from each other.

In an embodiment, the emission layer 130 may include, e.g., a host material represented by Chemical Formula PH. For example, the compound represented by Chemical Formula PH may be used as a host material for a phosphorescent device.

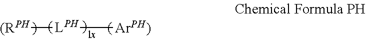

In Chemical Formula PH, R^{PH} may be a substituted or unsubstituted carbazole group. L^{PH} may be a direct linkage, a substituted or unsubstituted C₆-C₃₀ arylene group, or a substituted or unsubstituted C₂-C₃₀ heteroarylene group. Ar^{PH} may be a substituted or unsubstituted C₆-C₃₀ aryl group, or a substituted or unsubstituted C₂-C₃₀ heteroaryl group.

As described above in the definition of terminology, the term “C₆-C₃₀ aryl group” may encompass a group in which multiple aryl rings are condensed or bonded through a cyclic group (e.g., an alicyclic hydrocarbon ring). For example, a C₆-C₃₀ aryl group may be a fluorenyl group.

As described above in the definition of terminology, the term “C₂-C₃₀ heteroaryl group” may encompass a group in which multiple aryl rings are condensed or bonded through a heterocyclic ring. For example, a C₂-C₃₀ heteroaryl group may be a carbazole group, a dibenzofuran group, a dibenzothiophene group, or the like. In an embodiment, a C₂-C₃₀ heteroaryl group may be a group in which multiple aryl rings are condensed or bonded to each other through the same or different heterocyclic rings.

In an embodiment, a substituent included in Ar^{PH} may be a silyl group represented by —Si(R^{sa})(R^{sb})(R^{sc}); and R^{sa}, R^{sb}, and R^{sc} may each independently be hydrogen, a halogen, a hydroxyl group, a C₁-C₆₀ alkyl group, a C₁-C₆₀ alkoxy group, a C₆-C₆₀ aryl group, or a C₂-C₃₀ heteroaryl group. At least one of R^{sa}, R^{sb}, and R^{sc} may be a C₆-C₆₀ aryl group or a C₂-C₃₀ heteroaryl group. For example, R^{sa}, R^{sb} and R^{sc} may each independently be a C₆-C₆₀ aryl group or a C₂-C₃₀ heteroaryl group.

In Chemical Formula PH, lx may be an integer from 0 to 10. When lx is 2 or more, two or more of L^{PH} may be the same as or different from each other.

The emission layer 130 may include, e.g., BCPDS (bis(4-(9H-carbazol-9-yl) phenyl) diphenylsilane), POPCPA ((4-(1-(4-(diphenylamino) phenyl) cyclohexyl) phenyl) diphenyl-phosphine oxide), DPEPO (bis[2-(diphenylphosphino)phenyl]ether oxide), mCBP (3,3′-di(9H-carbazol-9-yl)-1,1′-biphenyl), CBP (4,4′-bis(N-carbazolyl)-1,1′-biphenyl), mCP (1,3-bis(carbazol-9-yl)benzene), PPF (2,8-bis(diphenylphosphoryl) dibenzo[b,d]furan), TCTA (4,4′,4″-tris(carbazol-9-yl)-triphenylamine), TPBi (1,3,5-tris(1-phenyl-1H-benzo[d]imidazole-2-yl)benzene), Alq3 (tris(8-hydroxyquinolino) aluminum), ADN (9,10-di(naphthalene-2-yl)anthracene), TBADN (2-tert-butyl-9,10-di(naphth-2-yl)anthracene), DSA (distyrylarylene), CDBP (4,4′-bis(9-carbazolyl)-2,2′-dimethyl-biphenyl), MADN (2-methyl-9,10-bis(naphthalen-2-yl)anthracene), CP1 (hexaphenyl cyclotriphosphazene), UGH2 (1,4-bis(triphenylsilyl)benzene), DPSiO3 (hexaphenylcyclotrisiloxane), DPSiO4 (octaphenylcyclotetrasiloxane), or the like, as a host material.

In an embodiment, in the emission layer 130, the host may include one of the materials as described above, or a combination thereof.

In an embodiment, the emission layer 130 may include two or more host materials. For example, the emission layer 130 may include a hole transporting host and an electron transporting host. In this case, the emission layer 130 may include a hole transporting host, an electron transporting host, a photosensitive agent, and a dopant. In an embodiment, the hole transporting host and the electron transporting host may form an exciplex, and energy may be transferred from the exciplex to the photosensitive agent and from the photosensitive agent to the dopant, thereby inducing a light emission.

Non-limiting examples of the hole transporting host may include a compound represented by Chemical Formula HT.

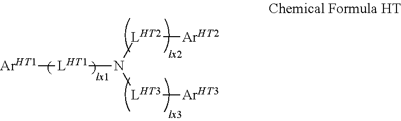

In Chemical Formula HT, L^{HT1}, L^{HT2}, and L^{HT3} may each independently be a direct linkage, a substituted or unsubstituted C₆-C₃₀ arylene group, or a substituted or unsubstituted C₂-C₃₀ heteroarylene group.

In Chemical Formula HT, lx1 to lx3 may each independently be an integer from 0 to 10. When lx1, lx2, or lx3 is 2 or more, two or more of each of L^{HT3}, L^{HT1}, or L^{HT2}, respectively, may be directly connected by, e.g., carbon atoms (e.g., sp2 carbons) of each aryl ring, to form a substituted or unsubstituted C₆-C₃₀ arylene group, or a substituted or unsubstituted C₂-C₃₀ heteroarylene group.

In Chemical Formula HT, Ar^{HT1} and Ar^{HT2} may each independently be a substituted or unsubstituted C₆-C₃₀ aryl group, or a substituted or unsubstituted C₂-C₃₀ heteroaryl group. Ar^{HT3} may be a substituted or unsubstituted C₆-C₃₀ aryl group.

In an embodiment, the compound represented by Chemical Formula HT may be a monoamine compound. In an embodiment, the compound represented by Chemical Formula HT may be a diamine compound in which at least one of Ar^{HT1} to Ar^{HT3} includes an amine group as a substituent.

In an embodiment, the compound represented by Chemical Formula HT may be a carbazole-based compound in which at least one of Ar^{HT1} and Ar^{HT2} includes a substituted or unsubstituted carbazole group, or a fluorene-based compound in which at least one of Ar^{HT1} and Ar^{HT2} includes a substituted or unsubstituted fluorene group.

In an embodiment, two adjacent groups among Ar^{HT1} to Ar^{HT3} may be condensed together to form a ring.

In a non-limiting example, the electron transporting host may include a compound represented by Chemical Formula ET.

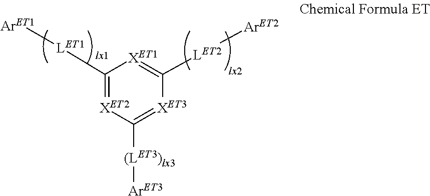

In Chemical Formula ET, at least one of X^{ET1} to X^{ET3} may be N; and the remainder of X^{ET1} to X^{ET3} may each independently be C(R^{ET}). R^{ET} may be a hydrogen atom, a deuterium atom, a substituted or unsubstituted C₁-C₂₀ alkyl group, a substituted or unsubstituted C₆-C₆₀ aryl group, or a substituted or unsubstituted C₂-C₆₀ heteroaryl group.

When one of X^{ET1} to X^{ET3} is N, the compound represented by Chemical Formula ET may include a pyridine group. When two of X^{ET1} to X^{ET3} are N, the compound represented by Chemical Formula ET may include a pyrimidine group. When X^{ET1} to X^{ET3} are each N, the compound represented by Chemical Formula ET may include a triazine group.

In Chemical Formula ET, lx1 to lx3 may each independently be an integer from 0 to 10. L^{ET1} to L^{ET3} may each independently be a direct linkage, a substituted or unsubstituted C₆-C₃₀ arylene group, or a substituted or unsubstituted C₂-C₃₀ heteroarylene group.

When lx1, lx2, or lx3 is 2 or more, two or more of each of L^{ET1}, L^{ET2}, or L^{ET3}, respectively, may be directly linked together, e.g., by carbon atoms of each aryl ring (e.g., sp2 carbons), to form a substituted or unsubstituted C₆-C₃₀ arylene group, or a substituted or unsubstituted C₂-C₃₀ heteroarylene group.

In Chemical Formula ET, Ar^{ET1} to Ar^{ET3} may each independently be a hydrogen atom, a deuterium atom, a substituted or unsubstituted C₁-C₂₀ alkyl group, a substituted or unsubstituted C₆-C₃₀ aryl group, or a substituted or unsubstituted C₂-C₃₀ heteroaryl group. For example, Ar^{ET1} to Ar^{ET3} may each independently be a substituted or unsubstituted phenyl group, a substituted or unsubstituted carbazole group, a substituted or unsubstituted fluorene group, or a substituted or unsubstituted silyl group. The silyl group may be represented by —Si(R^{sa})(R^{sb})(R^{sc}), as explained above.

In an embodiment, the emission layer 130 may include quantum dots. A quantum dot may include a Group II-VI compound, a Group III-VI compound, a Group I-III-VI compound, a Group III-V group compound, a Group III-II-V group compound, a Group IV-VI compound, a Group IV element, a Group IV compound, or a combination thereof.

The quantum dot may include a core that includes the compound as described above, and a shell surrounding the core. The shell may include an inorganic oxide or a semiconductor compound. Examples of the semiconductor compound may include CdS, CdSe, CdTe, ZnS, ZnSe, ZnTe, ZnSe, ZnTeS, GaAs, GaP, GaSb, HgS, HgSe, HgTe, InAs, InP, InGaP, InSb, AlAs, AlP, AlSb, or the like.

In an embodiment, a color of light from a quantum dot may be adjusted according to a particle size of the quantum dot. The quantum dot may be a blue quantum dot, a red quantum dot, or a green quantum dot.

The hole transfer region 120 may be formed between the first electrode 110 and the emission layer 130. The hole transfer region 120 may have a single-layered or a multi-layered including different materials.

The hole transfer region 120 may include a hole injection layer, a hole transport layer, and/or an electron blocking layer, and may further include an auxiliary emission layer.

In an embodiment, as illustrated in FIG. 2, the hole transfer region 120 may include a hole injection layer 122 and a hole transport layer 124, sequentially stacked from the first electrode 110.

In an embodiment, as illustrated in FIG. 3, the hole transfer region 120 may include a hole injection layer 122, a hole transport layer 124, and an electron blocking layer 126, sequentially stacked from the first electrode 110. The electron blocking layer 126 may block electrons from the electron transfer region 140 to the hole transfer region 120. Accordingly, the generation of excitons in the emission layer 130 may be increased, and light-emission efficiency may be further increased.

For example, the hole transfer region 120 may include the above-described compound represented by Chemical Formula HT.

For example, the hole transfer region 120 may include m-MTDATA (4,4′,4″-[tris(3-methylphenyl)phenylamino] triphenylamine), TDATA (4,4′4″-tris(N,N-diphenylamino)triphenylamine), 2-TNATA (4,4′,4″-tris[N(2-naphthyl)-N-phenylamino]-triphenylamine), NPB (N,N′-di(naphthalene-1-yl)-N,N′-diphenyl-benzidine), TPD (N,N′-bis(3-methylphenyl)-N,N′-diphenyl-[1,1′-biphenyl]-4,4′-diamine), Spiro-TPD, Spiro-NPB, DNTPD (N¹,N^{1′}-([1,1′-biphenyl]-4,4′-diyl)bis(N¹-phenyl-N⁴,N⁴-di-m-tolylbenzene-1,4-diamine), TAPC (4,4′-cyclohexylidene bis[N,N-bis(4-methylphenyl)benzenamine]), HMTPD (4,4′-bis[N,N′-(3-tolyl)amino]-3,3′-dimethylbiphenyl), TCTA (4,4′,4″-tris(N-carbazolyl)triphenylamine), PANI/DBSA (polyaniline/dodecylbenzenesulfonic acid), PEDOT/PSS (poly(3,4-ethylenedioxythiophene)/poly(4-styrenesulfonate)), PANI/CSA (Polyaniline/Camphor sulfonic acid), PANI/PSS (polyaniline/poly(4-styrenesulfonate)), a phthalocyanine compound, a carbazole compound (N-phenylcarbazole, polyvinylcarbazole, or the like), a fluorene compound, or the like. The hole transfer region 120 may include one of the hole transfer materials described above, or a combination thereof.

The hole transfer materials described above may be included in at least one of the hole injection layer 122, the hole transport layer 124, and the electron blocking layer 126.

The hole transfer region 120 may further include a charge generating material. The charge generating material may be a dopant material such as a p-dopant, so that conductivity of the hole transfer region 120 may be improved.

Examples of dopant materials may include a halogenated metal compound such as LiF, NaCl, CsF, RbCl, RbI, CuI, and KI; a quinone derivative such as TCNQ (tetracyanoquinodimethane), F4-TCNQ (2,3,5,6-tetrafluoro-7,7,8,8-tetracyanoquinodimethane), or the like; a cyano-containing compound such as HATCN (dipyrazino[2,3-f: 2′,3′-h]quinoxaline-2,3,6,7,10,11-hexacarbonitrile), NDP9 (4-[[2,3-bis[cyano-(4-cyano-2,3,5,6-tetrafluorophenyl)methylidene]cyclopropylidene]-cyanomethyl]-2,3,5,6-tetrafluorobenzonitrile), or the like; a tungsten (W) oxide; a molybdenum (Mo) oxide; or the like. The hole transfer region 120 may include one of the dopant materials described above, or a combination thereof.

A thickness of the hole transfer region 120 may be in a range of about 100 Å to about 10,000 Å. For example, the thickness of the hole transfer region 120 may be in a range of about 100 Å to about 1,500 Å.

When the hole transfer region 120 includes the hole injection layer 122 or the hole transport layer 124, a thickness of the hole injection layer 122 may be in a range from about 100 Å to about 9,000 Å, from about 100 Å to about 3,000 Å, or from about 100 Å to about 1,000 Å. A thickness of the hole transport layer 124 may be in a range from 50 Å to about 2,000 Å, from about 100 Å to about 1,500 Å, from about 100 Å to about 1,000 Å, or from about 100 Å to about 600 Å.

In the thickness ranges described above, hole transfer properties may be enhanced even at a low voltage operation, and a life-span of the device may be further improved.

Each layer of the hole transfer region 120 may be formed by a process such as a vacuum deposition, a spin coating, an inkjet printing, a laser printing, a casting, a laser thermal transfer, or the like.

The electron transfer region 140 between the second electrode 150 and the emission layer 130. The electron transfer region 140 may have a single-layered, or a multi-layered structure including different materials.

The electron transfer region 140 may include an electron injection layer, an electron transport layer, and/or a hole blocking layer, and may further include an auxiliary emission layer.

In embodiments, as illustrated in FIG. 3, the electron transfer region 140 may include an electron injection layer 142 and an electron transport layer 144, stacked from the second electrode 150 to the emission layer 130.

In an embodiment, as illustrated in FIG. 3, the electron transfer region 140 may include an electron injection layer 142, an electron transport layer 144, and a hole blocking layer 146, stacked from the second electrode 150 to the emission layer 130. The hole blocking layer 146 may block or suppress holes from the hole transfer region 120. Accordingly, emission energy and luminescence efficiency in the emission layer 130 may be further improved.

For example, the electron transfer region 140 may include the above-described compound represented by Chemical Formula ET.

For example, the electron transfer region 140 may include an anthracene compound, Alq3 (tris(8-hydroxyquinolinato) aluminum), 1,3,5-tri[(3-pyridyl)-phen-3-yl] benzene, 2,4,6-tris (3′-(pyridin-3-yl)biphenyl-3-yl)-1,3,5-triazine, 2-(4-(N-phenylbenzimidazol-1-yl)phenyl)-9,10-dinaphthylanthracene, TPBi (1,3,5-tri(1-phenyl-1H-benzo[d]imidazol-2-yl)benzene), BCP (2,9-dimethyl-4,7-diphenyl-1,10-phenanthroline), Bphen (4,7-diphenyl-1,10-phenanthroline), TAZ (3-(4-biphenylyl)-4-phenyl-5-tert-butylphenyl-1,2,4-triazole), NTAZ (4-(naphthalen-1-yl)-3,5-diphenyl-4H-1,2,4-triazole), tBu-PBD (2-(4-biphenylyl)-5-(4-tert-butylphenyl)-1,3,4-oxadiazole), BAlq (bis(2-methyl-8-quinolinolato-N1,O8)-(1,1′-biphenyl-4-olato)aluminum), Bebq₂ (beryllium bis(benzoquinolin-10-olate)), ADN (9,10-di(naphthalene-2-yl)anthracene), BmPyPhB (1,3-bis[3,5-di(pyridin-3-yl)phenyl]benzene), or the like. The electron transfer region 140 may include one of the electron transfer materials described above, or a combination thereof.

The above-mentioned material may be included in at least one of the electron injection layer 142, the electron transport layer 144, and the hole blocking layer 146.

The electron transfer region 140 may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or a combination thereof. In an embodiment, the above-mentioned material may be included in the electron injection layer 142.

The alkali metal may include Li, Na, K, Rb, Cs, or any combination thereof. The alkaline earth metal may include Mg, Ca, Sr, Ba, or any combination thereof. The rare earth metal may include Sc, Y, Ce, Tb, Yb, Gd, or any combination thereof.

The alkali metal-containing compound, the alkaline earth metal-containing compound, and the rare earth metal-containing compound may include an oxide, a halide (e.g., a fluoride, a chloride, a bromide, an iodide, or the like), a telluride, or a combination thereof of the alkali metal, the alkaline earth metal, and the rare earth metal, respectively.

The alkali metal complex, the alkaline earth metal complex, and the rare earth metal complex may include a metal ion such as an alkali metal ion, an alkaline earth metal ion or a rare earth metal ion, and a ligand bonded to the metal ion. The ligand may include, e.g., hydroxyquinoline, hydroxyisoquinoline, hydroxybenzoquinoline, hydroxyacridine, hydroxyphenanthridine, hydroxyphenyloxazole, hydroxyphenylthiazole, hydroxyphenyloxadiazole, hydroxyphenylthiadiazole, hydroxyphenylpyridine, hydroxyphenylbenzoimidazole, hydroxyphenylbenzothiazole, bipyridine, phenanthroline, cyclopentadiene, or a combination thereof.

A thickness of the electron transfer region 140 may be in a range from about 100 Å to about 1,000 Å, e.g., from about 150 Å to about 500 Å.

When the electron transfer region 140 includes an electron injection layer 142 or an electron transport layer 144, a thickness of the electron injection layer 142 may be in a range from about 1 Å to about 100 Å, from 1 Å to about 90 Å or from about 5 Å to about 50 Å, and a thickness of the electron transport layer 144 may be in a range from 10 Å to about 900 Å, from about 10 Å to about 500 Å or from about 100 Å to about 400 Å.

Within any of the thickness ranges described above, electron injection and electron transport properties may be further improved without an excessive increase in driving voltage, and stability of the electron transfer region 140 may be improved.

Each layer of the electron transfer region 140 may be formed by a process such as a vacuum deposition, a spin coating, an inkjet printing, a laser printing, a casting, a laser thermal transfer, or the like.

The light-emitting device ED may further include a capping layer. Light emission efficiency to an outside of the light-emitting device ED may be improved through the capping layer.

As illustrated in FIG. 4, a second capping layer 160b may be formed on an outer surface of the second electrode 150. In an embodiment, a first capping layer 160a may be formed on an outer surface of the first electrode 110.

A refractive index of the first capping layer 160a and/or the second capping layer 160b may be 1.6 or more. For example, the refractive index of the first capping layer 160a and/or the second capping layer 160b may be 1.6 or more, 1.8 or more, or 2.0 or more for a light in a wavelength range of 550 nm to 660 nm.

The first capping layer 160a and the second capping layer 160b may each be formed as an organic capping layer including an organic material, an inorganic capping layer including an inorganic material, or an organic-inorganic hybrid capping layer including both the organic and inorganic materials.

The first capping layer 160a and/or the second capping layer 160b may each have a single-layered structure or a multi-layered structure including different materials.

In an embodiment, the first capping layer 160a and the second capping layer 160b may each independently include a carbocyclic compound, a heterocyclic compound, an amine group-containing compound, a porphine derivative, a phthalocyanine derivative, a naphthalocyanine derivative, an alkaline metal complex, an alkaline earth metal complex, or the like. The first capping layer 160a and the second capping layer 160b may each independently include one of the aforementioned materials, or a combination thereof.

In an embodiment, the first capping layer 160a and/or the second capping layer 160b may each independently include an amine group-containing compound.

Referring to FIG. 5, the light-emitting device ED may include a plurality of light-emitting structures (e.g., the light-emitting structures ES1, ES2 and ES3). The light-emitting structures ES1, ES2, and ES3 may each include a stacked structure of the hole transfer region 120, the emission layer 130, and the electron transfer region 140, as described with reference to FIGS. 1 to 4. In an embodiment, the light-emitting device ED of FIG. 5 may be a light-emitting device having a tandem structure.

Charge generation layers CGL1 and CGL2 may each be disposed between adjacent structures among the light-emitting structures ES1, ES2 and ES3. Charge generation layers CGL1 and CGL2 may each independently include a p-type charge generation layer and/or an n-type charge generation layer.

The p-type charge generation layer may include a hole transport host compound, such as N,N′-Di(1-naphthyl)-N,N′-diphenyl-(1,1′-biphenyl)-4,4′-diamine (NPB). For example, the p-type charge generation layer may include a compound represented by Chemical Formula HT as described above. The p-type charge generation layer may further include a p-dopant, such as tetracyanoquinodimethane (TCNQ).

The n-type charge generation layer may include an electron transport host compound. For example, the n-type charge generation layer may include a compound represented by Chemical Formula ET as described above. In an embodiment, the n-type charge generation layer may include a phenanthroline-based compound.

The charge generation layers CGL1 and CGL2 may include a first charge generation layer CGL1 disposed between the first light-emitting structure ES1 and the second light-emitting structure ES2, and a second charge generation layer CGL2 disposed between the second light-emitting structure ES2 and the third-light emitting structure ES3.

In an embodiment, the first light-emitting structure ES1, the first charge generation layer CGL1, the second light-emitting structure ES2, the second charge generation layer CGL2, the third light-emitting structure ES3, and the second electrode 150 may be sequentially stacked on a top surface of the first electrode 110.

Colors emitted from the first light-emitting structure ES1, the second light-emitting structure ES2 and the third light-emitting structure ES3 may be the same or different from each other. In an embodiment, the first light-emitting structure ES1, the second light-emitting structure ES2 and the third light-emitting structure ES3 may include a red light-emitting layer, a green light-emitting layer and a blue light-emitting layer, respectively, and a white light-emitting structure may be implemented through the tandem structure, but is not limited thereto.

In FIG. 5, the 3-stack tandem structure in which three light-emitting structures are stacked is illustrated as an example, but the tandem structure of the light-emitting device of the present disclosure is not limited to the structure illustrated in FIG. 5. For example, 2-stack structure, or a 4-stack structure, a 5-stack structure, or more stacked structure as will be described with reference FIG. 6 may also be implemented.

Referring to FIG. 6, as described with reference to FIG. 5, a tandem structure in which the light-emitting structure and a charge generation layer are alternately and repeatedly stacked may be disposed between the first electrode 110 and the second electrode 150.

In an embodiment, first to mth light-emitting structures ES1 to ESm may be sequentially stacked from the top surface of the first electrode 110 with the charge generation layer interposed therebetween. The charge generation layer may include a first charge generation layer CGL1 to an (m−1)th charge generation layer CGLm−1 sequentially stacked from the top surface of the first electrode 110.

As illustrated in FIG. 6, the first light-emitting structure ES1, the first charge generation layer CGL1, the second light-emitting structure ES2, the second charge generation layer CGL2, . . . , an (m−1)th light-emitting structure ESm−1, an (m−1)th charge generation layer CGLm−1, an mth light-emitting structure ESm, and the second electrode 150 may be sequentially stacked from the top surface of the first electrode 110.

In an embodiment, m is 4, and the intermediate layer ITL of the light-emitting device may have a 4-stack tandem structure, and may include first to fourth light-emitting structures ES1, ES2, ES3 and ES4, and first to third charge generation layers CGL1, CGL2 and CGL3. Colors of light generated from the first to fourth light-emitting structures ES1, ES2, ES3 and ES4 may be the same or different from each other.

In an embodiment, the first to fourth light emitting structures ES1, ES2, ES3 and ES4 may include at least one blue light-emitting structure and at least one green-light emitting structure. In a non-limiting example, the first to third light emitting structures ES1, ES2 and ES3 may correspond to the blue light-emitting structure, and the fourth light emitting structure ES4 may correspond to the green-light emitting structure.

In an embodiment, m is 5, and the intermediate layer ITL of the light-emitting device may have a 5-stack tandem structure, and may include first to fifth light-emitting structures ES1, ES2, ES3, ES4 and ES5, and first to fourth charge generation layers CGL1, CGL2, CGL3 and CGL4. Colors of light generated from the first to fifth light-emitting structures ES1, ES2, ES3, ES4, and ES5 may be the same or different from each other.

In an embodiment, the first to fifth light-emitting structures ES1, ES2, ES3, ES4 and ES5 may include at least one blue light emitting structure and at least one green light emitting structure. In a non-limiting example, the first to fifth light-emitting structures ES1, ES2, ES3, ES4 and ES5 may include three blue light-emitting structures and two green light-emitting structures. For example, the first, third and fifth light-emitting structures ES1, ES3 and ES5 may correspond to the blue light-emitting structure, and the second and fourth light-emitting structures ES2 and ES4 may correspond to the green light-emitting structure.

### Electronic Device

The above-described light-emitting device ED may be applied to an electronic device and may be provided as a light-emitting portion or a light-emitting unit of the electronic device.

Examples of an electronic device may include a display device, a billboard, a signboard, a light source, a lighting device, a personal computer such as a laptop computer or a desktop computer, a mobile phone, an electronic book, an electronic dictionary, an electronic notebook, a health-care device including a diagnostic device and various sensors, various display parts for transportation means (automobile, aircraft, ship, train, or the like).

In an embodiment, the light-emitting device ED may be applied to an organic light emitting diode (OLED) display device or a quantum dot (QD)-OLED display device.

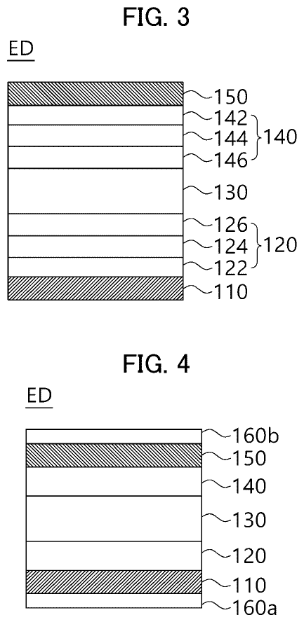

FIG. 7 is a schematic cross-sectional view illustrating a light-emitting device in accordance with an embodiment.

Referring to FIG. 7, the light-emitting device may include a circuit layer CL disposed on a base substrate 200, and light-emitting devices ED1, ED2 and ED3 disposed on the circuit layer CL.

The base substrate 200 may serve as a supporting substrate or as a back-plane substrate of a light-emitting device. The base substrate 200 may be a glass substrate or a plastic substrate.

In an embodiment, the base substrate 200 may include a polymer material having transparent and flexible properties. When the base substrate 200 includes a polymer material, the base substrate 200 may be used in a transparent flexible light-emitting device. For example, the base substrate 200 may include a polymer material such as polyimide, polysiloxane, an epoxy resin, an acrylic resin, polyester, or the like. In an embodiment, the base substrate 200 may include polyimide.

The circuit layer CL may include transistors TR1, TR2, and TR3. The circuit layer CL may include wiring layers and insulating layers that form a thin film transistor array (TFT-Array).

The circuit layer CL may further include a buffer layer 205 on a top surface of the base substrate 200. The buffer layer 205 may block the penetration of moisture through the base substrate 200, and may also block the diffusion of impurities between the base substrate 200 and the structures formed thereon.

The buffer layer 205 may include, e.g., silicon oxide, silicon nitride, or silicon oxynitride. The buffer layer 205 may include one of the aforementioned materials, or a combination thereof. In an embodiment, the buffer layer 205 may have a stacked structure that includes a silicon oxide layer and a silicon nitride layer.

The transistors TR1, TR2, and TR3 may be disposed on the buffer layer 205. A first transistor TR1, a second transistor TR2, and a third transistor TR3 may be electrically connected to a first light-emitting device ED1, a second light-emitting device ED2, and a third light-emitting device ED3, respectively.

The transistors TR1, TR2 and TR3 may each include an active layer 210, a gate insulation layer 220, and a gate electrode 230.

The active layer 210 may be disposed on the buffer layer 205, and may be patterned for each pixel. The active layer 210 may include a silicon compound such as amorphous silicon or polysilicon. A p-type dopant or an n-type dopant may be doped in a region of the active layer 210, and the active layer 210 may include a source region, a drain region, and a channel region.

The active layer 210 may include an oxide semiconductor, such as indium gallium zinc oxide (IGZO), zinc tin oxide (ZTO), or indium tin zinc oxide (ITZO).

The gate insulation layer 220 may be formed on the active layer 210, and the gate electrode 230 may be stacked on the gate insulation layer 220. As illustrated in FIG. 7, the gate insulation layer 220 may be patterned to partially cover each active layer 210. Alternatively, the gate insulation layer 220 may extend continuously over multiple pixels or light-emitting regions, and may be provided as a common layer for the first, second, and third transistors TR1, TR2 and TR3.

The gate electrode 230 may overlap the channel region of the active layer 210 in a thickness direction.

An insulating interlayer 240 may be formed on the active layer 210 to cover the gate electrode 230 and the gate insulation layer 220. Connection electrodes 250 and 260 which may be in contact with or electrically connected to the active layer 210 may each be disposed on the insulating interlayer 240.

The connection electrodes 250 and 260 may extend through the insulating interlayer 240 to be in contact with or electrically connected to the active layer 210. When the gate insulation layer 220 is provided as a common layer for multiple light-emitting regions, the connection electrodes 250 and 260 may also extend through the gate insulation layer 220.

The connection electrodes 250 and 260 may include a source electrode 250 that may be in contact with or connected to the source region of the active layer 210, and a drain electrode 260 that may be in contact with or connected to the drain region of the active layer 210.

The gate insulation layer 220 and the insulating interlayer 240 may each independently include silicon oxide, silicon nitride, or silicon oxynitride, and may each have a stacked structure that includes a silicon oxide layer and a silicon nitride layer.

The gate electrode 230 and the connection electrodes 250 and 260 may include a metal such as Ag, Mg, Al, W, Cu, Ni, Cr, Mo, Ti, Pt, Ta, Nd, Sc, an alloy thereof, or a nitride thereof.

A via insulation layer 270 may be formed on the insulating interlayer 240 to cover the connection electrodes 250 and 260.

The via insulation layer 270 may accommodate a via structure electrically connecting the first electrode 110 and the drain electrode 260. The via insulation layer 270 may serve as a planarization layer of the circuit layer CL. In an embodiment, the via insulation layer 270 may include an organic material such as polyimide, an epoxy resin, an acrylic resin, polyester, or the like.

The light-emitting devices ED1, ED2, and ED3 may be disposed on the via insulation layer 270. For example, as described with reference to FIGS. 1 to 4, the light-emitting devices ED1, ED2, and ED3 may include the first electrode 110, the hole transfer region 120, the emission layer 130, the electron transfer region 140, and the second electrode 150 which are sequentially stacked from the via insulation layer 270.

The first electrode 110 may be electrically connected to the transistors TR1, TR2 and TR3 or the connection electrodes 250 and 260 in the circuit layer CL through the via structure. As illustrated in FIG. 7, the first electrode 110 may be in contact with or connected to the drain electrode 260 to serve as a pixel electrode patterned for each light-emitting region or pixel.

A pixel defining layer 280 may be formed on the via insulation layer 270 to define each light-emitting region or pixel. A blue light-emitting region, a red light-emitting region, and a green light-emitting region may be separated and defined by the pixel defining layer 280, and the light-emitting devices ED1, ED2, and ED3 may respectively correspond to a blue light-emitting device, a red light-emitting device, and a green light-emitting device.

In an embodiment, the emission layer of at least one of the red light-emitting device, the green light-emitting device, or the blue light-emitting device may include the heterocyclic compound represented by the above-described Chemical Formula 1. In an embodiment, the emission layer of the blue light-emitting device may include the heterocyclic compound represented by the above-described Chemical Formula 1.

The pixel defining layer 280 may partially cover the first electrode 110 of each light-emitting region.

As illustrated in FIG. 7, the hole transfer region 120 and the electron transfer region 140 may each be provided as a common layer that continuously extends over the pixel defining layer 280 and the first electrodes 110. The emission layer 130 may be formed within each light emitting-region or pixel, and may be separated by the pixel defining layer 280.

In an embodiment, the emission layer 130 may also be provided as a common layer that continuously extends over the light emitting-regions or pixels. In an embodiment, the hole transfer region 120, the emission layer 130, and the electron transfer region 140 may each be patterned and separately formed for each light-emitting region or pixel.

The second electrode 150 may be provided as a common electrode that continuously extends over the light-emitting regions or the pixels.

An encapsulation layer 290 may be disposed on the pixel defining layer 280 and the light-emitting devices ED1, ED2, and ED3 to protect the light-emitting devices ED1, ED2 and ED3 from moisture and/or oxygen. The encapsulation layer 290 may be a thin film encapsulation (TFE) having a single-layered structure or multi-layered structure.

The encapsulation layer 290 may include an inorganic layer that includes silicon nitride (SiNₓ), silicon oxide (SiOₓ), indium tin oxide, indium zinc oxide, or a combination thereof; an organic layer that includes polyethylene terephthalate, polyethylene naphthalate, polycarbonate, polyimide, polyethylene sulfonate, polyoxymethylene, polyarylate, hexamethyldisiloxane, an acrylic resin (e.g., polymethylmethacrylate, polyacrylic acid, or the like), an epoxy resin (e.g., an aliphatic glycidyl ether (AGE)) or a combination thereof; or a combination of the inorganic layer and the organic layer.

The light-emitting device may further include a functional layer 300 disposed on the encapsulation layer 290. The functional layer 300 may include a sensor layer such as a touch sensor layer, an optical layer such as a polarizing layer, a color conversion layer, a color filter layer, a window film, or a combination thereof.

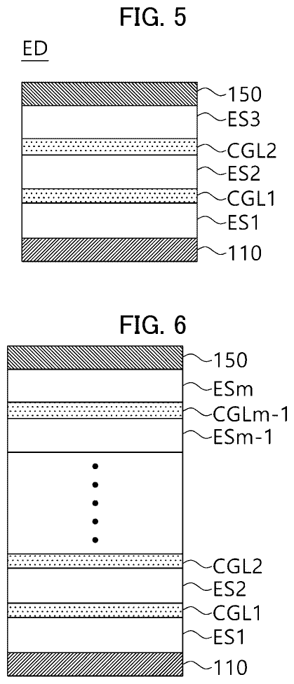

FIG. 8 is a schematic cross-sectional view illustrating a light-emitting device in accordance with an embodiment.

Referring to FIG. 8, each of the light-emitting devices ED1, ED2 and ED3 may have a tandem structure, e.g., a 2-stack tandem structure.

In an embodiment, the hole transfer region 120 and the electron transfer region 140 may be continuously and commonly formed and included in an intermediate layer of each light-emitting structure. Additionally, a charge generation layer CGL may continuously extend across a plurality of pixels and may be commonly included in the intermediate layer of each light-emitting structure.

The first light-emitting device ED1 may include a first lower emission layer 130-1a disposed between the hole transfer region 120 and the charge generation layer CGL, and a first upper emission layer 130-1b disposed between the charge generation layer CGL and the electron transfer region 140.

The second light-emitting device ED2 may include a second lower emission layer 130-2a disposed between the hole transfer region 120 and the charge generation layer CGL, and a second upper emission layer 130-2b disposed between the charge generation layer CGL and the electron transfer region 140.

The third light-emitting device ED3 may include a third lower emission layer 130-3a disposed between the hole transfer region 120 and the charge generation layer CGL, and a third upper emission layer 130-3b disposed between the charge generation layer CGL and the electron transfer region 140.

The lower and upper emission layers included in each light-emitting structure may generate light of the same color. In an embodiment, each of the first lower emission layer 130-1a and the first upper emission layer 130-1b included in the first light-emitting device ED1 may correspond to a red emission layer. Each of the second lower emission layer 130-2a and the second upper emission layer 130-2b included in the second light-emitting device ED2 may correspond to a green emission layer. Each of the third lower emission layer 130-3a and the third upper emission layer 130-3b included in the third light-emitting device ED3 may correspond to a blue emission layer.

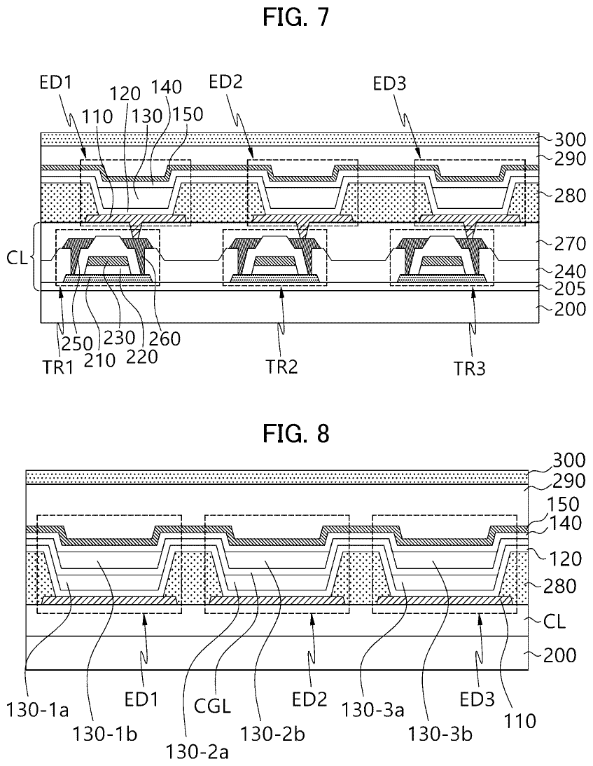

FIG. 9 is a schematic cross-sectional view illustrating a stack construction of light-emitting structure in a light-emitting device in accordance with an embodiment. For convenience of illustration and description, illustration of the circuit layer, the base substrate, the pixel defining layer, or the like, is omitted from FIG. 9, and a shape of each layer or element in the light-emitting structure is briefly shown as a rectangle.

Referring to FIG. 9, at least one of the light-emitting devices ED1, ED2 and ED3 or pixel areas PA1, PA2 and PA3 may have a tandem structure including a plurality of emission layers, and at least one of the remainders may have a single emission layer structure.

In an embodiment, one of the light-emitting devices ED1, ED2 and ED3 or the pixel areas PA1, PA2, and PA3 may have a tandem structure, and the remainder may have a single emission layer structure.

As illustrated in FIG. 9, the first light-emitting device ED1, the second light-emitting device ED2, and the third light-emitting device ED3 may be included in the first pixel area PA1, the second pixel area PA2, and the third pixel area PA3, respectively. In an embodiment, the first pixel area PA1, the second pixel area PA2, and the third pixel area PA3 may correspond to a red pixel area, a green pixel area, and a blue pixel area, respectively.

The hole transfer region 120, the electron transfer region 140, and the second electrode 150 may each be provided as a common layer continuously extending over the first pixel area PA1, the second pixel area PA2, and the third pixel area PA3.

The first-light emitting device ED1 included in the first pixel area PA1 may include a first emission layer 130-1, and the second light-emitting device ED2 included in the second pixel area PA2 may include a second emission layer 130-2. Each of the first emission layer 130-1 and the second emission layer 130-2 may be a single-layered emission layer.

The third light-emitting device ED3 included in the third pixel area PA3 may have, e.g., a 2-stack tandem structure. The third light-emitting device ED3 may include a third lower emission layer 130-3a and a third upper emission layer 130-3b separated with the charge generation layer CGL interposed therebetween. Each of the third lower emission layer 130-3a and the third upper emission layer 130-3b may correspond to a blue emission layer.

A lower electron transfer region 140a may be disposed between the charge generation layer CGL and the third lower emission layer 130-3a. An upper hole transfer region 120b may be disposed between the charge generation layer CGL and the third upper emission layer 130-3b.

Accordingly, a tandem light-emitting structure in which the first electrode 110, the hole transfer region 120, the third lower emission layer 130-3a, the lower electron transfer region 140a, the charge generation layer CGL, the upper hole transfer region 120b, the third upper emission layer 130-3b, the electron transfer region 140, and the second electrode 150 are sequentially stacked may be disposed in the third pixel area PA3.

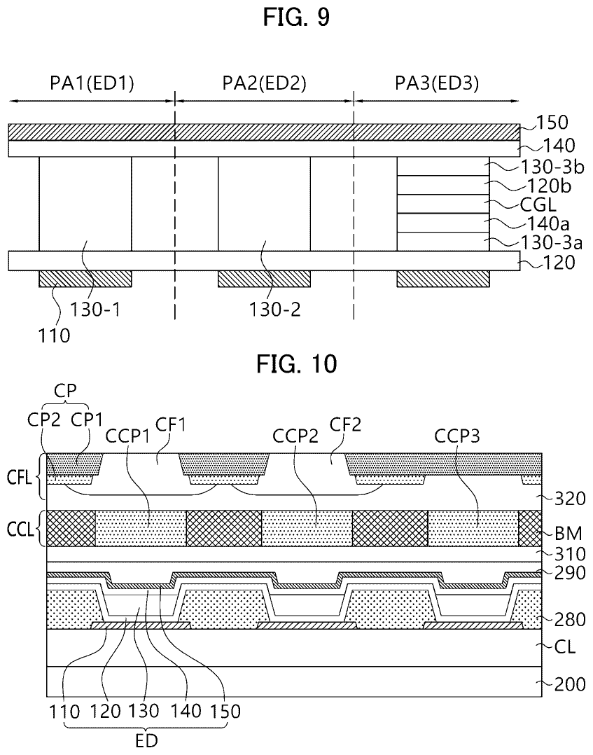

FIG. 10 is a schematic cross-sectional view illustrating a light-emitting device in accordance with an embodiment.

FIG. 10 illustrates a light-emitting device having a QD-OLED structure according to an embodiment. Detailed descriptions regarding elements and structures that are the same as or substantially similar to those described with reference to FIG. 7 will not be repeated here.

Referring to FIG. 10, the pixel defining layer 280 and the light-emitting device ED may be disposed on the circuit layer CL, as described above with reference to FIG. 7. In an embodiment, each pixel may emit light of the same wavelength region. In an embodiment, each light-emitting device ED may emit a blue light.

In an embodiment, each light-emitting region may include the light-emitting device having the tandem structure, as described above with respect to FIG. 5. In this case, the intermediate layer ITL of each light-emitting device ED may be provided as a common layer that continuously extends over a plurality of the light-emitting regions.

A color control layer CCL may be disposed on the encapsulation layer 290, and the color control layer CCL may include color control portions CCP1, CCP2, and CCP3.

The color control portions CCP1, CCP2 and CCP3 may each include a light transformer such as a quantum dot or a phosphor. In each of the color control portions CCP1, CCP2 and CCP3, the light transformer may convert a wavelength of a provided light and emit a resulting light.

The color control portions CCP1, CCP2 and CCP3 may be separated or spaced apart from each other by a bank BM. The bank BM may substantially overlap the pixel defining layer 280, and the color control portions CCP1, CCP2 and CCP3 may substantially overlap each of the emission layers 130.

The color control layer CCL may include a first color control portion CCP1 including a first quantum dot that converts a first color light provided from the light-emitting device ED into a second color light, a second color control portion CCP2 including a second quantum dot that converts the first color light into a third color light, and a third color control portion CCP3 that transmits the first color light.

In an embodiment, the first color light, the second color light, and the third color light may be a blue light, a red light, and a green light, respectively. The first quantum dot and the second quantum dot may respectively be a red quantum dot and a green quantum dot.

The color control portions CCP1, CCP2 and CCP3 may each further include a scattering material such as inorganic particles. The third color control portion CCP3 may not include quantum dots and may include the scattering material. The scattering material may include TiO₂, ZnO, Al₂O₃, SiO₂, hollow silica, or the like. The scattering material may be one of the aforementioned materials or a combination thereof.

The color control portions CCP1, CCP2, and CCP3 may each further include a binder resin that disperses the quantum dot and the scattering material. The binder resin may include an acrylic resin, a urethane resin, a silicone resin, an epoxy resin, or the like.

A color filter layer CFL that includes color filters CF1 and CF2 and a light-shielding portion CP may be disposed on the color control layer CCL.

The color filter layer CFL may include a first filter CF1 that transmits the second color light, a second filter CF2 that transmits the third color light, and a third filter that transmits the first color light. For example, the first filter CF1 may be a red filter, the second filter CF2 may be a green filter, and the third filter may be a blue filter.

The color filters CF1 and CF2 may each include a photosensitive binder resin and a colorant including a pigment and/or a dye. The first filter CF1 may include a red pigment or dye, and the second filter CF2 may include a green pigment or dye.

The light-shielding portion CP may be disposed between the color filters. In an embodiment, the light-shielding portion may include a first light-shielding portion CP1 and a second light-shielding portion CP2 that includes colorants of different colors.

In an embodiment, the first light-shielding portion CP1 may include a blue colorant, and the second light-shielding portion CP2 may include a red colorant or a black colorant. In an embodiment, in the blue light-emitting region, a portion of the first light-shielding portion CP1 may be provided as a blue color filter and may be exposed between the second light-shielding portions CP2, so that an additional color filter (e.g., the third filter) may be omitted.

A first barrier layer 310 may be disposed between the color control layer CCL and the light-emitting device ED (or the encapsulation layer 290). A second barrier layer 320 may be disposed between the color control layer CCL and the color filter layer CFL.

The barrier layers 310 and 320 may each include at least one inorganic layer. For example, the barrier layers 310 and 320 may each independently include silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, or the like.

In an embodiment, the barrier layers 310 and 320 may each have a multi-layered structure that further includes an organic layer.

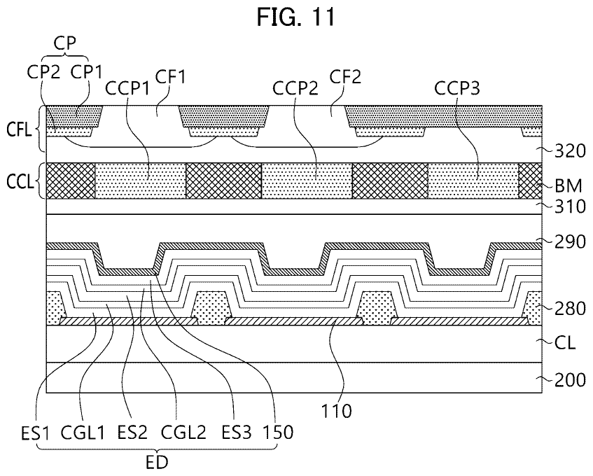

FIG. 11 is a schematic cross-sectional view illustrating a light-emitting device in accordance with an embodiment. Detailed descriptions of elements and structures substantially the same as or similar to those described with reference to FIG. 10 are omitted herein.

Referring to FIG. 11, the light-emitting device ED corresponding to the color control portions CCP1, CCP2 and CCP3 may be disposed on the first electrode 110 serving as the pixel electrode, and the light-emitting device ED may have a tandem structure.

In an embodiment, as described with reference to FIG. 5, the first light-emitting structure ES1, the first charge generation layer CGL1, the second light-emitting structure ES2, the second charge generation layer CGL2, and the third light-emitting structure ES3 may be sequentially stacked between the first electrode 110 and the second electrode 150. The first light-emitting structure ES1, the first charge generation layer CGL1, the second light-emitting structure ES2, the second charge generation layer CGL2, and the third light-emitting structure ES3 may be continuously and commonly formed in a plurality of pixel areas or light-emitting regions.

In an embodiment, the first light-emitting structure ES1, the second light-emitting structure ES2, and the third light-emitting structure ES3 may generate different color lights, and the light-emitting device ED may generate a white light. In an embodiment, the first light-emitting structure ES1, the second light-emitting structure ES2, and the third light-emitting structure ES3 may all generate blue lights.

In an embodiment, as described with reference to FIG. 6, the light-emitting device ED may include a tandem structure of 4-stack, 5-stack, or more of the stacked number.

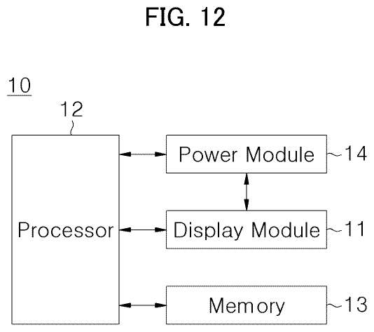

FIG. 12 is a block diagram of an electronic device in accordance with an embodiment.

Referring to FIG. 12, an electronic device 10 according to an embodiment may include a display module 11, a processor 12, a memory 13 and a power module 14.

The processor 12 may include a central processing unit (CPU), an application processor (AP), a graphic processing unit (GPU), a communication processor (CP), an image signal processor (ISP) and/or a controller.

Data information for an operation of the processor 12 or the display module 11 may be stored in the memory 13. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter or a battery device, and a power conversion module that converts a power supplied by the power supply module to a generate power required for the operation of the electronic device 10.

At least one of components of the electronic device 10 as described above may be included in the display device according to the above-described embodiments. Additionally, some of individual modules functionally included in one module may be included in the display device, and others may be provided separately from the display device. For example, the display module 11 may include the display device, and the processor 12, the memory 13 and the power module 14 may be provided in the form of another device in the electronic device 10 different from the display device.

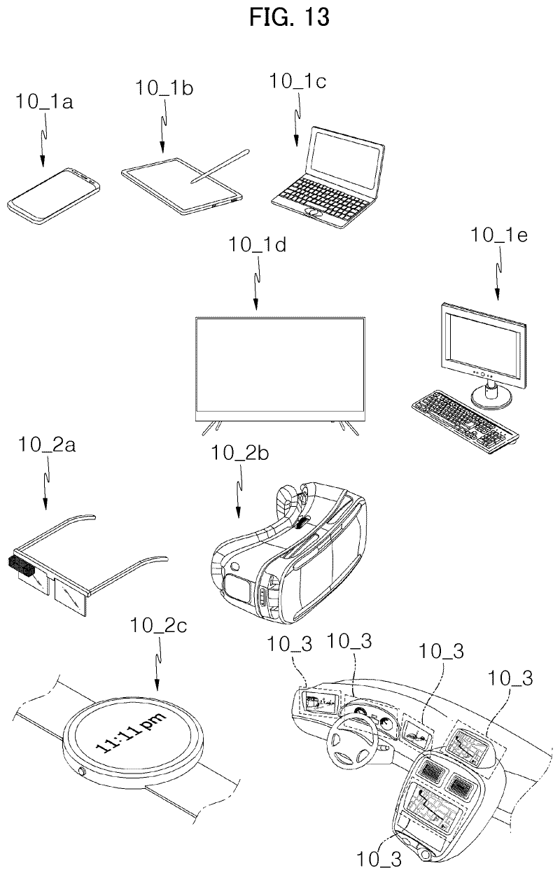

FIG. 13 is a schematic diagram of an electronic device in accordance with various embodiments.

Referring to FIG. 13, non-limiting examples of various electronic devices to which the display device according to the above-described embodiments is applied include an electronic device for displaying an image such as a smartphone 10_1a, a tablet PC 10_1b, a laptop 10_1c, a TV 10_1d, a desk monitor 10_1e, and the like; a wearable electronic device including a display module such as smart glasses 10_2a, a head mounted display 10_2b, a smart watch 10_2c, and the like; a vehicle electronic device 10_3 including a display module such as a center information display (CID) disposed at a vehicle instrument panel, a center fascia, a dashboard, or the like, a room mirror display, and the like. The electronic device may include a virtual reality glass or an augmented reality glass.

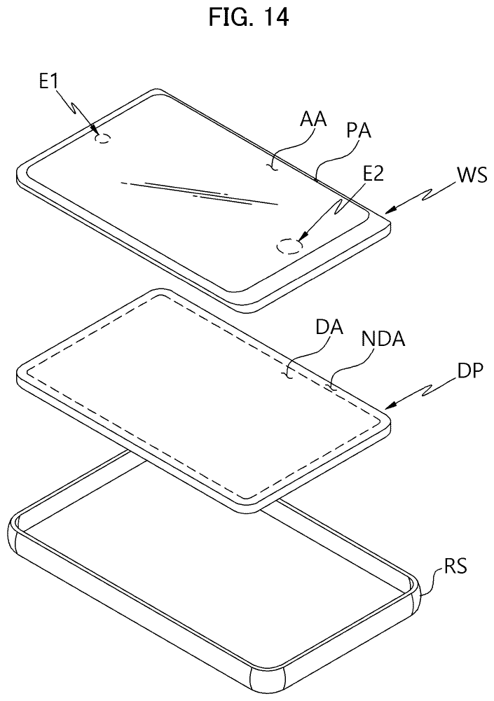

FIG. 14 is a schematic exploded perspective view illustrating an electronic device in accordance with an embodiment.

According to an embodiment, the electronic device may be implemented in the form of a mobile phone (smart phone), a tablet, a PC, or the like, including the above-described display device.

Referring to FIG. 14, the electronic device may include a window structure WS, a display panel DP, and a rear structure RS.

The window structure WS may provide an external display surface recognized by a user, such as a viewing surface of a mobile phone, and may include a transparent material film. For example, the window structure WS may include glass (e.g., ultra-thin glass (UTG), a hard coating film, a plastic film, or the like.

An outer surface of the window structure WS may include an active area AA and a peripheral area PA. The active area AA may provide a surface from which an image of the display device DD is substantially displayed and to which a user's touch/command is input. The peripheral area PA may substantially correspond to a bezel area of the display device.

The display panel DP may include the above-described electronic device and may have a display area DA and a non-display area NDA. The display area DA of the display panel DP may substantially correspond to or overlap the active area AA of the window structure WS. The non-display area NDA of the display panel DP may substantially correspond to or overlap the peripheral area PA of the window structure WS.

In an embodiment, functional device areas E1 and E2 may be included in the active area AA of the window structure WS. For example, a first functional device area E1 may be included at one end portion of the active area AA and may be implemented, e.g., in the form of a camera hole. The second functional device area E2 may serve as a fingerprint sensing area.

For example, a sensor structure for a touch sensing or a fingerprint sensing may be disposed in the display panel DP or between the window structure WS and the display panel DP.

The rear structure RS may serve as a frame structure or a housing of the electronic device or the electronic device. A cover panel may be disposed between the rear structure RS and the display panel DP.

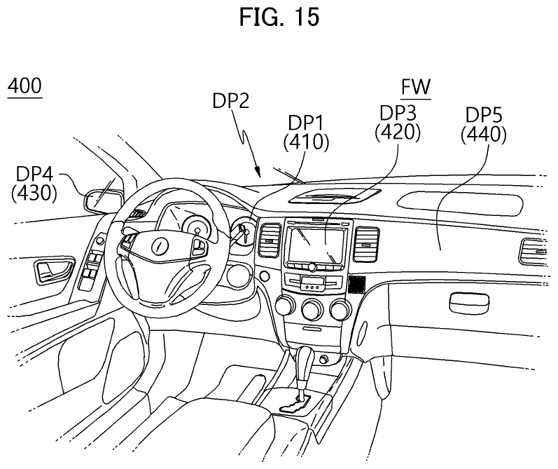

FIG. 15 is a schematic cross-sectional view illustrating an electronic device in accordance with an example embodiment.

The electronic device may be installed in, embedded in, attached to, or integrated with a vehicle 400. However, the vehicle 400 is not limited to the embodiment illustrated in FIG. 15. Further examples of the vehicle 400 may include a transportation means such as a three-wheeled or four-wheeled vehicle, a construction machine, a two-wheeled vehicle, a motor vehicle, a bicycle, a train, or the like. Other examples of the vehicle 400 may include an electric vehicle, a hybrid vehicle, or the like.

Referring to FIG. 15, at least one of first to fifth display devices DP1, DP2, DP3, DP4, and DP5 may be applied to the vehicle 400.

In an embodiment, the first display device DP1 may be disposed in a cluster area 410. Driving information such as a driving distance and speed, and various warning lights may be displayed in the cluster area 410.

The second display device DP2 may be disposed on a front window FW of the vehicle 400. For example, the second display device DP2 may be installed as a head-up display (HUD).

The third display device DP3 may be disposed on a center fascia 420 of the vehicle 400. In the center fascia 420, a button or a switch for controlling an image display or a music player, an air conditioner, a heater, or the like, may be displayed, and vehicle information may be displayed thereon.

The fourth display device DP4 may be applied to side mirrors 430 of the vehicle 400. A side mirror 430 may be installed at each of both sides of an exterior of the vehicle 400, and the fourth display device DP4 may be applied to at least one of the side mirrors 430 installed at each of the both sides.

The fifth display device DP5 may be disposed on a passenger seat dashboard 440. Information/image identical to or different from information/image displayed on the cluster area 410 and/or the center fascia 420 may be displayed at the passenger seat dashboard 440.

The electronic device may be at least one of a video wall, a flat panel display, a curved display, a computer monitor, a medical monitor, a television, a billboard, a light for indoor or outdoor lighting and/or signals, a head-up display, a full or partial transparent display, a flexible display, a rollable display, a foldable display, a laser printer, a phone, a mobile phone, a tablet, a phablet, a personal information terminal (PDA), a wearable device, a laptop computer, a digital camera, a camcorder, a viewfinder, a micro display, a 3D display, a virtual reality or augmented reality display, a vehicle, a video wall including multiple displays tiled together, a theater or stadium screen, a phototherapy device, or a signage.

The above-described light-emitting device ED may be applied to an electronic apparatus, and may serve as a light-emitting portion or a light-emitting unit of the electronic apparatus.

In some embodiments, the electronic apparatus may include the above-described electronic device.

The electronic apparatus may include, e.g., a video wall, a flat panel display, a curved display, a computer monitor, a medical monitor, a television, a billboard, a light for indoor or outdoor lighting and/or signals, a head-up display, a full or partial transparent display, a flexible display, a rollable display, a foldable display, a laser printer, a phone, a mobile phone, a tablet, a phablet, a personal information terminal (PDA), a wearable device, a laptop computer, a digital camera, a camcorder, a viewfinder, a micro display, a 3D display, a virtual reality or augmented reality display, a vehicle, a video wall including multiple displays tiled together, a theater or stadium screen, a phototherapy device, and/or a signage. Hereinafter, an organometallic compound according to an embodiment will be described in detail with reference to Examples and Comparative Examples. The Examples are provided to assist in understanding the disclosure, but they are provided as non-limiting examples, and the scope of the disclosure is not limited thereto. It will be clear to those skilled in the art that various changes and modifications to disclosed examples can be made within the scope of the disclosure.

### Example 1: Synthesis of Compound 23

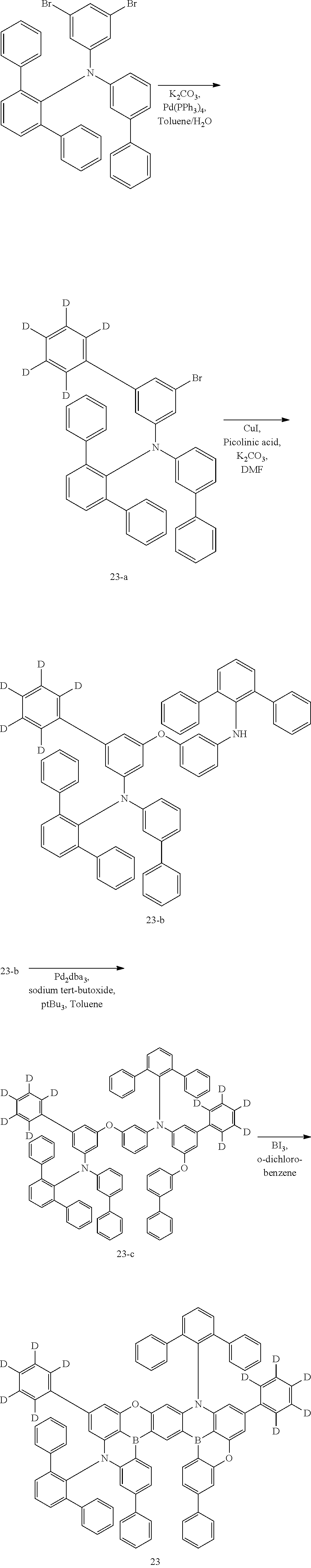

### (1) Synthesis of Intermediate 23-a

Under an argon atmosphere, a 2 L flask was charged with N-([1,1′-biphenyl]-3-yl)-N-(3,5-dibromophenyl)-[1,1′:3′,1″-terphenyl]-2′-amine (10 g, 16 mmol), (phenyl-d5)boronic acid (2 grams (g), 16 millimole (mmol)), pd₂dba₃ (1.6 g, 1.9 mmol), tris-tert-butyl phosphine (1.6 milliliters (mL), 3.8 mmol), and sodium tert-butoxide (5.8 g, 60 mmol). The solution was dissolved in 200 mL of o-xylene, and the reaction solution was stirred at 140° C. for 2 hours. After being cooled, water (1 liters (L)) and ethyl acetate (300 mL) were added for extraction. An organic layer was collected, dried over MgSO₄, and filtered. The filtered solution was depressurized to remove the solvent, and the obtained solid was purified and separated by column chromatography using silica gel, and using CH₂Cl₂ and hexane as developing solvents to obtain an intermediate compound 23-a (white solid, 7 g, 70%).

ESI-LCMS: [M]⁺: C₄₂H₂₅D₅BrN. 633.6496.

### 2) Synthesis of Intermediate Compound 23-b

Under an argon atmosphere, the intermediate compound 23-a (7 g, 11 mmol), 3-([1,1′:3′,1″-terphenyl]-2′-ylamino)phenol (3.7 g, 11 mmol), CuI (2 g, 11 mmol), picolinic acid (1.3 g, 11 mmol), and potassium carbonate (4.1 g, 30 mmol) were added in a 2 L flask, dissolved in 200 mL of DMF, and the reaction solution was stirred at 140° C. for 2 hours. After being cooled, water (1 L) and ethyl acetate (300 mL) were added for extraction. An organic layer was collected, dried over MgSO₄, and filtered. The filtered solution was depressurized to remove the solvent, and the obtained solid was purified and separated by column chromatography using silica gel and using CH₂Cl₂ and hexane as developing solvents to obtain an intermediate compound 23-b (white solid, 7.2 g, 72%).

ESI-LCMS: [M]⁺: C₆₆H₄₃D₅N₂O. 890.1542.

### 3) Synthesis of Intermediate Compound 23-c

Under an argon atmosphere, an intermediate compound 23-b (7 g, 7.8 mmol), 3-([1,1′-biphenyl]-3-yloxy)-5-iodo-1,1′-biphenyl-2′,3′,4′,5′,6′-d5 (3.5 g, 7.8 mmol), pd₂dba₃ (0.7 g, 0.78 mmol), tris-tert-butyl phosphine (0.7 mL, 1.5 mmol), and sodium tert-butoxide (2.9 g, 30 mmol) were added in a 2 L flask, dissolved in 100 mL of o-xylene, and the reaction solution was stirred at 140 degrees for 2 hours. After being cooled, water (1 L) and ethyl acetate (300 mL) were added for extraction. An organic layer was collected, dried over MgSO₄, and filtered. The filtered solution was depressurized to remove the solvent, and the obtained solid was purified and separated by column chromatography using silica gel and using CH₂Cl₂ and hexane as developing solvents to obtain an intermediate compound 23-c (white solid, 6.1 g, 63%).

ESI-LCMS: [M]+: C₉₀H₅₄D₁₀N₂O₂. 1215.5833.

### 4) Synthesis of Compound 23

Under an argon atmosphere, the intermediate compound 23-c (6 g, 5 mmol) was added to a 1 L flask, dissolved in 120 mL of o-dichlorobenzene, and then BBr₃ (4 equiv.) was added. The reaction solution was stirred at 140 degrees for 12 hours. After being cooled, triethylamine was added to terminate the reaction, and the solvent was removed under reduced pressure. The obtained solid was purified and separated by column chromatography using silica gel and using CH₂Cl₂ and hexane as developing solvents to obtain the compound 23 (yellow solid, 1.5 g, 25%).

ESI-LCMS: [M]+: C₉₀H₄₈D₁₀B₂N₂O₂. 1231.1558

1H-NMR (CDCl₃) of the compound 23: δ=8.20 (m, 4H), 7.90 (d, 2H), 7.75 (d, 4H), 7.43 (m, 12H), 7.33 (m, 8H), 7.21 (m, 4H), 7.25 (s, 1H), 7.08 (m, 8H), 6.99 (s, 4H), 6.86 (s, 1H)

### Examples 2 to 8

Condensed heterocyclic compounds were prepared by the same method as that in Example 1, except that intermediate compounds reactants a to c were changed as shown in Table 1 below.

TABLE 1

| | intermediate | intermediate | intermediate | product | |
|---|---|---|---|---|---|
| | compound a | compound b | compound c | compound | |
| Exam- ple 1 | 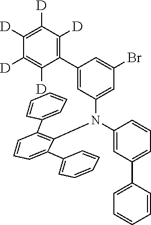 [SMILES: [2H]c1c([2H])c([2H])c(-c2cc(Br)cc(N(c3cccc(-c4ccccc4)c3)c3c(-c4ccccc4)cccc3-c3ccccc3)c2)c([2H])c1[2H]] | 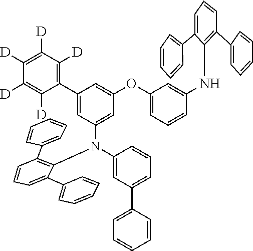 [SMILES: [2H]c1c([2H])c([2H])c(-c2cc(Oc3cccc(Nc4c(-c5ccccc5)cccc4-c4ccccc4)c3)cc(N(c3cccc(-c4ccccc4)c3)c3c(-c4ccccc4)cccc3-c3ccccc3)c2)c([2H])c1[2H]] | 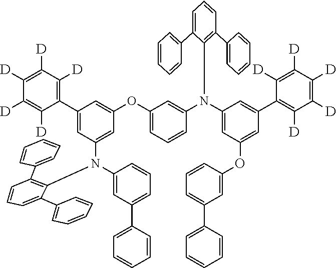 [SMILES: [2H]c1c([2H])c([2H])c(-c2cc(Oc3cccc(-c4ccccc4)c3)cc(N(c3cccc(Oc4cc(-c5c([2H])c([2H])c([2H])c([2H])c5[2H])cc(N(c5cccc(-c6ccccc6)c5)c5c(-c6ccccc6)cccc5-c5ccccc5)c4)c3)c3c(-c4ccccc4)cccc3-c3ccccc3)c2)c([2H])c1[2H]] | 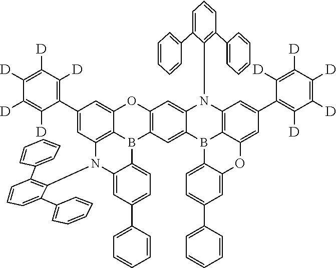 [SMILES: [2H]c1c([2H])c([2H])c(-c2cc3c4c(c2)N(c2c(-c5ccccc5)cccc2-c2ccccc2)c2cc(-c5ccccc5)ccc2B4c2cc4c(cc2O3)N(c2c(-c3ccccc3)cccc2-c2ccccc2)c2cc(-c3c([2H])c([2H])c([2H])c([2H])c3[2H])cc3c2B4c2ccc(-c4ccccc4)cc2O3)c([2H])c1[2H]] | com- pound 23 |
| Exam- ple 2 | 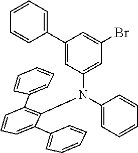 [SMILES: Brc1cc(-c2ccccc2)cc(N(c2ccccc2)c2c(-c3ccccc3)cccc2-c2ccccc2)c1] | 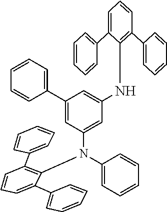 [SMILES: c1ccc(-c2cc(Nc3c(-c4ccccc4)cccc3-c3ccccc3)cc(N(c3ccccc3)c3c(-c4ccccc4)cccc3-c3ccccc3)c2)cc1] | 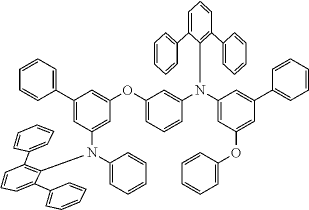 [SMILES: c1ccc(Oc2cc(-c3ccccc3)cc(N(c3cccc(Oc4cc(-c5ccccc5)cc(N(c5ccccc5)c5c(-c6ccccc6)cccc5-c5ccccc5)c4)c3)c3c(-c4ccccc4)cccc3-c3ccccc3)c2)cc1] | 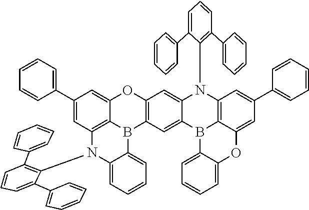 [SMILES: c1ccc(-c2cc3c4c(c2)N(c2c(-c5ccccc5)cccc2-c2ccccc2)c2ccccc2B4c2cc4c(cc2O3)N(c2c(-c3ccccc3)cccc2-c2ccccc2)c2cc(-c3ccccc3)cc3c2B4c2ccccc2O3)cc1] | com- pound 4 |
| Exam- ple 3 | 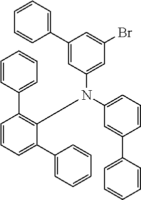 [SMILES: Brc1cc(-c2ccccc2)cc(N(c2cccc(-c3ccccc3)c2)c2c(-c3ccccc3)cccc2-c2ccccc2)c1] | 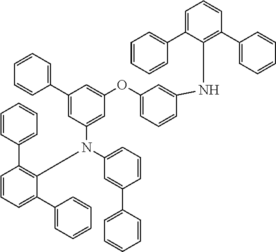 [SMILES: c1ccc(-c2cccc(N(c3cc(Oc4cccc(Nc5c(-c6ccccc6)cccc5-c5ccccc5)c4)cc(-c4ccccc4)c3)c3c(-c4ccccc4)cccc3-c3ccccc3)c2)cc1] | 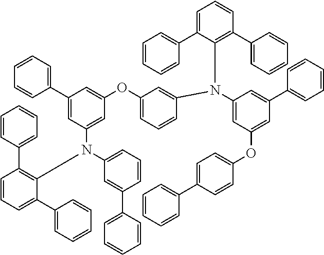 [SMILES: c1ccc(-c2ccc(Oc3cc(-c4ccccc4)cc(N(c4cccc(Oc5cc(-c6ccccc6)cc(N(c6cccc(-c7ccccc7)c6)c6c(-c7ccccc7)cccc6-c6ccccc6)c5)c4)c4c(-c5ccccc5)cccc4-c4ccccc4)c3)cc2)cc1] | 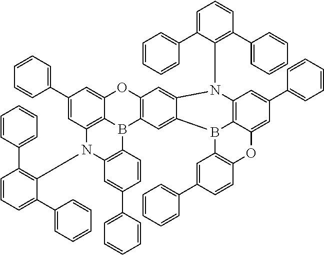 [SMILES: c1ccc(-c2ccc3c(c2)B2c4cc5c(cc4N(c4c(-c6ccccc6)cccc4-c4ccccc4)c4cc(-c6ccccc6)cc(c42)O3)Oc2cc(-c3ccccc3)cc3c2B5c2ccc(-c4ccccc4)cc2N3c2c(-c3ccccc3)cccc2-c2ccccc2)cc1] | com- pound 31 |
| Exam- ple 4 | 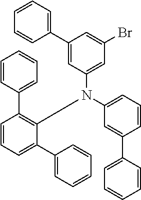 [SMILES: Brc1cc(-c2ccccc2)cc(N(c2cccc(-c3ccccc3)c2)c2c(-c3ccccc3)cccc2-c2ccccc2)c1] | 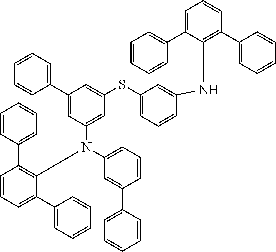 [SMILES: c1ccc(-c2cccc(N(c3cc(Sc4cccc(Nc5c(-c6ccccc6)cccc5-c5ccccc5)c4)cc(-c4ccccc4)c3)c3c(-c4ccccc4)cccc3-c3ccccc3)c2)cc1] | 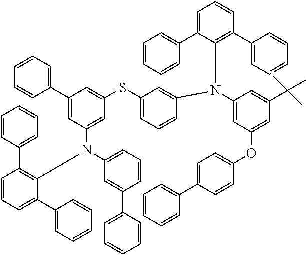 [SMILES: CC(C)(C)c1cc(Oc2ccc(-c3ccccc3)cc2)cc(N(c2cccc(Sc3cc(-c4ccccc4)cc(N(c4cccc(-c5ccccc5)c4)c4c(-c5ccccc5)cccc4-c4ccccc4)c3)c2)c2c(-c3ccccc3)cccc2-c2ccccc2)c1] | 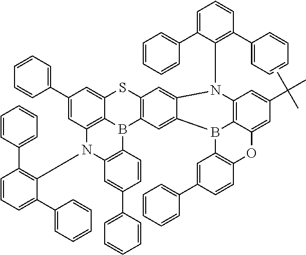 [SMILES: CC(C)(C)c1cc2c3c(c1)N(c1c(-c4ccccc4)cccc1-c1ccccc1)c1cc4c(cc1B3c1cc(-c3ccccc3)ccc1O2)B1c2ccc(-c3ccccc3)cc2N(c2c(-c3ccccc3)cccc2-c2ccccc2)c2cc(-c3ccccc3)cc(c21)S4] | com- pound 41 |
| Exam- ple 5 | 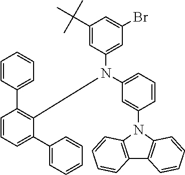 [SMILES: CC(C)(C)c1cc(Br)cc(N(c2cccc(-n3c4ccccc4c4ccccc43)c2)c2c(-c3ccccc3)cccc2-c2ccccc2)c1] | 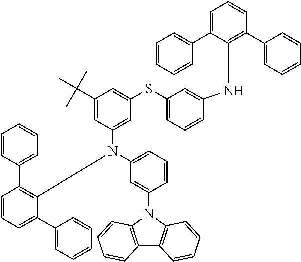 [SMILES: CC(C)(C)c1cc(Sc2cccc(Nc3c(-c4ccccc4)cccc3-c3ccccc3)c2)cc(N(c2cccc(-n3c4ccccc4c4ccccc43)c2)c2c(-c3ccccc3)cccc2-c2ccccc2)c1] | 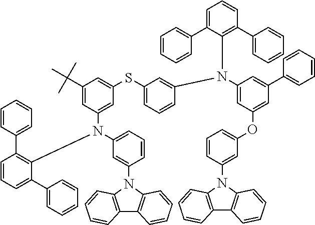 [SMILES: CC(C)(C)c1cc(Sc2cccc(N(c3cc(Oc4cccc(-n5c6ccccc6c6ccccc65)c4)cc(-c4ccccc4)c3)c3c(-c4ccccc4)cccc3-c3ccccc3)c2)cc(N(c2cccc(-n3c4ccccc4c4ccccc43)c2)c2c(-c3ccccc3)cccc2-c2ccccc2)c1] | 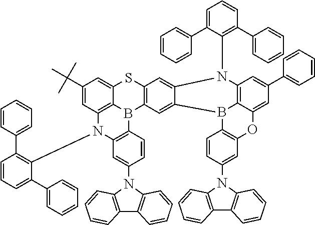 [SMILES: CC(C)(C)c1cc2c3c(c1)N(c1c(-c4ccccc4)cccc1-c1ccccc1)c1cc(-n4c5ccccc5c5ccccc54)ccc1B3c1cc3c(cc1S2)N(c1c(-c2ccccc2)cccc1-c1ccccc1)c1cc(-c2ccccc2)cc2c1B3c1ccc(-n3c4ccccc4c4ccccc43)cc1O2] | com- pound 47 |
| Exam- ple 6 | 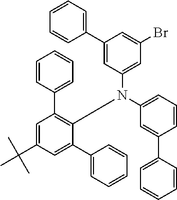 [SMILES: CC(C)(C)c1cc(-c2ccccc2)c(N(c2cccc(-c3ccccc3)c2)c2cc(Br)cc(-c3ccccc3)c2)c(-c2ccccc2)c1] | 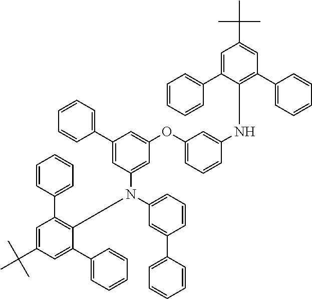 [SMILES: CC(C)(C)c1cc(-c2ccccc2)c(Nc2cccc(Oc3cc(-c4ccccc4)cc(N(c4cccc(-c5ccccc5)c4)c4c(-c5ccccc5)cc(C(C)(C)C)cc4-c4ccccc4)c3)c2)c(-c2ccccc2)c1] | 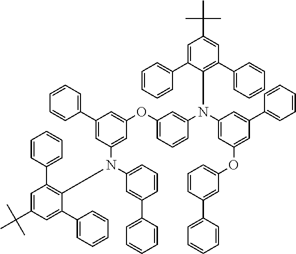 [SMILES: CC(C)(C)c1cc(-c2ccccc2)c(N(c2cccc(Oc3cc(-c4ccccc4)cc(N(c4cccc(-c5ccccc5)c4)c4c(-c5ccccc5)cc(C(C)(C)C)cc4-c4ccccc4)c3)c2)c2cc(Oc3cccc(-c4ccccc4)c3)cc(-c3ccccc3)c2)c(-c2ccccc2)c1] | 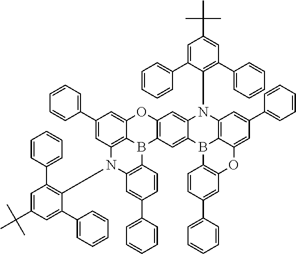 [SMILES: CC(C)(C)c1cc(-c2ccccc2)c(N2c3cc(-c4ccccc4)ccc3B3c4cc5c(cc4Oc4cc(-c6ccccc6)cc2c43)N(c2c(-c3ccccc3)cc(C(C)(C)C)cc2-c2ccccc2)c2cc(-c3ccccc3)cc3c2B5c2ccc(-c4ccccc4)cc2O3)c(-c2ccccc2)c1] | com- pound 52 |
| Exam- ple 7 | 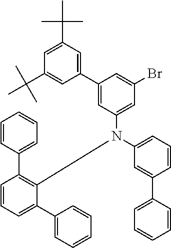 [SMILES: CC(C)(C)c1cc(-c2cc(Br)cc(N(c3cccc(-c4ccccc4)c3)c3c(-c4ccccc4)cccc3-c3ccccc3)c2)cc(C(C)(C)C)c1] | 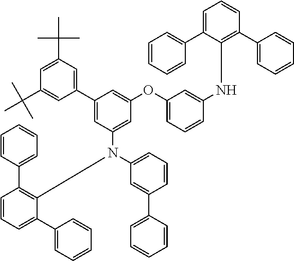 [SMILES: CC(C)(C)c1cc(-c2cc(Oc3cccc(Nc4c(-c5ccccc5)cccc4-c4ccccc4)c3)cc(N(c3cccc(-c4ccccc4)c3)c3c(-c4ccccc4)cccc3-c3ccccc3)c2)cc(C(C)(C)C)c1] | 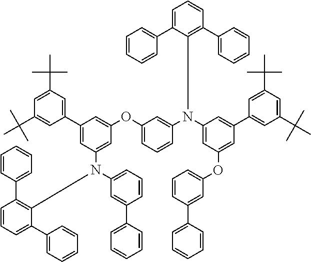 [SMILES: CC(C)(C)c1cc(-c2cc(Oc3cccc(-c4ccccc4)c3)cc(N(c3cccc(Oc4cc(-c5cc(C(C)(C)C)cc(C(C)(C)C)c5)cc(N(c5cccc(-c6ccccc6)c5)c5c(-c6ccccc6)cccc5-c5ccccc5)c4)c3)c3c(-c4ccccc4)cccc3-c3ccccc3)c2)cc(C(C)(C)C)c1] | 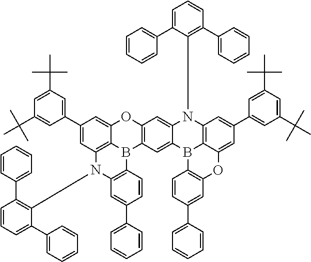 [SMILES: CC(C)(C)c1cc(-c2cc3c4c(c2)N(c2c(-c5ccccc5)cccc2-c2ccccc2)c2cc(-c5ccccc5)ccc2B4c2cc4c(cc2O3)N(c2c(-c3ccccc3)cccc2-c2ccccc2)c2cc(-c3cc(C(C)(C)C)cc(C(C)(C)C)c3)cc3c2B4c2ccc(-c4ccccc4)cc2O3)cc(C(C)(C)C)c1] | com- pound 62 |
| Exam- ple 8 | 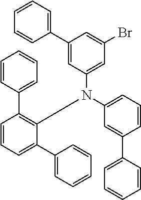 [SMILES: Brc1cc(-c2ccccc2)cc(N(c2cccc(-c3ccccc3)c2)c2c(-c3ccccc3)cccc2-c2ccccc2)c1] | 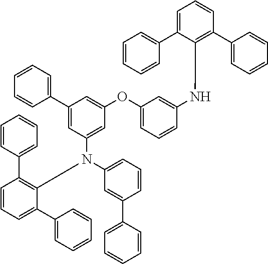 [SMILES: c1ccc(-c2cccc(N(c3cc(Oc4cccc(Nc5c(-c6ccccc6)cccc5-c5ccccc5)c4)cc(-c4ccccc4)c3)c3c(-c4ccccc4)cccc3-c3ccccc3)c2)cc1] | 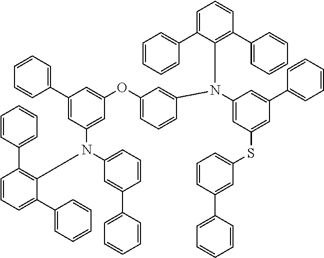 [SMILES: c1ccc(-c2cccc(Sc3cc(-c4ccccc4)cc(N(c4cccc(Oc5cc(-c6ccccc6)cc(N(c6cccc(-c7ccccc7)c6)c6c(-c7ccccc7)cccc6-c6ccccc6)c5)c4)c4c(-c5ccccc5)cccc4-c4ccccc4)c3)c2)cc1] | 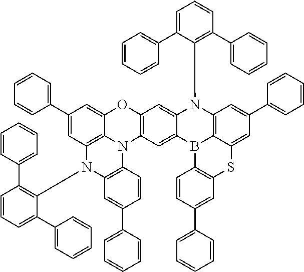 [SMILES: c1ccc(-c2ccc3c(c2)Sc2cc(-c4ccccc4)cc4c2B3c2cc3c(cc2N4c2c(-c4ccccc4)cccc2-c2ccccc2)Oc2cc(-c4ccccc4)cc4c2N3c2ccc(-c3ccccc3)cc2N4c2c(-c3ccccc3)cccc2-c2ccccc2)cc1] | com- pound 79 |

### Comparative Examples 1 to 7

Compounds represented by chemical formulas C1 to C7 below were used as compounds of Comparative Examples.

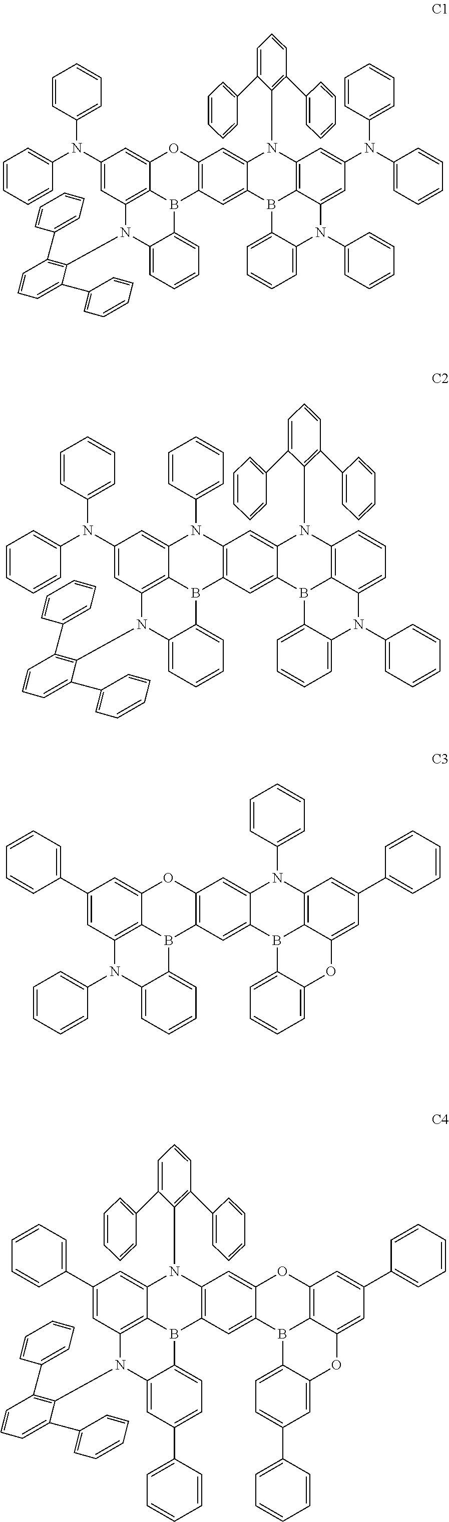

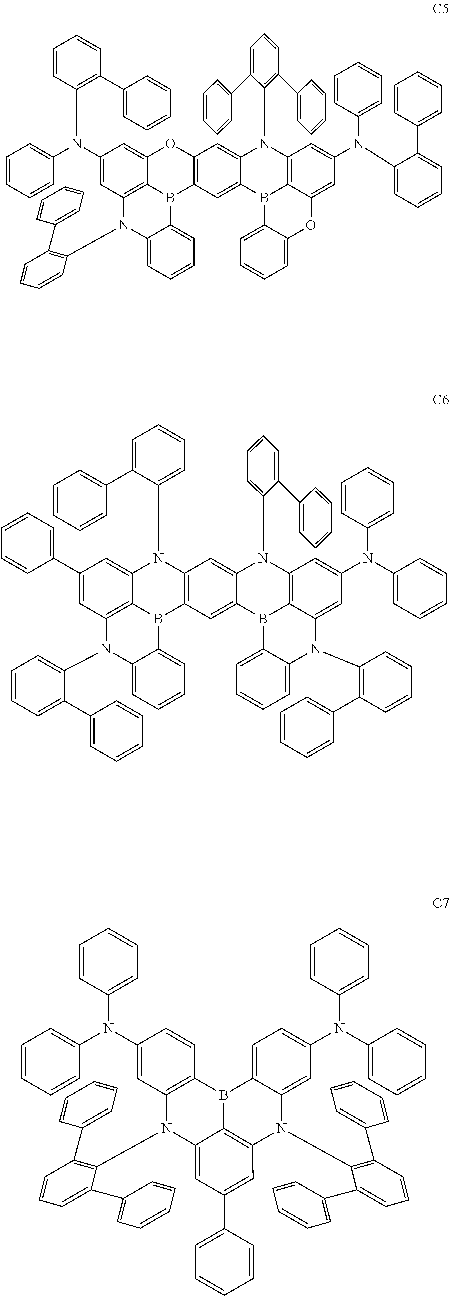 [SMILES: c1ccc(-c2ccccc2N(c2ccccc2)c2cc3c4c(c2)N(c2ccccc2-c2ccccc2)c2ccccc2B4c2cc4c(cc2O3)N(c2c(-c3ccccc3)cccc2-c2ccccc2)c2cc(N(c3ccccc3)c3ccccc3-c3ccccc3)cc3c2B4c2ccccc2O3)cc1 ; c1ccc(-c2cc3c4c(c2)N(c2ccccc2-c2ccccc2)c2cc5c(cc2B4c2ccccc2N3c2ccccc2-c2ccccc2)B2c3ccccc3N(c3ccccc3-c3ccccc3)c3cc(N(c4ccccc4)c4ccccc4)cc(c32)N5c2ccccc2-c2ccccc2)cc1 ; c1ccc(-c2cc3c4c(c2)N(c2c(-c5ccccc5)cccc2-c2ccccc2)c2cc(N(c5ccccc5)c5ccccc5)ccc2B4c2ccc(N(c4ccccc4)c4ccccc4)cc2N3c2c(-c3ccccc3)cccc2-c2ccccc2)cc1]

### Measurement Examples

For each of the compounds of Examples and Comparative Examples, a HOMO (Highest occupied molecular orbital) energy level, an emission wavelength (λₑₘᵢ) in a film phase, an absorption wavelength (λ_{Abs}) and an emission wavelength (λₑₘᵢ₎ in a solution phase, a difference between a maximum wavelength when absorbing energy and a maximum wavelength when emitting energy (λₑₘᵢ-λ_{Abs}; Stokes-shift), a luminescence efficiency (PLQY, Photoluminescence Quantum Yield), and a delayed fluorescence lifetime (τD) were measured and the results are shown in Table 2.
(1) λ_{Abs} was measured using Labsolution UV-Vis software with a SHIMADZU UV-1800 ultraviolet visual (UV)/Visible Scanning Spectrophotometer equipped with a deuterium/tungsten-halogen light source and a silicon photodiode.
(2) λₑₘᵢ was measured using FluorEssence software with a HORIBA fluoromax+spectrometer equipped with a xenon light source and a monochromator.
(3) PLQY was measured using PLQY measurement software with a Hamamatsu Quantaurus-QY Absolute PL quantum yield spectrometer equipped with a xenon light source, a monochromator, a photonic multichannel analyzer and an integrating sphere.

TABLE 2

| | | solution phase | | | film | | | |
|---|---|---|---|---|---|---|---|---|
| | compound | | | Stokes- | phase | Homo | PLQY | FWQM |
| | No. | λ_{Abs}(nm) | λₑₘᵢ(nm) | shift | λₑₘᵢ(nm) | (eV) | (%) | (nm) |
| Example 1 | compound 23 | 451 | 458 | 7 | 458 | −5.35 | 99 | 22 |
| Example 2 | compound 4 | 443 | 450 | 7 | 451 | −5.33 | 99 | 22 |
| Example 3 | compound 31 | 450 | 457 | 7 | 457 | −5.36 | 99 | 21 |
| Example 4 | compound 41 | 452 | 458 | 6 | 458 | −5.31 | 97 | 21 |
| Example 5 | compound 47 | 453 | 459 | 6 | 459 | −5.39 | 98 | 21 |
| Example 6 | compound 52 | 451 | 458 | 7 | 458 | −5.34 | 99 | 22 |
| Example 7 | compound 62 | 452 | 458 | 6 | 458 | −5.38 | 99 | 22 |
| Example 8 | compound 79 | 453 | 458 | 5 | 458 | −5.33 | 99 | 21 |
| Comparative | compound C1 | 447 | 458 | 11 | 459 | −5.21 | 90 | 28 |
| Example 1 | | | | | | | | |
| Comparative | compound C2 | 449 | 461 | 12 | 463 | −5.16 | 88 | 27 |
| Example 2 | | | | | | | | |
| Comparative | compound C3 | 440 | 450 | 10 | 454 | −5.33 | 95 | 26 |
| Example 3 | | | | | | | | |
| Comparative | compound C4 | 460 | 474 | 14 | 479 | −5.25 | 42 | 29 |
| Example 4 | | | | | | | | |
| Comparative | compound C5 | 435 | 448 | 13 | 450 | −5.12 | 79 | 33 |
| Example 5 | | | | | | | | |
| Comparative | compound C6 | 440 | 453 | 13 | 455 | −5.22 | 89 | 26 |
| Example 6 | | | | | | | | |
| Comparative | compound C7 | 442 | 456 | 14 | 458 | −5.15 | 91 | 34 |
| Example 7 | | | | | | | | |

### Fabrication of Light-Emitting Device

As an anode, a glass substrate (Corning product) on which a 15 ohm per square centimeters (Ω/cm²) (1200 Å) ITO electrode was formed was cut into a size of 50 millimeters (mm)×50 mm×0.7 mm, and the cut substrate was ultrasonically cleaned for 5 minutes using isopropyl alcohol and pure water. The ultrasonically cleaned substrate was irradiated with an ultraviolet ray for 30 minutes and exposed to ozone, and then mounted on a vacuum deposition device.

Thereafter, NPD was vacuum-deposited on the anode to form a hole injection layer having a thickness of 300 Å. HTL-1 was deposited on the hole injection layer to form a hole transport layer, and then CzSi was deposited on the hole transport layer to form an electron blocking layer having a thickness of 100 Å.

A host mixture compound in which HT-1 and ET-1 were mixed in a weight ratio of 1:1, PS-1, and a dopant compound shown in Table 3 below were co-deposited in a weight ratio of 85:14:1 to form an emission layer having a thickness of 300 Å. TSPO1 was deposited on the emission layer to form a hole blocking layer having a thickness of 200 Å.

TPBi was deposited on the hole blocking layer to form an electron transport layer having a thickness of 300 Å, and then LiF was deposited on the electron transport layer to form an electron injection layer having a thickness of 10 Å. A second electrode having a thickness of 3000 Å was formed of Al to form a LiF/Al electrode. Thereafter, a capping layer having a thickness of 700 Å was formed of CPL-1 on the electrode. Each layer was formed by a vacuum-deposition. The compounds used in the fabrication of the light-emitting device are shown below. The following materials were commercially available products and purified by sublimation.

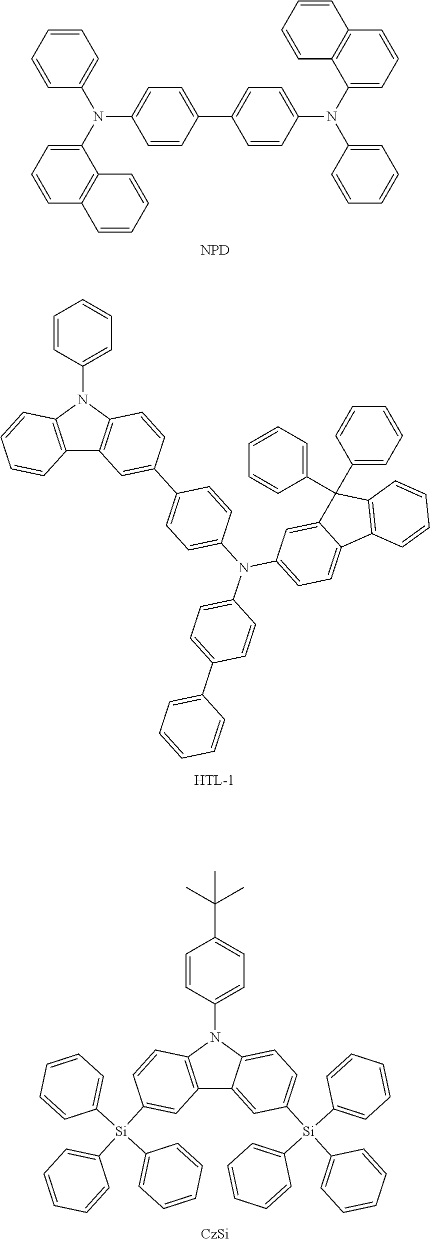

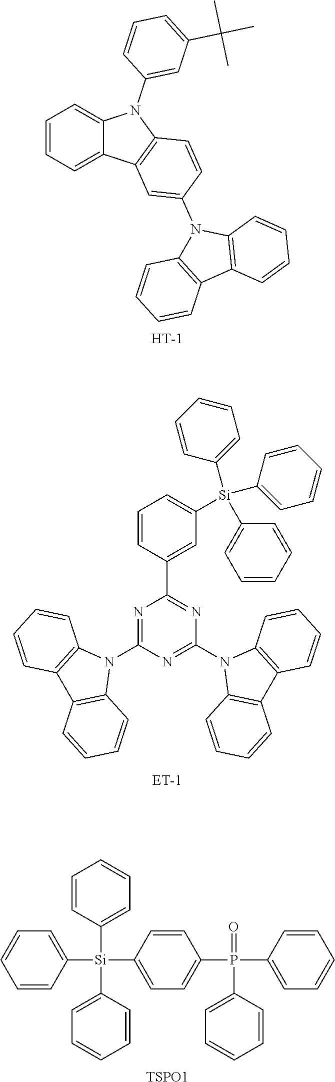

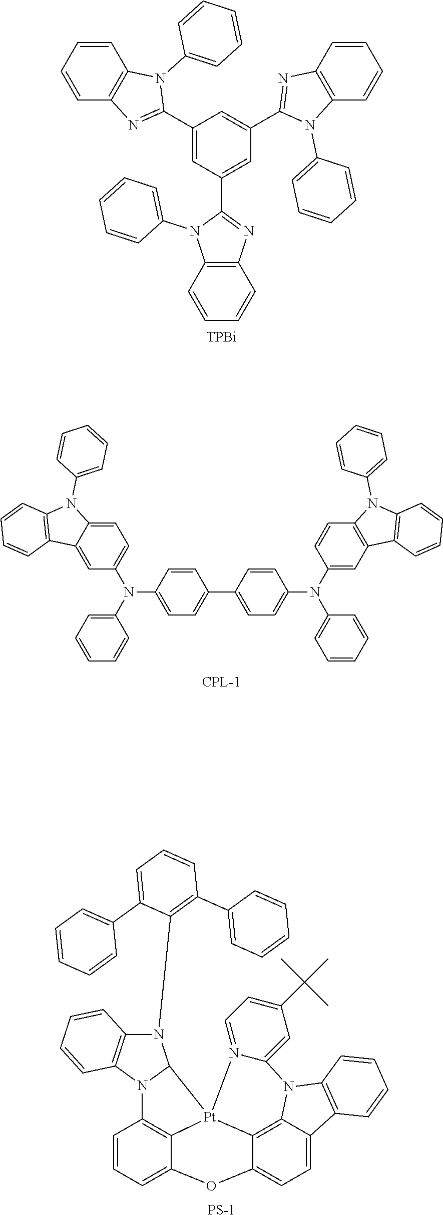

### Evaluation Example

Properties of the light-emitting device were measured as follows, and the results are shown in Table 3 below.
1) A driving voltage and an efficiency (candela per ampere (cd/A)) at a current density of 10 milliampere per square centimeters (mA/cm²) were measured using the V7000 OLED IVL Test System (Polaronix).
2) A duration from an initial luminance to 95% luminance degradation when continuously driven at a current density of 10 mA/cm² relative to a value from Comparative Example 1 was measured as a relative device life-span.

TABLE 3

| | | driving | front | emission | life- | |
|---|---|---|---|---|---|---|
| | | voltage | efficiency | wavelength | span | CIE |
| | dopant | (V) | (cd/A/y) | (nm) | (T95) | y |
| Example 1 | compound 23 | 3.8 | 550 | 458 | 10.1 | 0.047 |
| Example 2 | compound 4 | 3.7 | 580 | 451 | 7.4 | 0.035 |
| Example 3 | compound 31 | 3.7 | 570 | 457 | 12.7 | 0.046 |
| Example 4 | compound 41 | 3.7 | 560 | 458 | 4.9 | 0.048 |
| Example 5 | compound 47 | 3.6 | 600 | 459 | 8.2 | 0.049 |
| Example 6 | compound 52 | 3.6 | 600 | 458 | 8.2 | 0.048 |
| Example 7 | compound 62 | 3.7 | 590 | 458 | 6.5 | 0.047 |
| Example 8 | compound 79 | 3.7 | 550 | 458 | 2.7 | 0.047 |
| Comparative | compound C1 | 4.3 | 400 | 459 | 1 | 0.052 |
| Example 1 | | | | | | |
| Comparative | compound C2 | 4.4 | 430 | 463 | 0.8 | 0.059 |
| Example 2 | | | | | | |
| Comparative | compound C3 | 4.0 | 450 | 454 | 2.1 | 0.049 |
| Example 3 | | | | | | |
| Comparative | compound C4 | 4.8 | 290 | 479 | 0.3 | 0.072 |
| Example 4 | | | | | | |
| Comparative | compound C5 | 4.6 | 400 | 449 | 0.07 | 0.035 |
| Example 5 | | | | | | |
| Comparative | compound C6 | 4.0 | 430 | 455 | 0.1 | 0.043 |
| Example 6 | | | | | | |
| Comparative | compound C7 | 3.8 | 500 | 460 | 0.2 | 0.055 |
| Example 7 | | | | | | |

Referring to Tables 2 and 3, the condensed heterocyclic compounds of Examples had a Homo level of −5.3 eV or less, a luminescence efficiency of 97% or more, a Stokes shift of 10 nm or less, and a luminescence quarter width (FWQM) of 22 nm or less. Accordingly, the light-emitting device having a low driving voltage of 3.8 V or less, a high efficiency of 550 cd/A or more, an improved CIE color coordinate property of 0.05 or less, and a 95% life-span that was 2.7 times or more than that of Comparative Example 1 was implemented.

The compounds of Comparative Examples did not satisfy the structure of Chemical Formula 1, and the light-emitting devices of Comparative Examples provided degraded properties than those from the light-emitting devices of Examples.

In the compounds C1 and C2 in Comparative Examples 1 and 2, nitrogen having an aryl group is bonded to the X₁ and/or X₂ positions of Chemical Formula 1, and the HOMO level was significantly lowered and the luminescence efficiency was slightly degraded. Accordingly, the life-span and the efficiency of the light-emitting device was also deteriorated.

In the compound C4 of Comparative Example 4, the X₁ position of Chemical Formula 1 is shifted, and oxygen atoms are concentrated at one side of the molecule to cause an imbalance in the molecule. Accordingly, the luminescence efficiency of the compound was significantly reduced, and the driving voltage of the light-emitting device was increased. The efficiency of the light-emitting device was also deteriorated. Further, the color coordinate property of the light-emitting device were significantly reduced compared to those from the light-emitting devices of Examples.

In the compounds C3 and C5 of Comparative Examples 3 and 5, a phenyl group or a biphenyl group, not a terphenyl group, was bonded to the R₁ and/or R₂ positions of Chemical Formula 1, and the HOMO level was decreased, the life-span or the efficiency of the light-emitting device was deteriorated.

In the compound C6 of Comparative Example 6, nitrogen having an aryl group was bonded to the X₁ and X₂ positions of Chemical Formula 1, and a biphenyl group, not a terphenyl group, was bonded to the R₁ and/or R₂ positions. In the compound C7 of Comparative Example 7, a different core structure from that of Chemical Formula 1 is included. In Comparative Examples 6 and 7, the HOMO level was slightly reduced and the Stokes shift increased. Accordingly, the life-span of the light-emitting element was deteriorated.

What is claimed is:

1. A condensed heterocyclic compound represented by Chemical Formula 1: 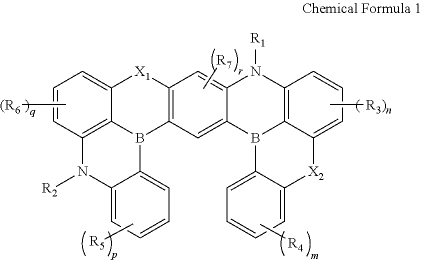
wherein, in Chemical Formula 1, X₁ and X₂ are each independently O, S or Se, and
R₁ and R₂ are each independently represented by Chemical Formula 2: 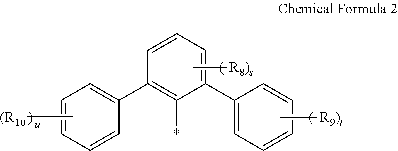
wherein, in Chemical Formulae 1 and 2, R₃ to R₁₀ are each independently hydrogen, deuterium, halogen, a hydroxyl group, a cyano group, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group, a substituted or unsubstituted C₈-C₆₀ condensed polycyclic group, —SiRR′R″, —P(═O)RR′, —NRR′, —BRR′, —C(═O)R or —S(═O)₂R; or
two or more of R₃ to R₁₀ are combined with each other to form a substituted or unsubstituted C₃-C₆₀ cycloalkyl ring, a substituted or unsubstituted C₅-C₆₀ cycloalkenyl ring, a substituted or unsubstituted C₃-C₆₀ heterocycloalkyl ring, a substituted or unsubstituted C₃-C₆₀ heterocycloalkenyl ring, a substituted or unsubstituted C₆-C₆₀ aryl ring, or a substituted or unsubstituted C₂-C₆₀ heteroaryl ring,
wherein R, R′ and R″ are each independently hydrogen, deuterium, halogen, a hydroxyl group, a cyano group, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group or a substituted or unsubstituted C₈-C₆₀ condensed polycyclic group,
n, q and s are each independently an integer from 0 to 3,
m and p are each independently an integer from 0 to 4,
r is an integer from 0 to 2,
t and u are each independently an integer from 0 to 5,
when n, m, p, q, r, s, t and u are each 2 or more, two or more of each of R₃ to R₁₀ are the same or different from each other, and
* represents a bonding position.

2. The condensed heterocyclic compound of claim 1, wherein the condensed heterocyclic compound is represented by any one of Chemical Formulae 1-1 to 1-6: 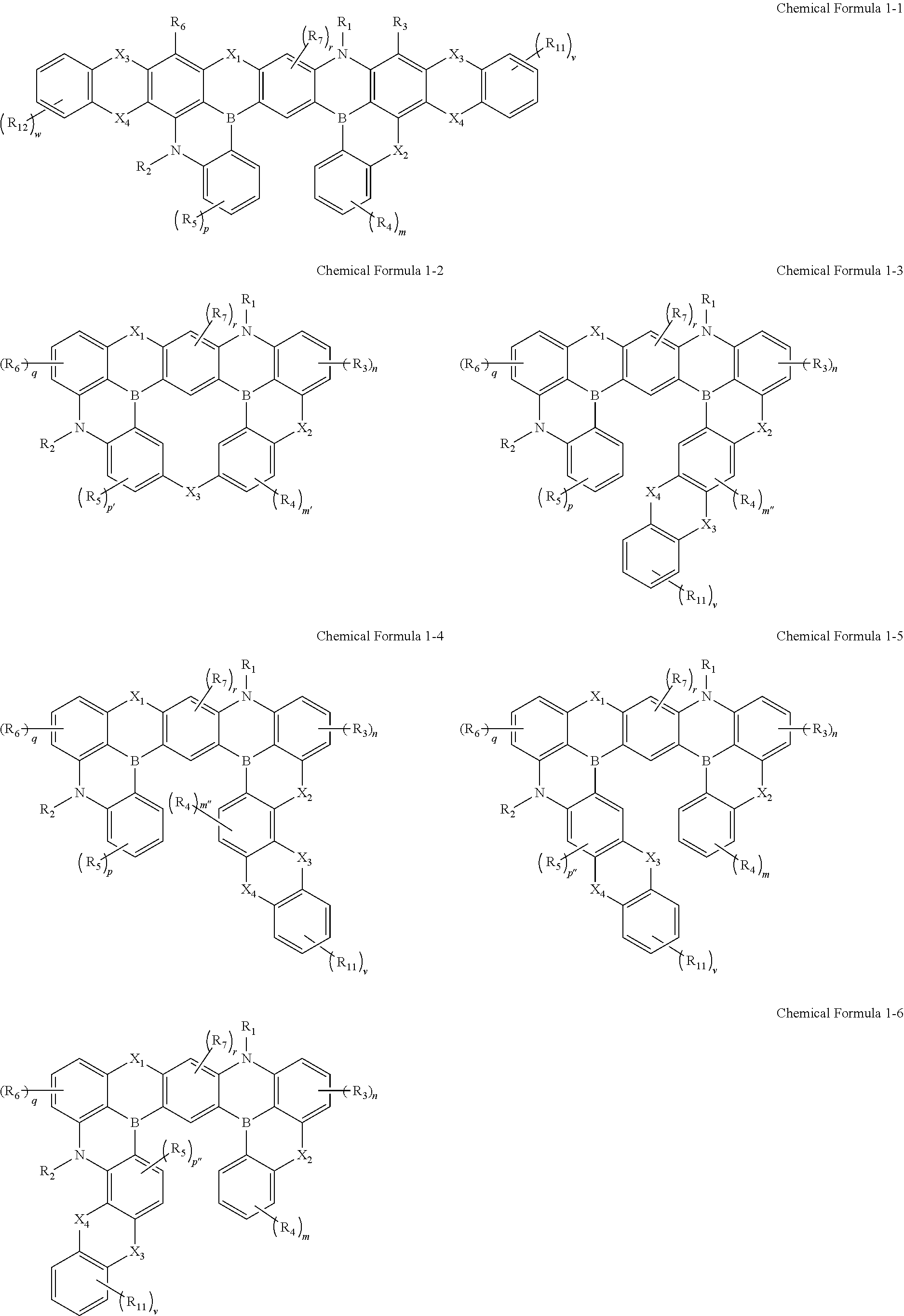
wherein, in Chemical Formulae 1-1 and 1-6, t, X₁ and X₂, R₁ to R₇, n, m, p, q and r are the same as those defined by Chemical Formulae 1 and 2,
X₃ and X₄ are each independently a direct bond, O, S, Se, NR or CRR′,
R₁₁ and R₁₂ are each independently hydrogen, deuterium, halogen, a cyano group, a hydroxyl group, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group, a substituted or unsubstituted C₈-C₆₀ condensed polycyclic group, —SiRR′R″, —P(═O)RR′, —NRR′, —BRR′, —C(═O)RR′ or —S(═O)₂R,
R, R′ and R″ are the same as those defined in Chemical Formulae 1 and 2,
v and w are each independently an integer from 0 to 4,
p′ and m′ are each independently an integer from 0 to 3,
p″ and m″ are each independently an integer from 0 to 2,
when v, w, p′, m′, p″ and m″ are 2 or more, two or more of each of R₄, R₅, R₁₁ and R₁₂ are each independently the same or different from each other.

3. The condensed heterocyclic compound of claim 1, wherein, in Chemical Formula 2, the R₈ to R₁₀ are each independently hydrogen or deuterium.

4. The condensed heterocyclic compound of claim 1, wherein the condensed heterocyclic compound is represented by Chemical Formula 1-7: 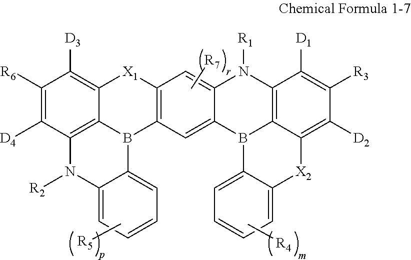
wherein, in Chemical Formula 1-7, X₁ to X₂, R₁ to R₇, m, p, and r are the same as those defined in Chemical Formula 1, and D1 to D4 are each independently hydrogen or deuterium.

5. The condensed heterocyclic compound of claim 1, wherein, in Chemical Formulae 1 and 2, R₃ to R₁₀ are each independently a substituted or unsubstituted C₆-C₂₀ aryl group, or a substituted or unsubstituted C₂-C₁₅ heteroaryl group.

6. The condensed heterocyclic compound of claim 1, wherein, in Chemical Formula 1, n, m, p, and q are each independently 0 or 1.

7. The condensed heterocyclic compound of claim 1, wherein, in Chemical Formula 2, s, t, and u are each independently 0 or 1.

8. The condensed heterocyclic compound of claim 1, wherein, in Chemical Formulae 1 and 2, R₃ to R₁₀ are each independently hydrogen, deuterium, a cyano group, a C₄-C₁₅ tert-alkyl group substituted or unsubstituted with deuterium, a C₃-C₁₅ trialkylsilyl group substituted or unsubstituted with deuterium, a C₁₈-C₄₀ triarylsilyl group substituted or unsubstituted with deuterium, a phenyl group substituted or unsubstituted with deuterium, a cyanophenyl group substituted or unsubstituted with deuterium, a C₇-C₂₀ alkylphenyl group substituted or unsubstituted with deuterium, a biphenyl group substituted or unsubstituted with deuterium, a terphenyl group substituted or unsubstituted with deuterium, a naphthalene group substituted or unsubstituted with deuterium, a tetrahydronaphthalene group substituted or unsubstituted with deuterium, a C₁₁-C₄₀ alkyltetrahydronaphthalene group substituted or unsubstituted with deuterium, a C₁₂-C₂₀ diarylamine group substituted or unsubstituted with deuterium, a carbazole group substituted or unsubstituted with deuterium, a dibenzofuran group substituted or unsubstituted with deuterium, a phenothiazine group substituted or unsubstituted with deuterium, or a pyridine group substituted or unsubstituted with deuterium.

9. The condensed heterocyclic compound of claim 1, wherein the condensed heterocyclic compound comprises at least one of compounds represented by chemical formulae below:

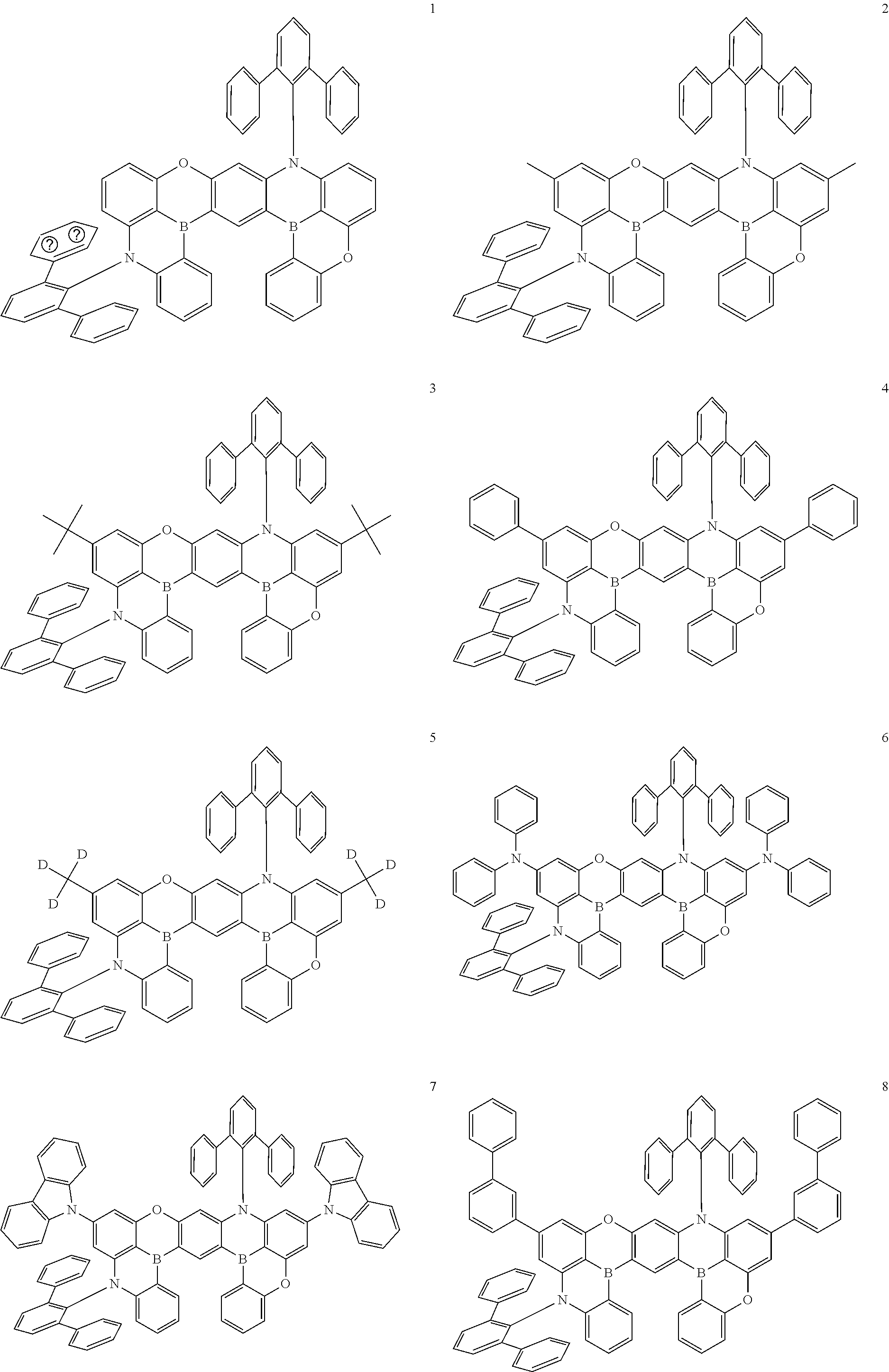

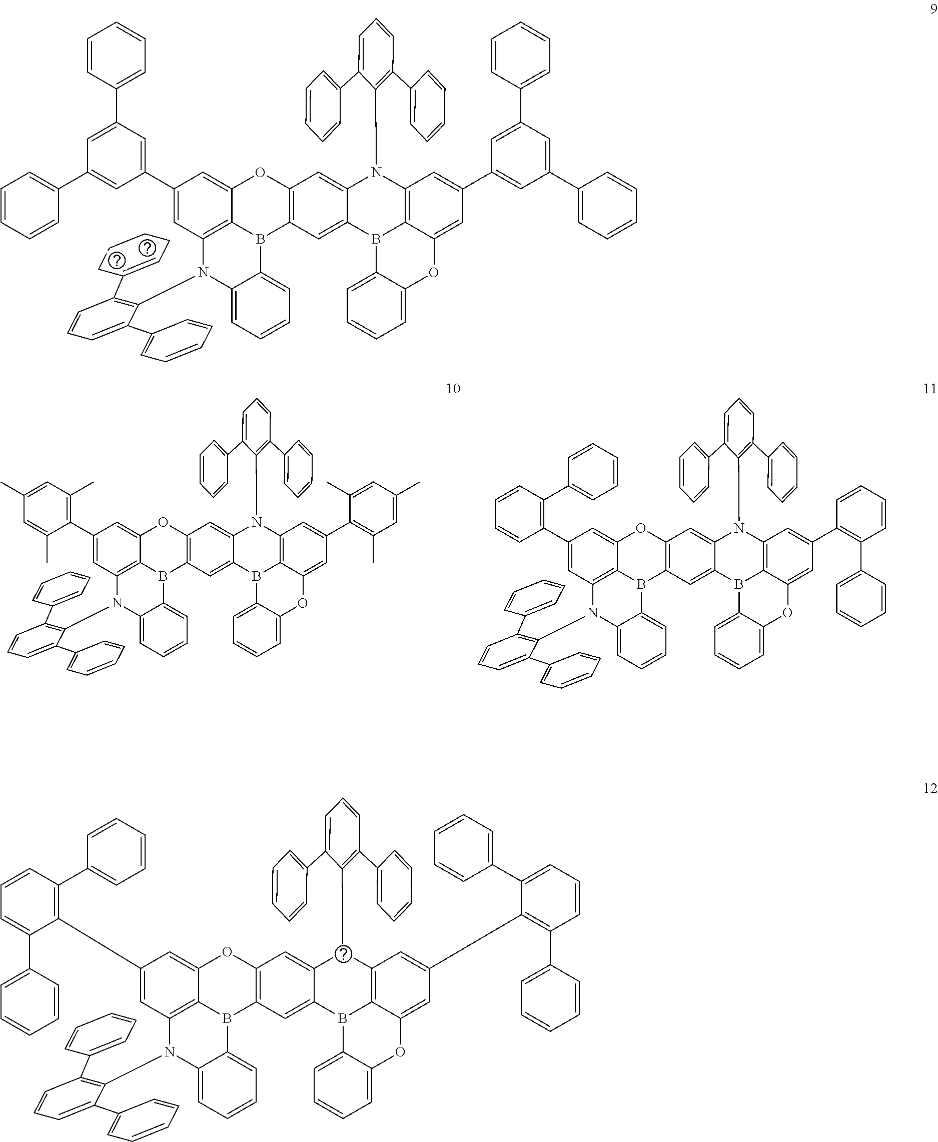

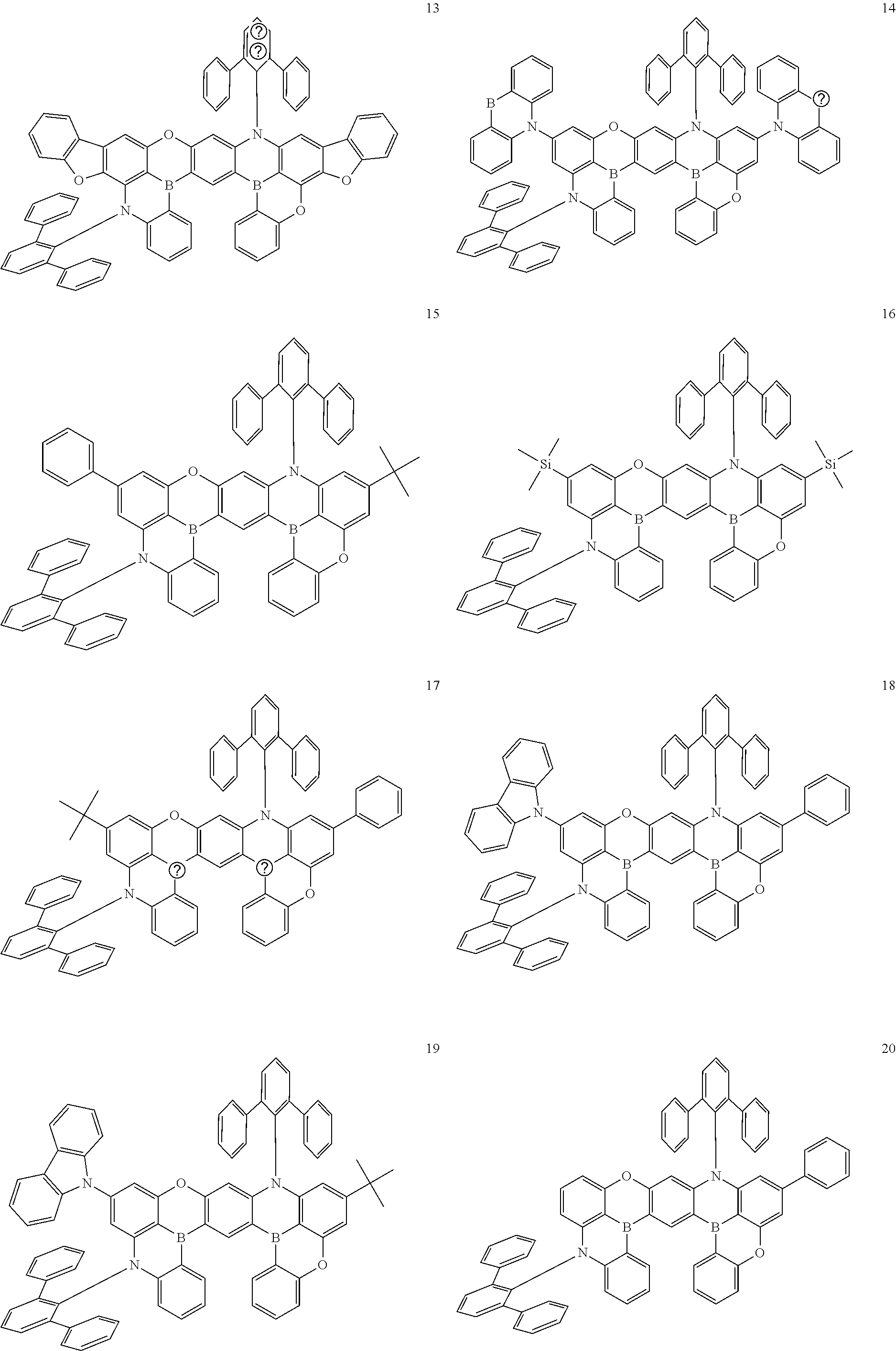

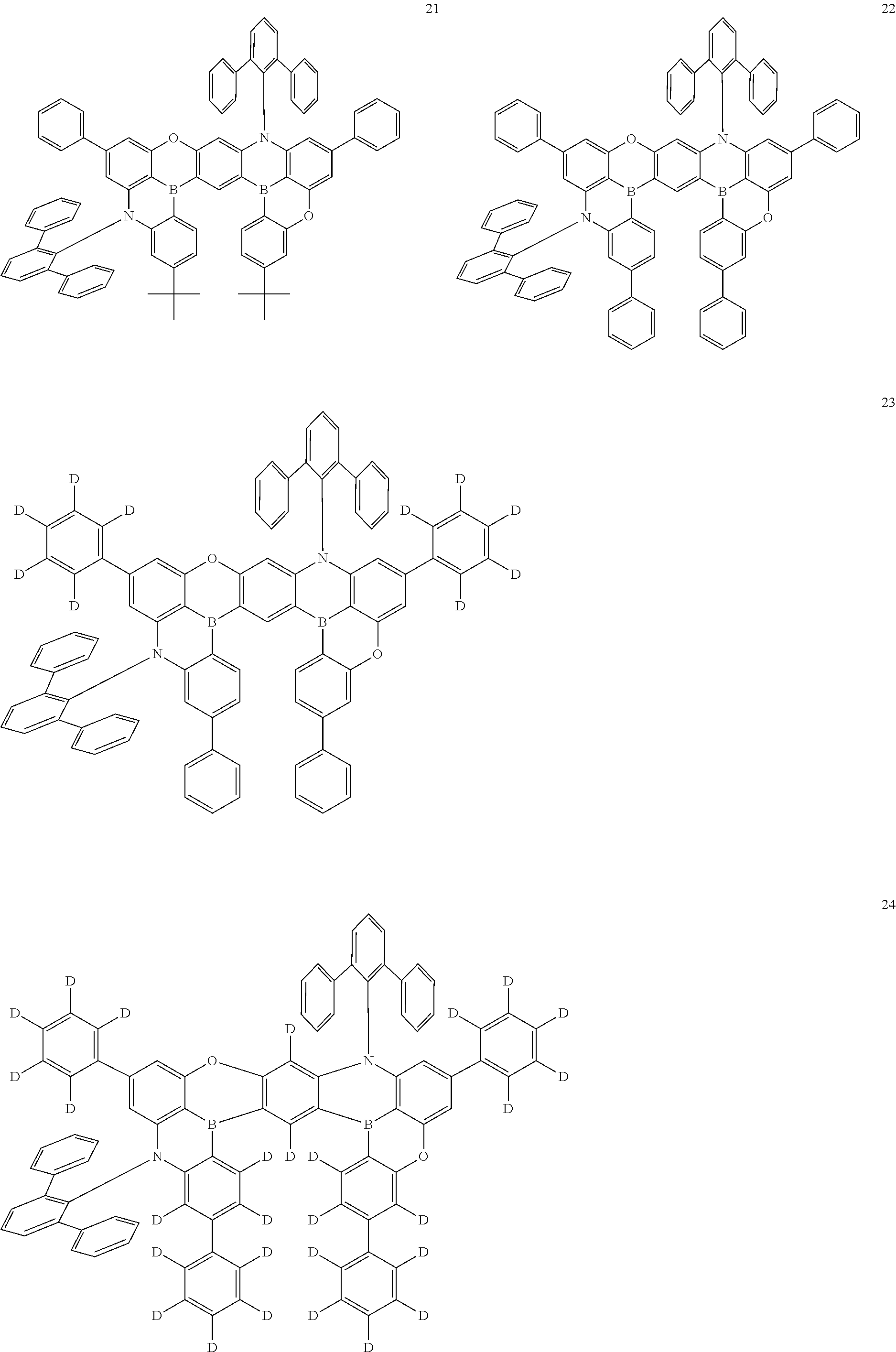

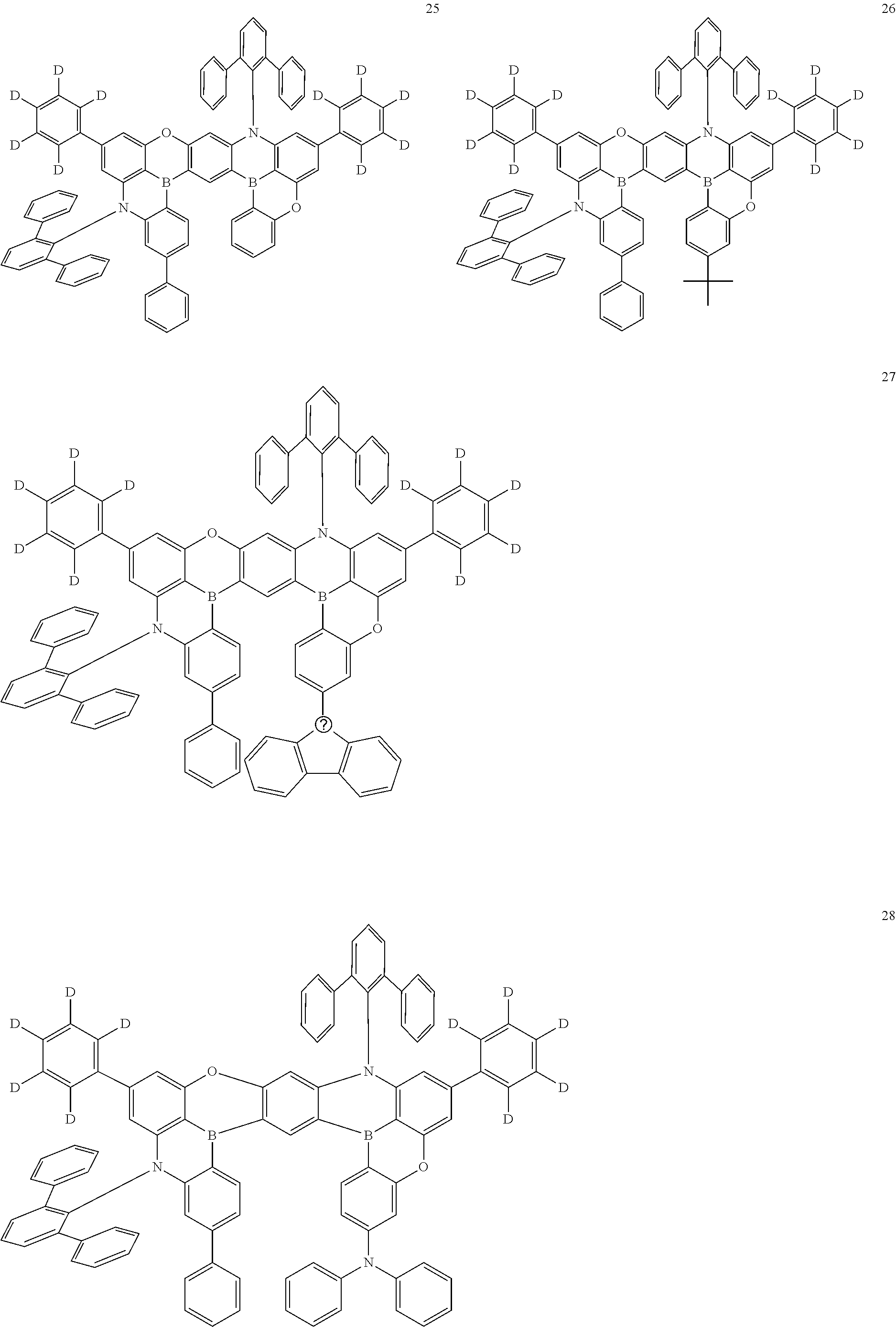

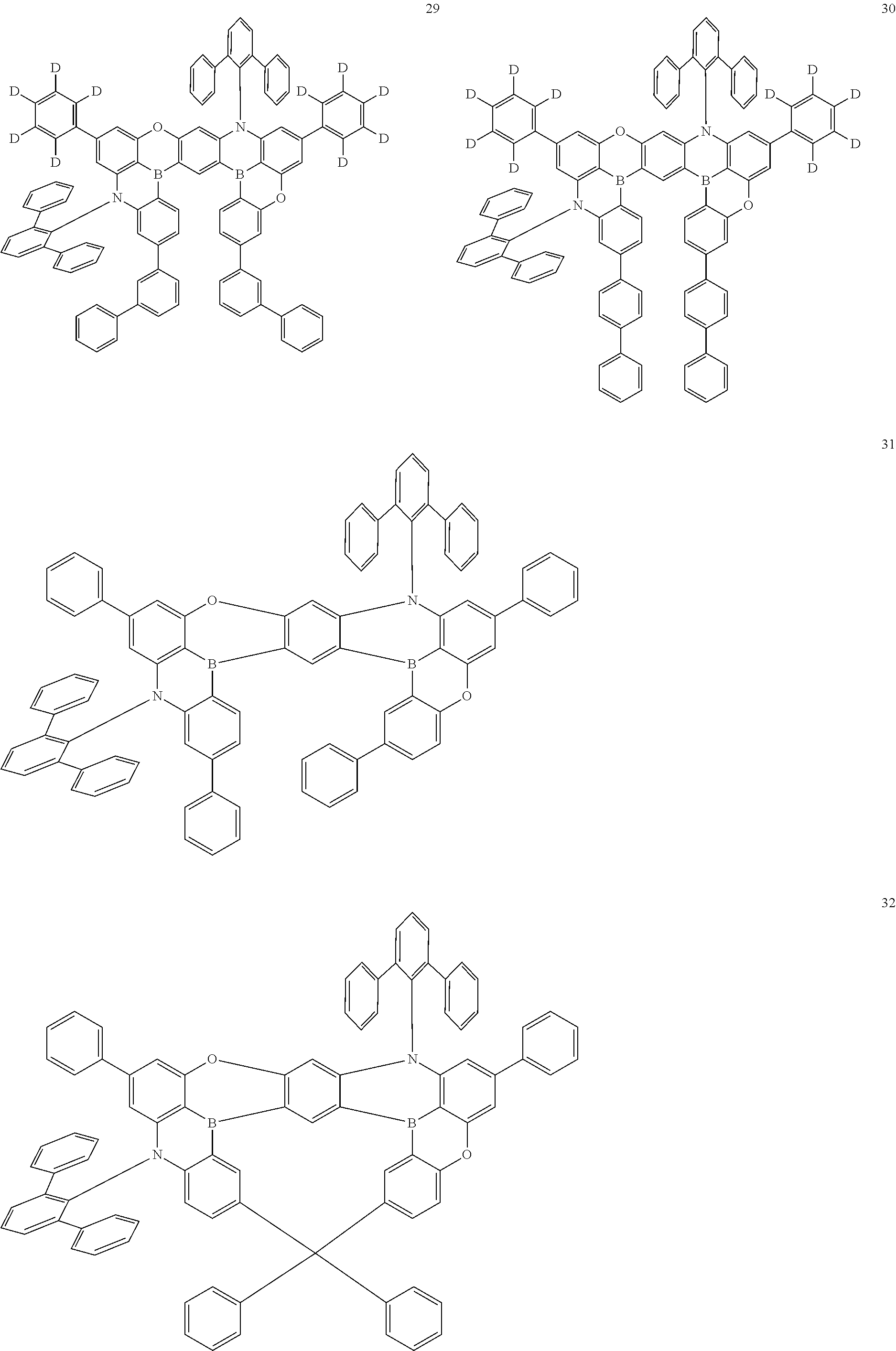

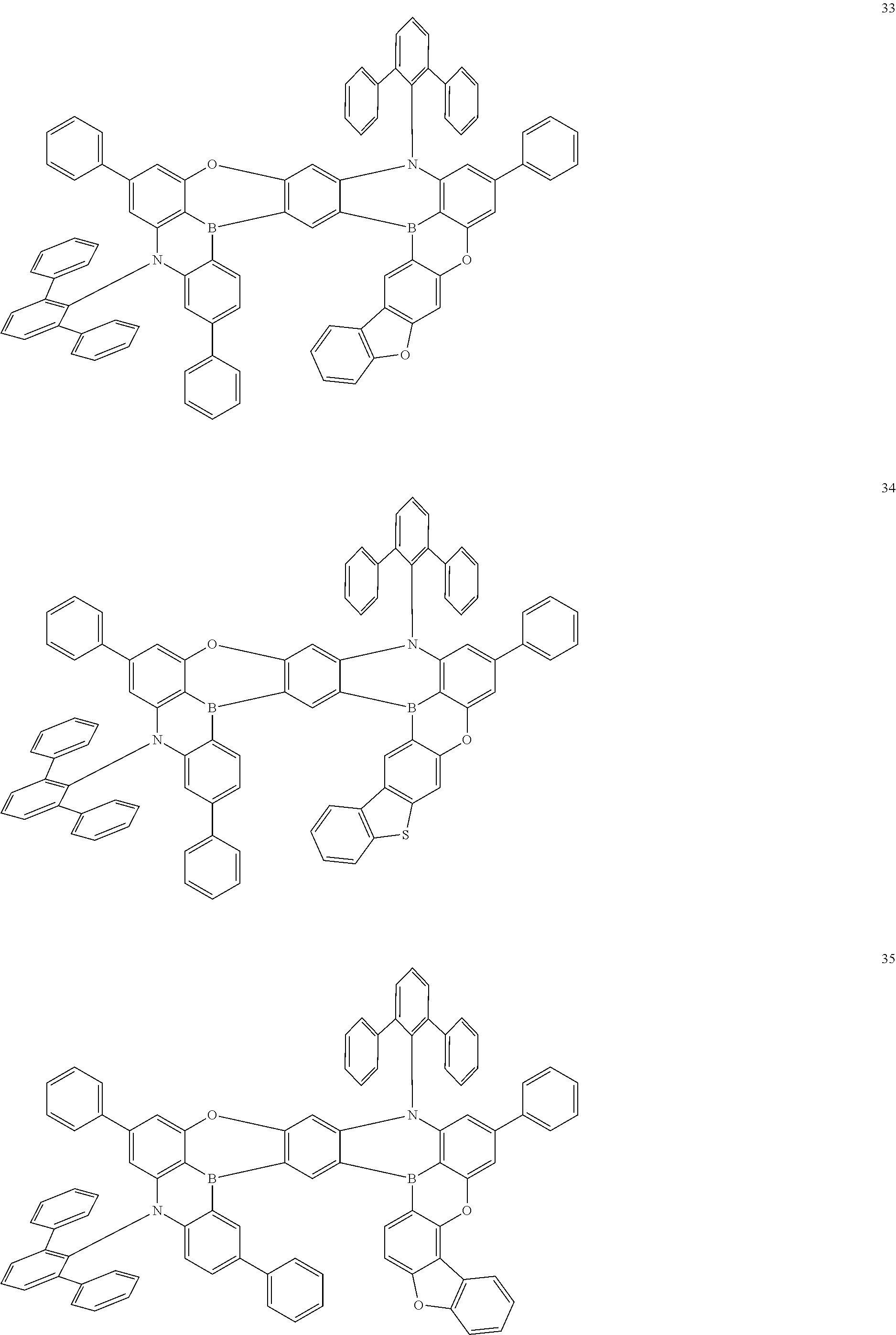 [SMILES: c1ccc(-c2ccc3c(c2)N(c2c(-c4ccccc4)cccc2-c2ccccc2)c2cc(-c4ccccc4)cc4c2B3c2cc3c(cc2O4)N(c2c(-c4ccccc4)cccc2-c2ccccc2)c2cc(-c4ccccc4)cc4c2B3c2cc3c(cc2O4)oc2ccccc23)cc1 ; c1ccc(-c2ccc3c(c2)N(c2c(-c4ccccc4)cccc2-c2ccccc2)c2cc(-c4ccccc4)cc4c2B3c2cc3c(cc2O4)N(c2c(-c4ccccc4)cccc2-c2ccccc2)c2cc(-c4ccccc4)cc4c2B3c2cc3c(cc2O4)sc2ccccc23)cc1 ; c1ccc(-c2ccc3c(c2)B2c4cc5c(cc4Oc4cc(-c6ccccc6)cc(c42)N3c2c(-c3ccccc3)cccc2-c2ccccc2)N(c2c(-c3ccccc3)cccc2-c2ccccc2)c2cc(-c3ccccc3)cc3c2B5c2ccc4oc5ccccc5c4c2O3)cc1]

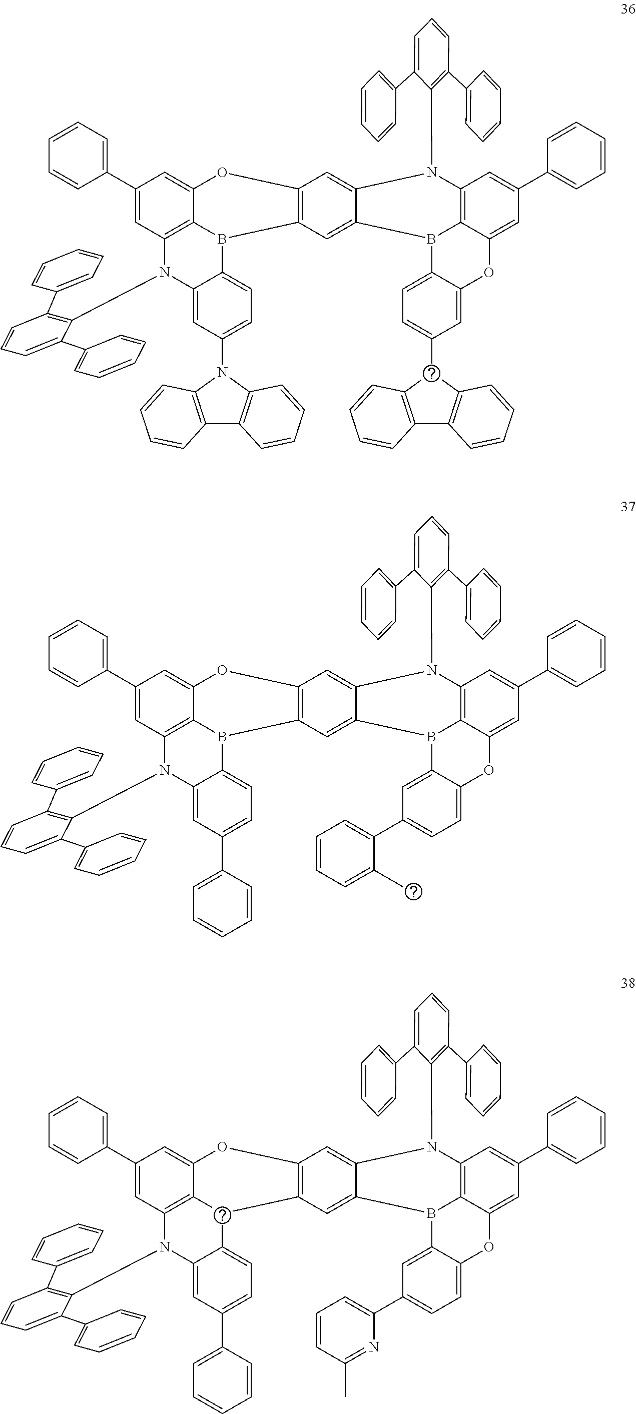

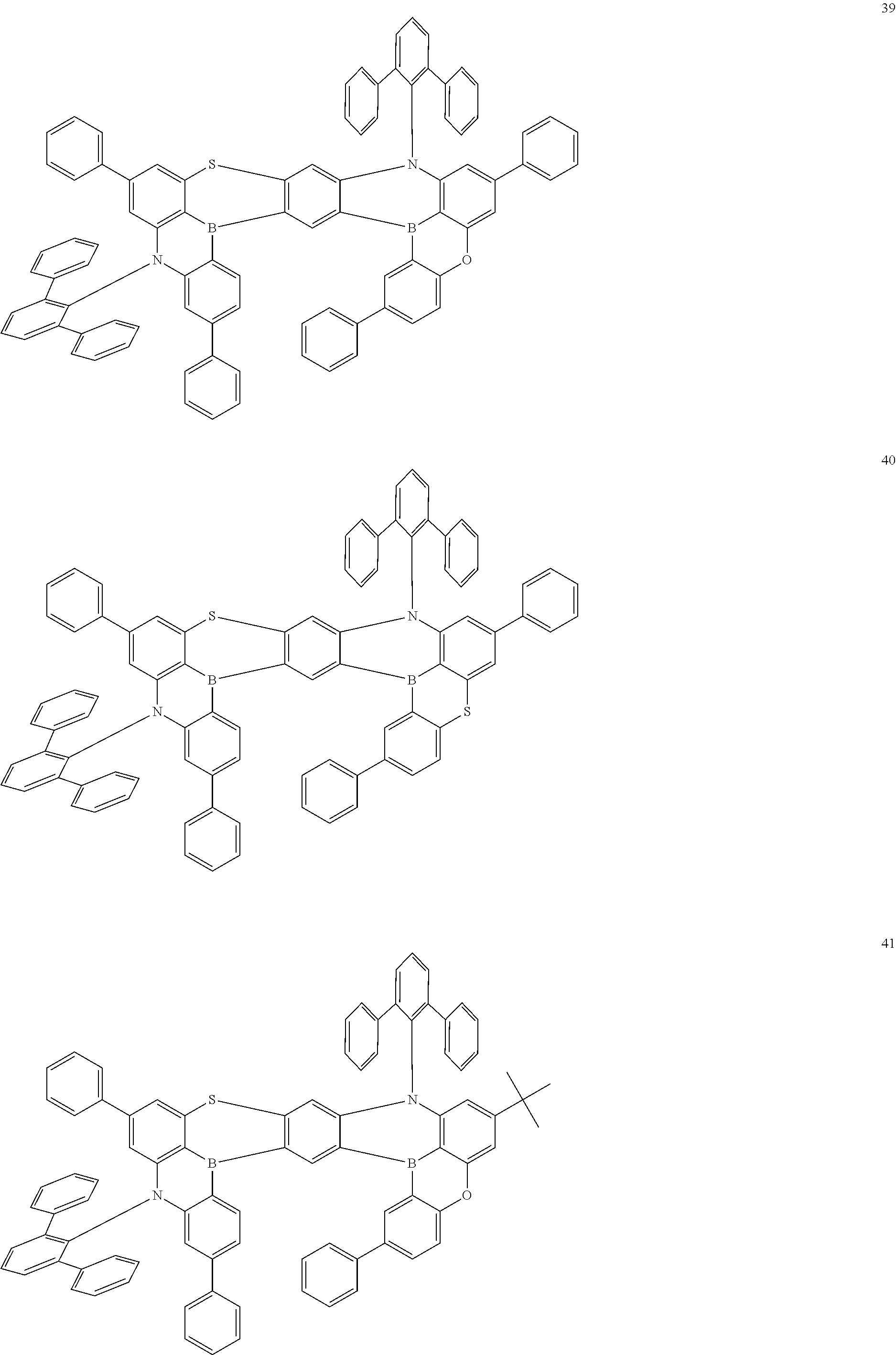 [SMILES: c1ccc(-c2ccc3c(c2)B2c4cc5c(cc4N(c4c(-c6ccccc6)cccc4-c4ccccc4)c4cc(-c6ccccc6)cc(c42)O3)Sc2cc(-c3ccccc3)cc3c2B5c2ccc(-c4ccccc4)cc2N3c2c(-c3ccccc3)cccc2-c2ccccc2)cc1 ; c1ccc(-c2ccc3c(c2)B2c4cc5c(cc4N(c4c(-c6ccccc6)cccc4-c4ccccc4)c4cc(-c6ccccc6)cc(c42)S3)Sc2cc(-c3ccccc3)cc3c2B5c2ccc(-c4ccccc4)cc2N3c2c(-c3ccccc3)cccc2-c2ccccc2)cc1 ; CC(C)(C)c1cc2c3c(c1)N(c1c(-c4ccccc4)cccc1-c1ccccc1)c1cc4c(cc1B3c1cc(-c3ccccc3)ccc1O2)B1c2ccc(-c3ccccc3)cc2N(c2c(-c3ccccc3)cccc2-c2ccccc2)c2cc(-c3ccccc3)cc(c21)S4]

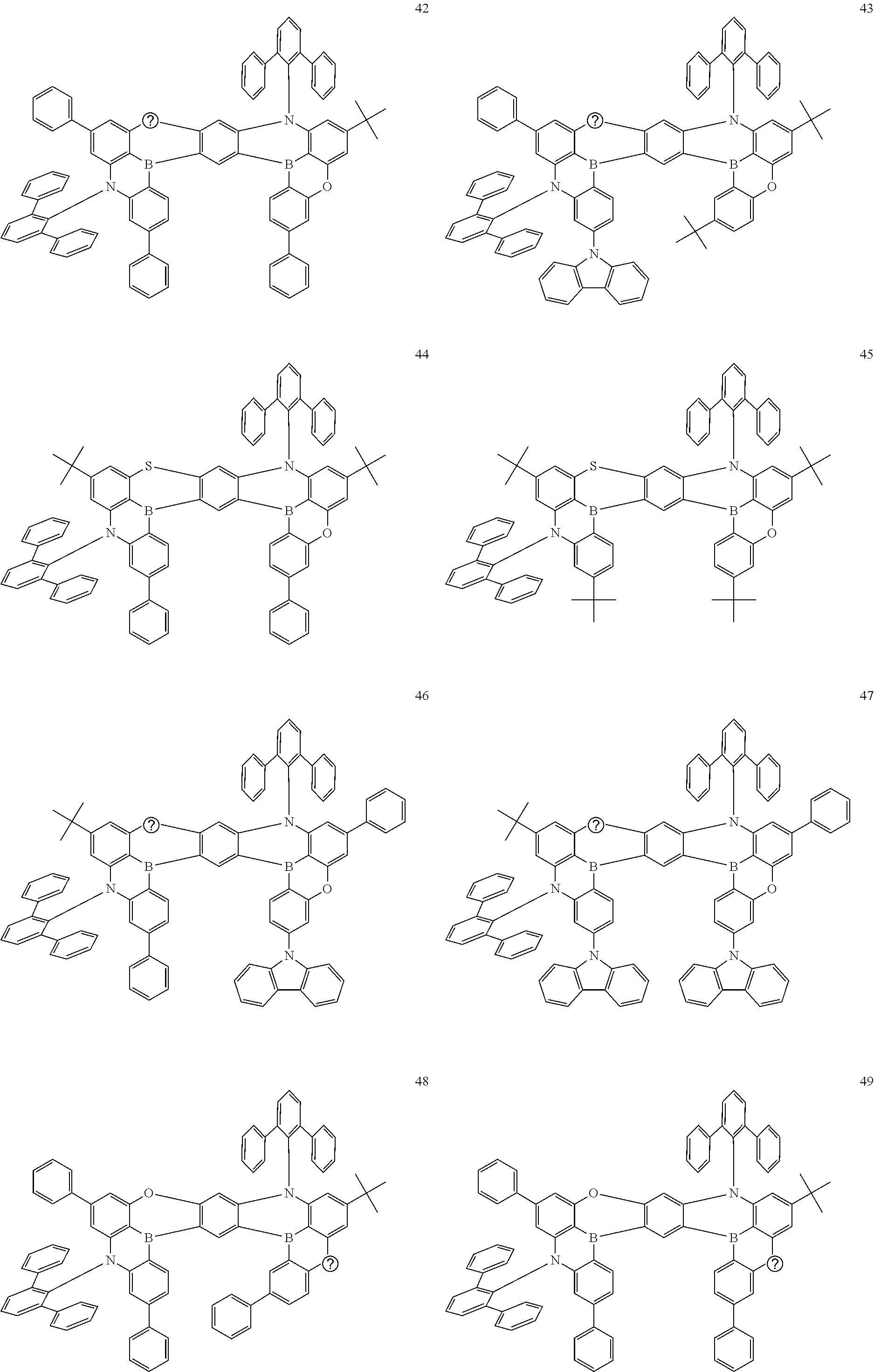

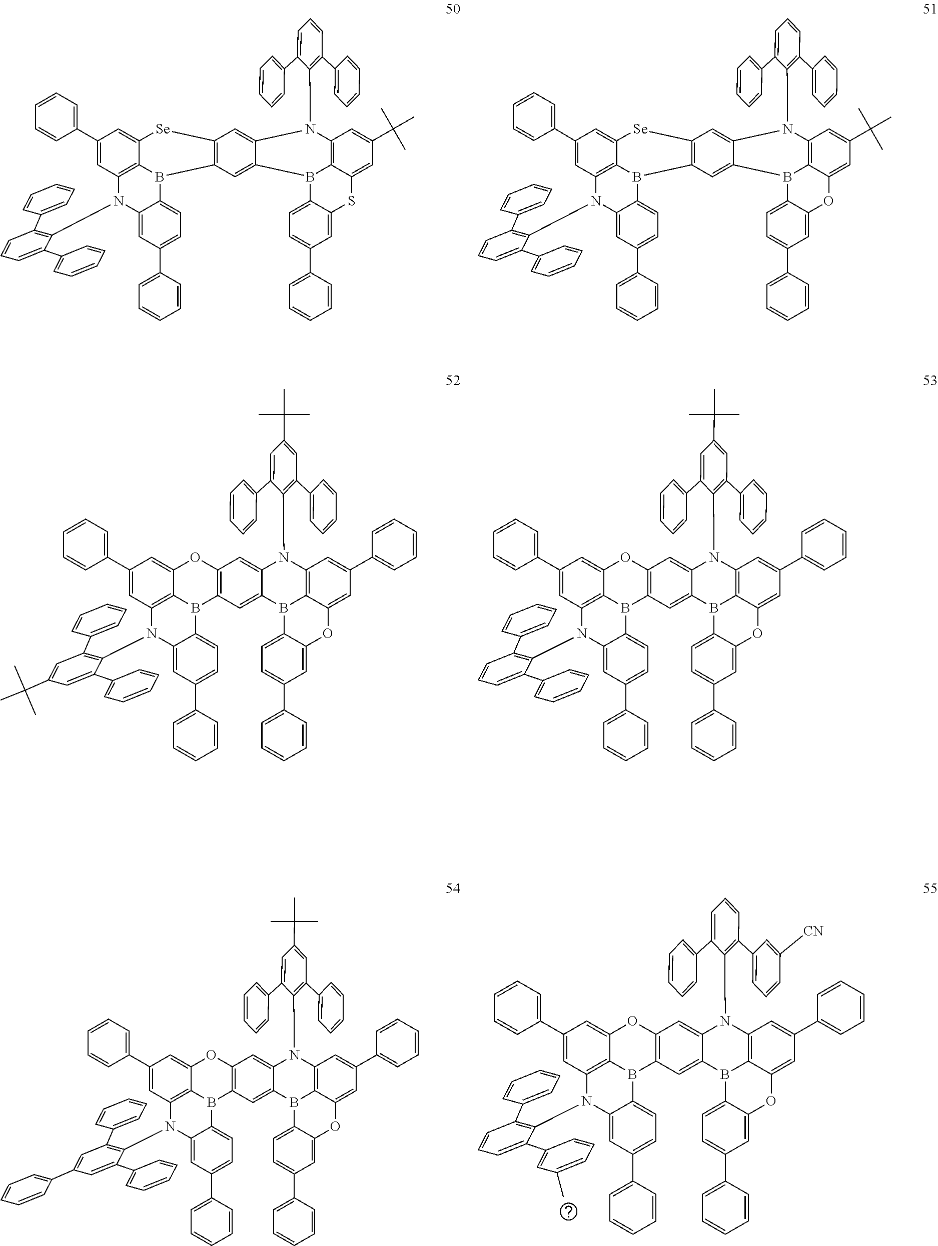

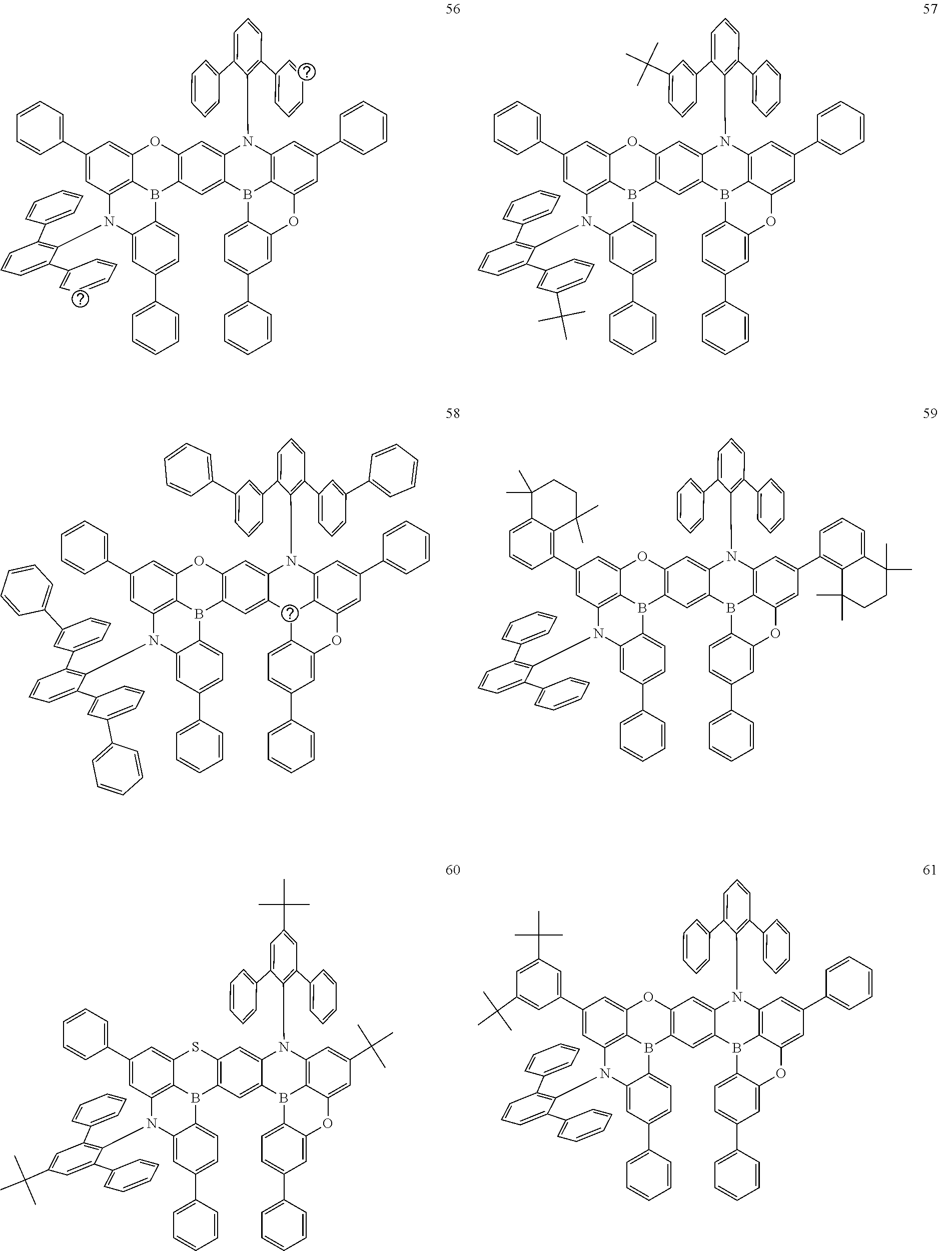

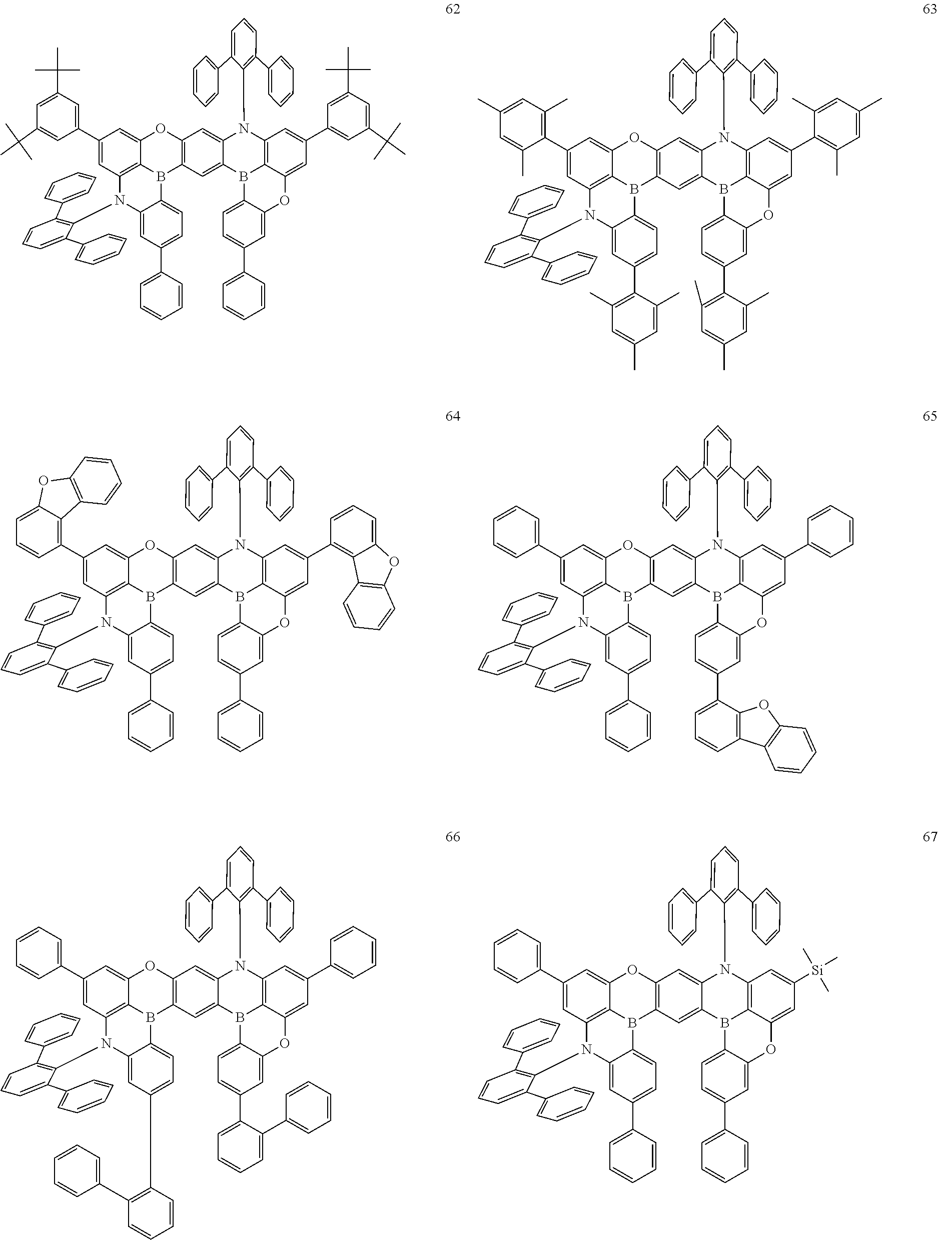

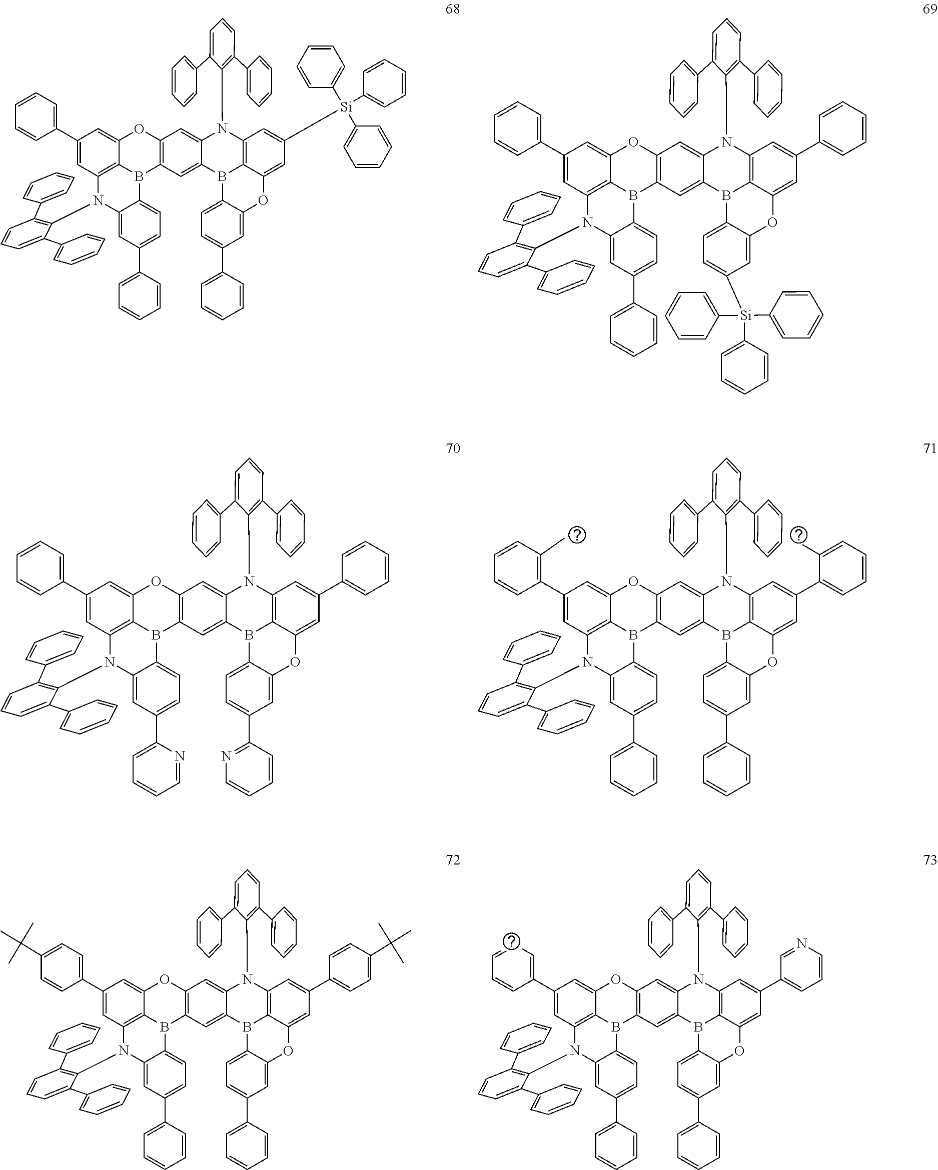

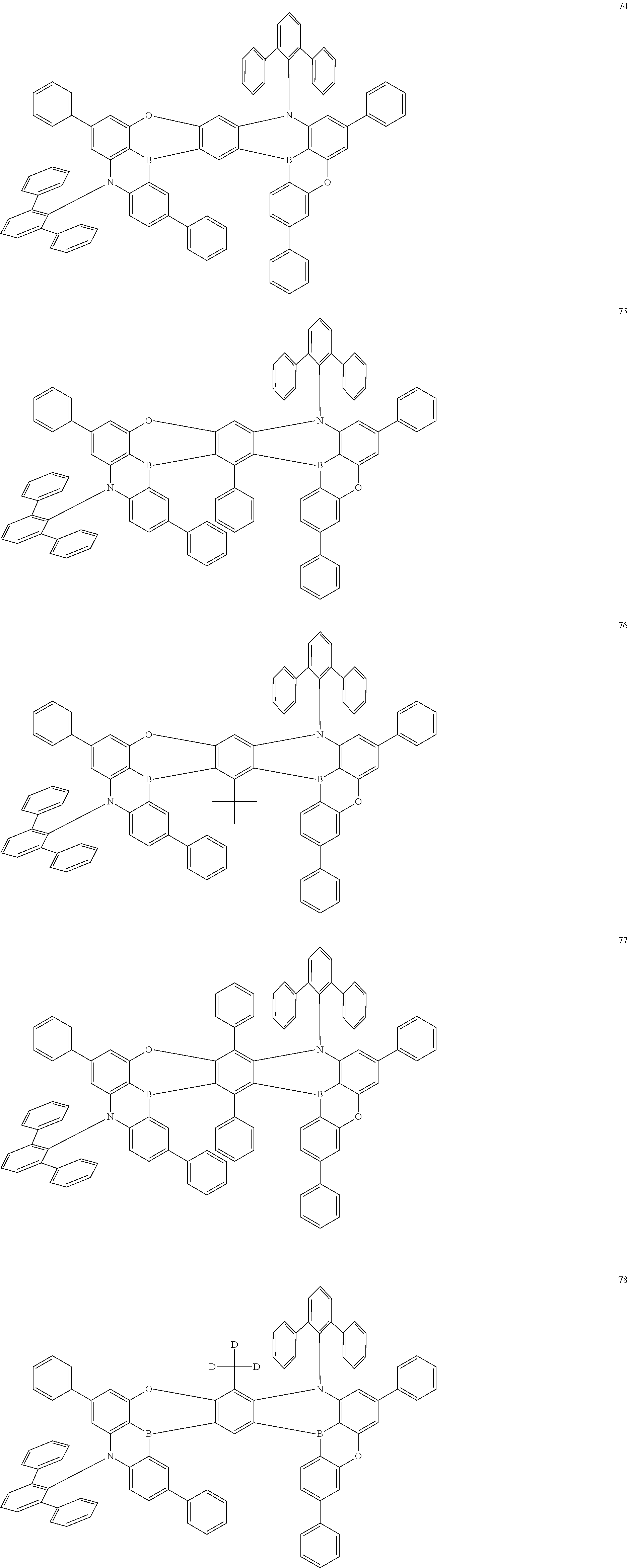

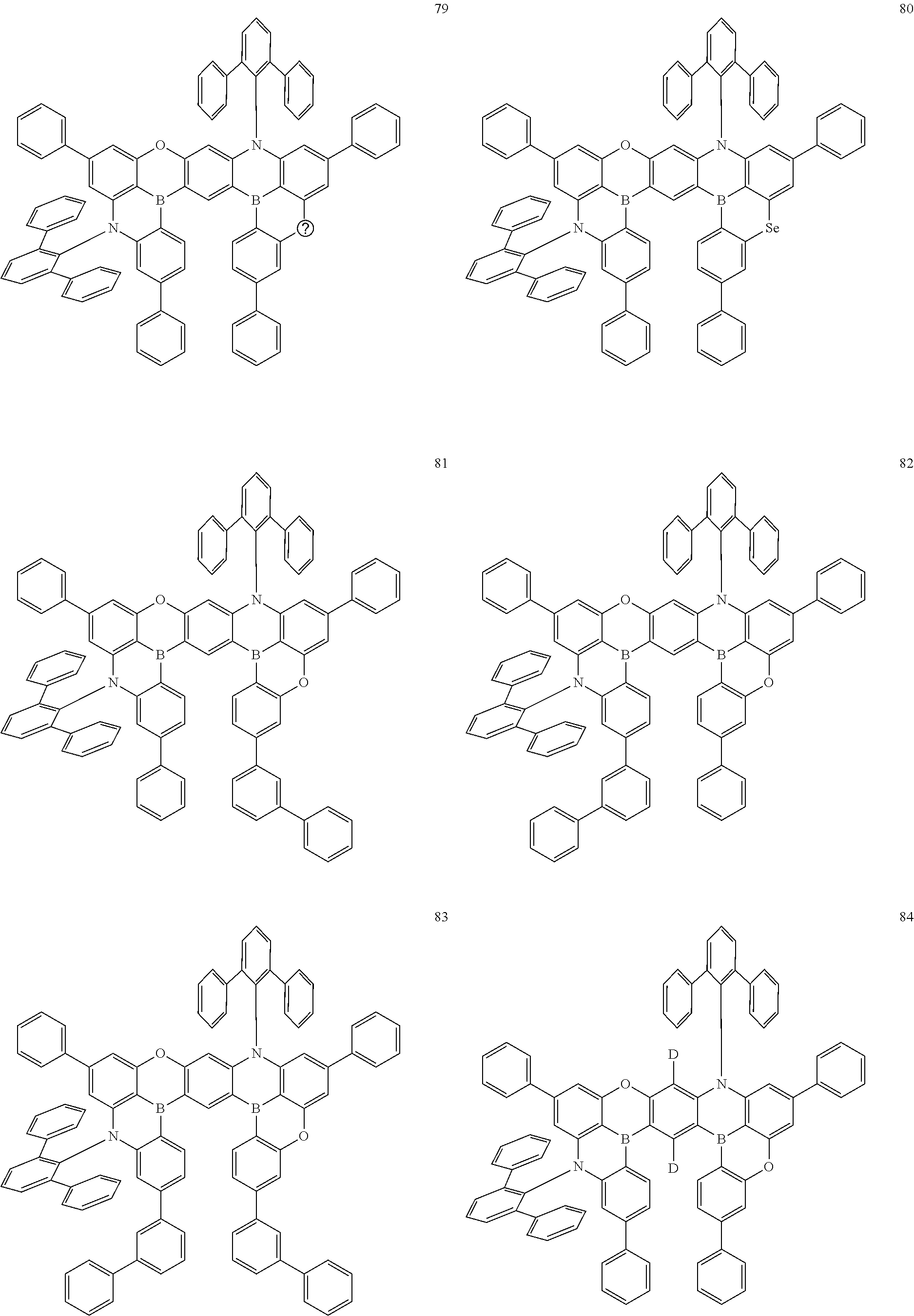

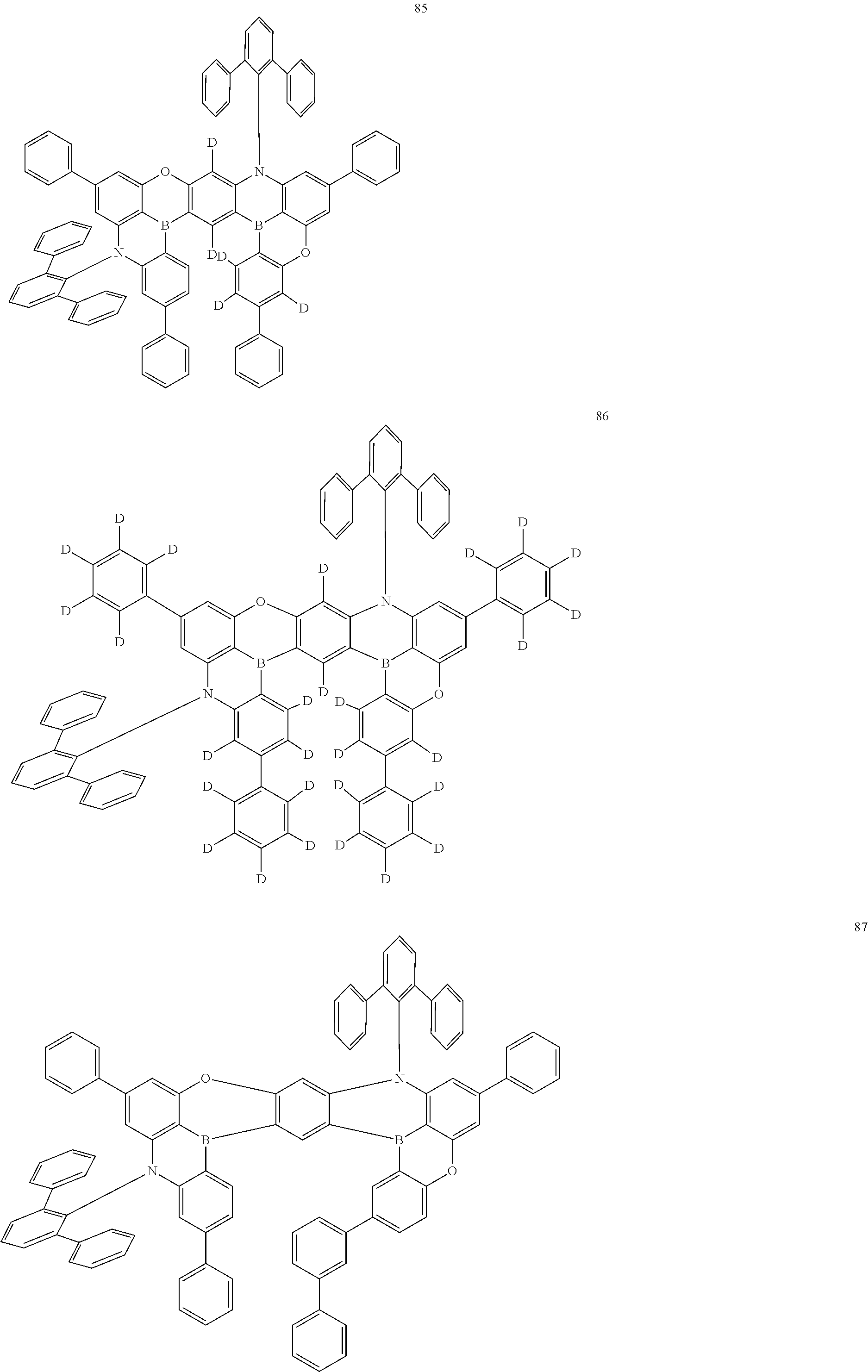

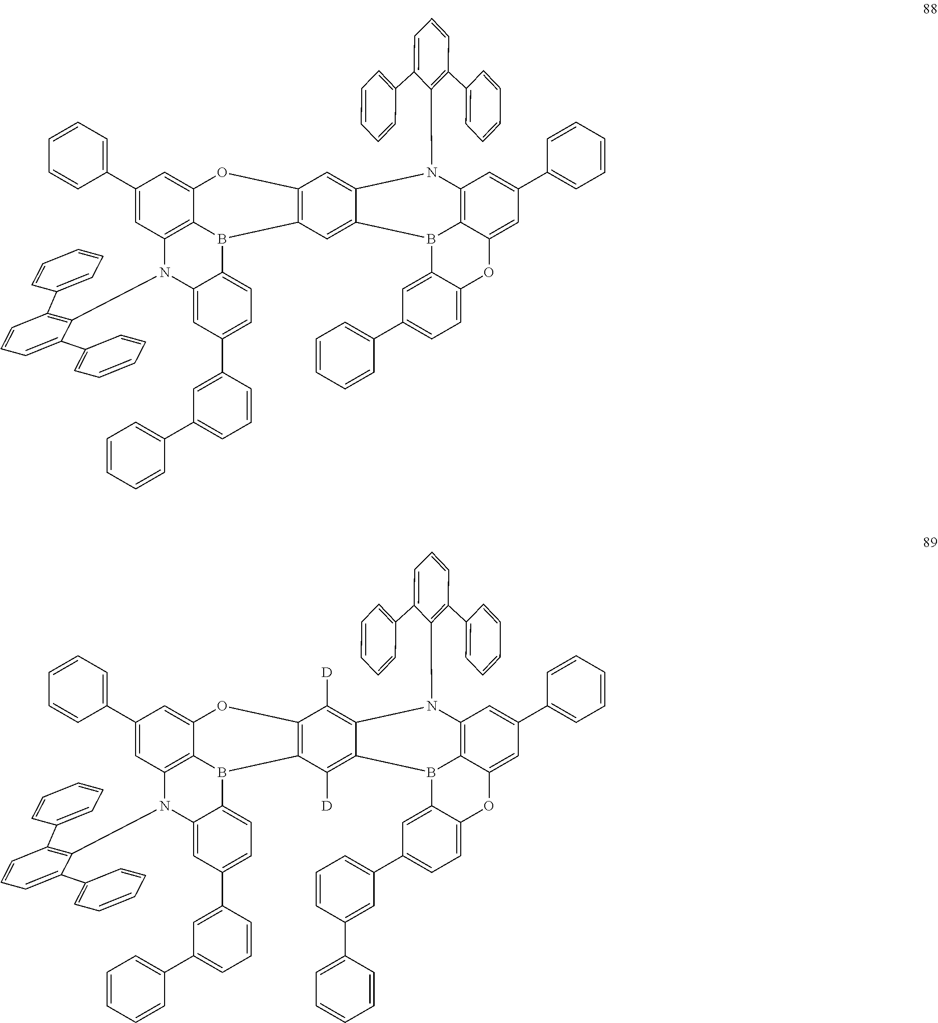 [SMILES: c1ccc(-c2cccc(-c3ccc4c(c3)N(c3c(-c5ccccc5)cccc3-c3ccccc3)c3cc(-c5ccccc5)cc5c3B4c3cc4c(cc3O5)N(c3c(-c5ccccc5)cccc3-c3ccccc3)c3cc(-c5ccccc5)cc5c3B4c3cc(-c4ccccc4)ccc3O5)c2)cc1 ; [2H]c1c2c(c([2H])c3c1B1c4cc(-c5cccc(-c6ccccc6)c5)ccc4Oc4cc(-c5ccccc5)cc(c41)N3c1c(-c3ccccc3)cccc1-c1ccccc1)Oc1cc(-c3ccccc3)cc3c1B2c1ccc(-c2cccc(-c4ccccc4)c2)cc1N3c1c(-c2ccccc2)cccc1-c1ccccc1]

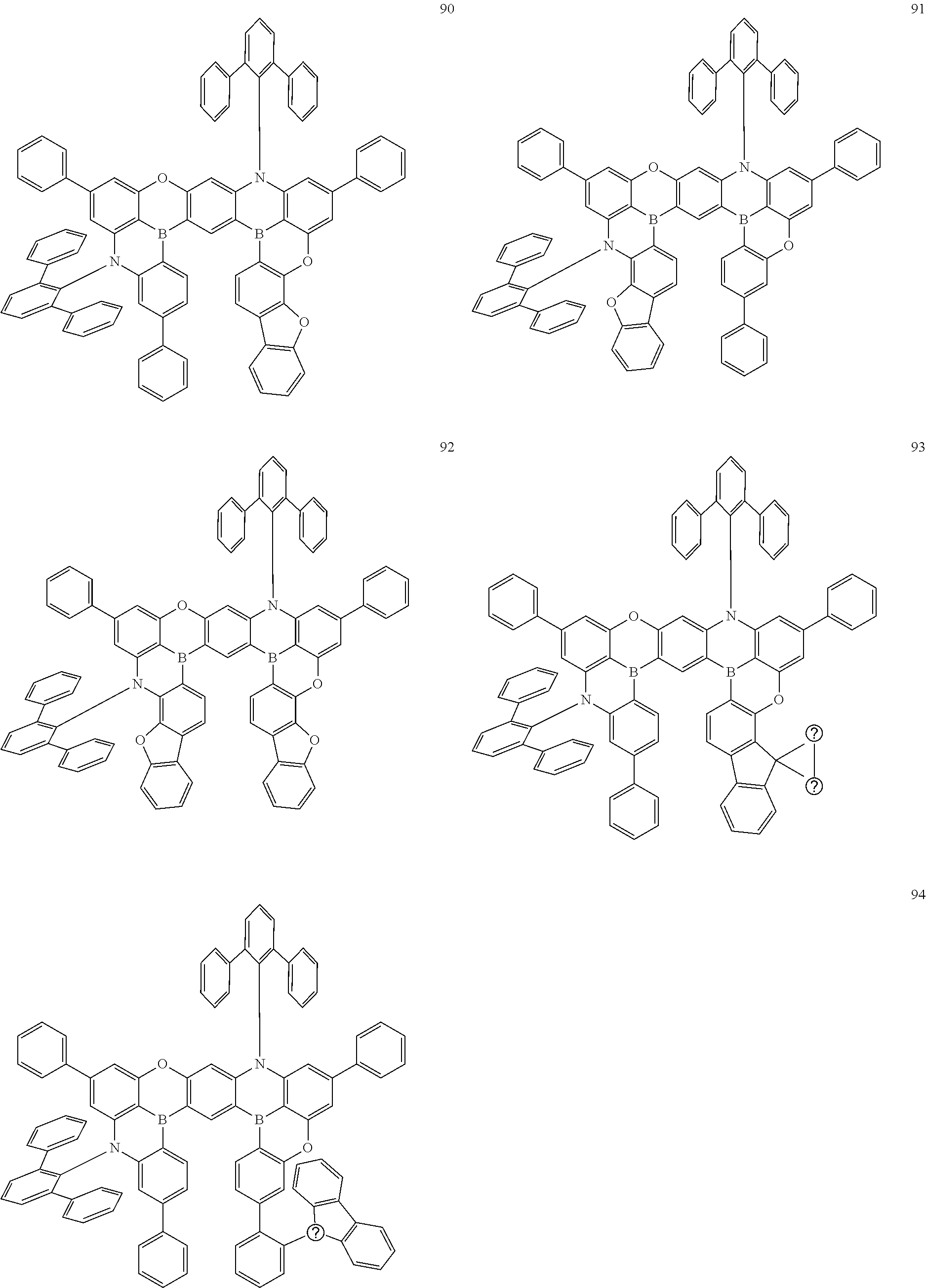

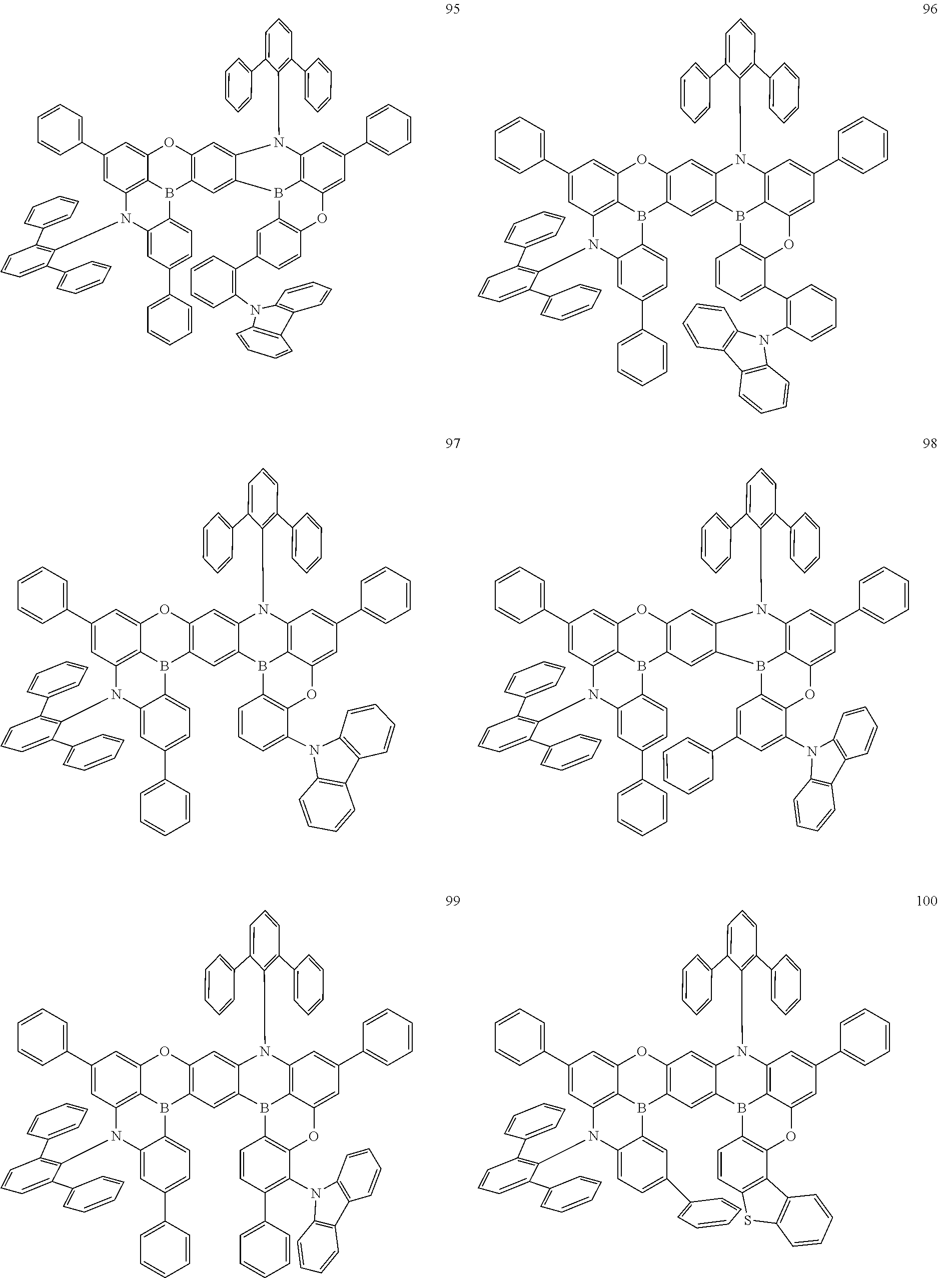

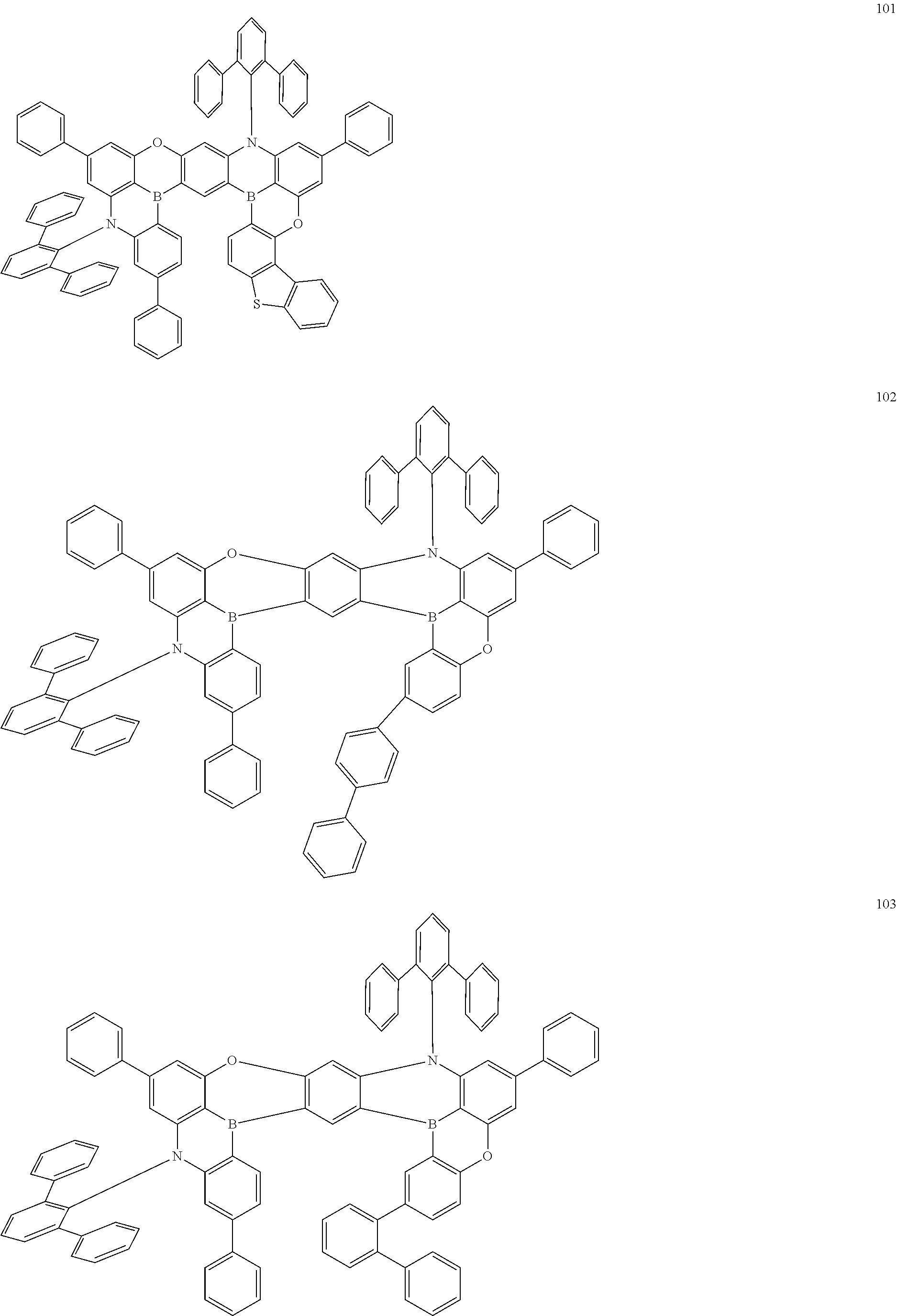

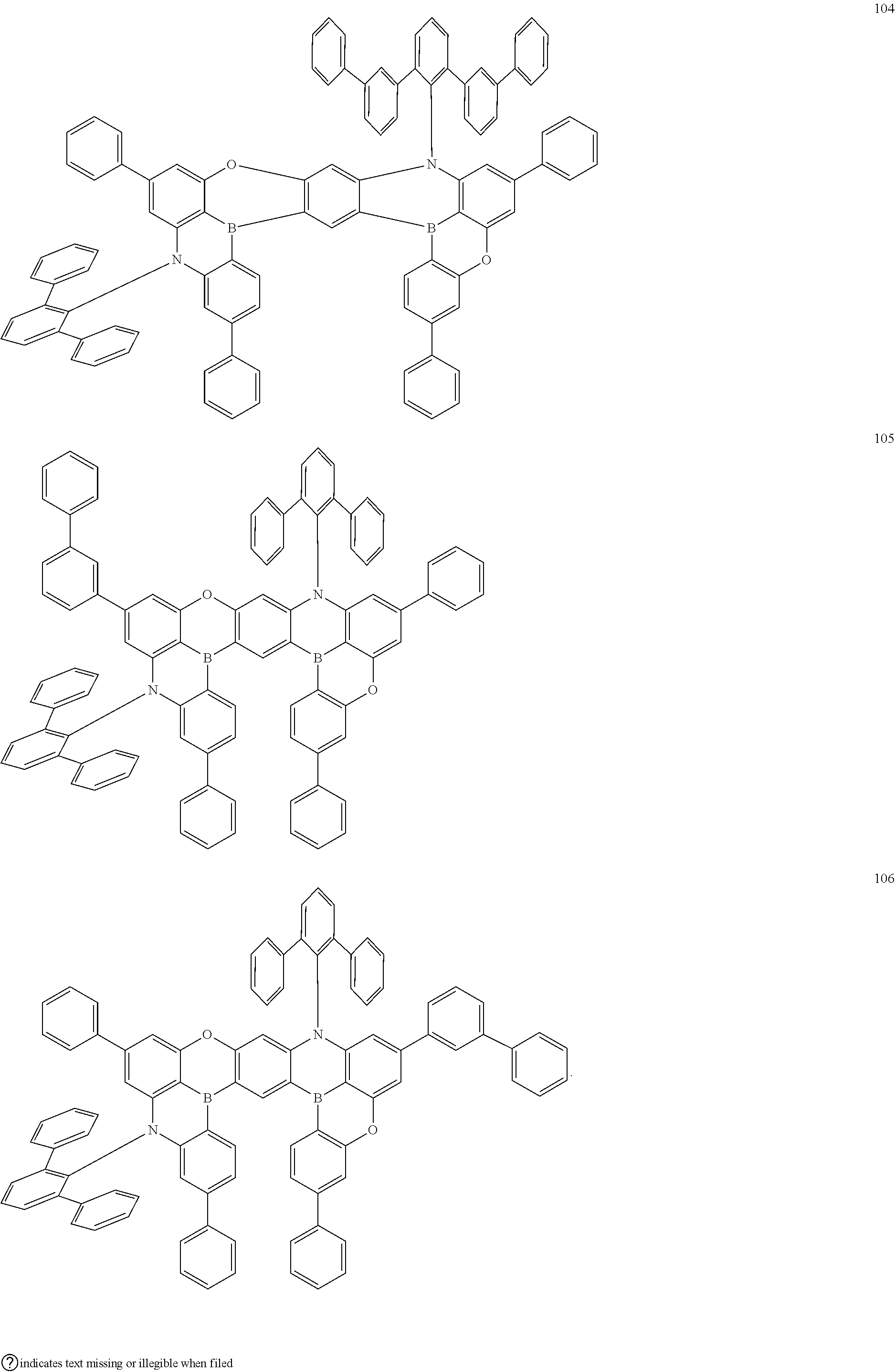

10. The condensed heterocyclic compound of claim 1, wherein the condensed heterocyclic compound has a highest occupied molecular orbital energy level of −5.3 electronvolts or less.

11. A light-emitting device, comprising:
a first electrode;
a second electrode; and
an intermediate layer between the first electrode and the second electrode, the intermediate layer comprising an emission layer that comprises a condensed heterocyclic compound represented by Chemical Formula 1: 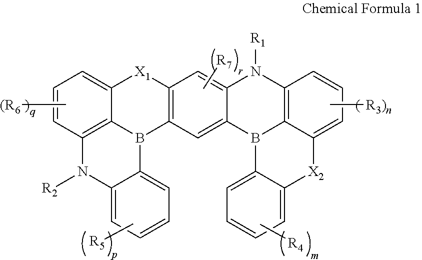
wherein, in Chemical Formula 1, X₁ and X₂ are each independently O, S or Se, and
R₁ and R₂ are each independently represented by Chemical Formula 2: 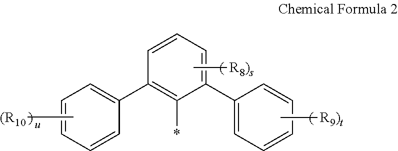
wherein, in Chemical Formulae 1 and 2, R₃ to R₁₀ are each independently hydrogen, deuterium, halogen, a hydroxyl group, a cyano group, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group, a substituted or unsubstituted C₈-C₆₀ condensed polycyclic group, —SiRR′R″, —P(═O)RR′, —NRR′, —BRR′, —C(═O)R or —S(═O)₂R; or
two or more of R₃ to R₁₀ are combined with each other to form a substituted or unsubstituted C₃-C₆₀ cycloalkyl ring, a substituted or unsubstituted C₅-C₆₀ cycloalkenyl ring, a substituted or unsubstituted C₃-C₆₀ heterocycloalkyl ring, a substituted or unsubstituted C₃-C₆₀ heterocycloalkenyl ring, a substituted or unsubstituted C₆-C₆₀ aryl ring, or a substituted or unsubstituted C₂-C₆₀ heteroaryl ring,
wherein R, R′ and R″ are each independently hydrogen, deuterium, halogen, a hydroxyl group, a cyano group, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group or a substituted or unsubstituted C₈-C₆₀ condensed polycyclic group,
n, q and s are each independently an integer from 0 to 3,
m and p are each independently an integer from 0 to 4,
r is an integer from 0 to 2,
t and u are each independently an integer from 0 to 5,
when n, m, p, q, r, s, t and u are each 2 or more, two or more of each of R₃ to R₁₀ are the same or different from each other, and
* represents a bonding position.

12. The light-emitting device of claim 11, wherein the emission layer comprises a host and a dopant, and the condensed heterocyclic compound is included as a thermally activated delayed fluorescence dopant.

13. The light-emitting device of claim 12, wherein the dopant further comprises a phosphorescent dopant.

14. The light-emitting device according to claim 12, wherein the host comprises a hole transporting host represented by Chemical Formula HT and an electron transporting host represented by Chemical Formula ET: 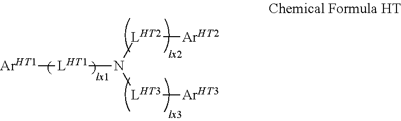
wherein, in Chemical Formula HT, L^{HT1}, L^{HT2}, and L^{HT3} are each independently a direct linkage, a substituted or unsubstituted C₆-C₃₀ arylene group, or a substituted or unsubstituted C₂-C₃₀ heteroarylene group,
lx1 to lx3 are each independently be an integer from 0 to 10,
Ar^{HT1} and Ar^{HT2} are each independently a substituted or unsubstituted C₆-C₃₀ aryl group, or a substituted or unsubstituted C₂-C₃₀ heteroaryl group, and Ar^{HT3} is a substituted or unsubstituted C₆-C₃₀ aryl group. 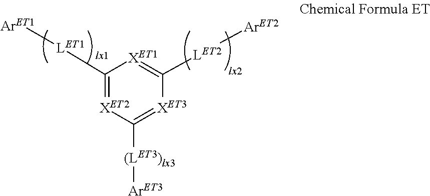
wherein, in Chemical Formula ET, at least one of X^{ET1} to X^{ET3} is N, and the remainder of X^{ET1} to X^{ET3} are each independently C(R^{ET}),
R^{ET} is a hydrogen atom, a deuterium atom, a substituted or unsubstituted C₁-C₂₀ alkyl group, a substituted or unsubstituted C₆-C₆₀ aryl group, or a substituted or unsubstituted C₂-C₆₀ heteroaryl group,
lx1 to lx3 are each independently an integer from 0 to 10,
L^{ET1} to L^{ET3} are each independently be a direct linkage, a substituted or unsubstituted C₆-C₃₀ arylene group, or a substituted or unsubstituted C₂-C₃₀ heteroarylene group, and
Ar^{ET1} to Ar^{ET3} are each independently a hydrogen atom, a deuterium atom, a substituted or unsubstituted C₁-C₂₀ alkyl group, a substituted or unsubstituted C₆-C₃₀ aryl group, or a substituted or unsubstituted C₂-C₃₀ heteroaryl group.

15. The light-emitting device of claim 11, wherein the emission layer emits a blue light, and a maximum emission wavelength of the blue light is in a range from 440 nanometers to 470 nanometers.

16. An electronic device including the light-emitting device of claim 11.

17. The electronic device of claim 16, wherein the emission layer of the light-emitting device comprises two or more emission layers, and at least one of the emission layers comprises the condensed heterocyclic compound of Chemical Formula 1.

18. The electronic device of claim 17, further comprising a color control portion including a light transformer.

19. The electronic device of claim 16, wherein the light-emitting device comprises a blue light-emitting device, a red light-emitting device and a green light-emitting device, and
at least one of the blue light-emitting device, the red light-emitting device, or the green light-emitting device comprises the condensed heterocyclic compound of Chemical Formula 1.

20. The electronic device of claim 19, wherein the electronic device is at least one of a flat panel display, a curved display, a computer monitor, a medical monitor, a television, a billboard, a light for indoor or outdoor lighting and/or signals, a head-up display, a full or partial transparent display, a flexible display, a rollable display, a foldable display, a stretchable display, a laser printer, a phone, a mobile phone, a tablet, a phablet, a personal information terminal, a wearable device, a laptop computer, a digital camera, a camcorder, a viewfinder, a micro display, a three-dimensional display, a virtual reality or augmented reality display, a vehicle, a video wall including multiple displays tiled together, a theater or stadium screen, a phototherapy device, or a signage.
